(19) United States
(12) Patent Application Publication
(10) Pub. No.: US 2019/0091970 A1
(43) Pub. Date: Mar. 28, 2019

(54) LAMINATE AND FRONT PANEL OF IMAGE DISPLAY APPARATUS, IMAGE DISPLAY APPARATUS, MIRROR WITH IMAGE DISPLAY FUNCTION, RESISTIVE FILM-TYPE TOUCH PANEL, AND CAPACITANCE-TYPE TOUCH PANEL HAVING LAMINATE

(71) Applicant: FUJIFILM Corporation, Tokyo (JP)

(72) Inventors: Keigo UEKI, Kanagawa (JP); Kazuhide KANEMURA, Kanagawa (JP); Jumpei FUJITA, Kanagawa (JP); Katsuyuki TAKADA, Kanagawa (JP)

(73) Assignee: FUJIFILM Corporation, Tokyo (JP)

(21) Appl. No.: 16/197,582

(22) Filed: Nov. 21, 2018

Related U.S. Application Data
(63) Continuation of application No. PCT/JP2017/019277, filed on May 23, 2017.

(30) Foreign Application Priority Data
May 24, 2016 (JP) 2016-103762
Jun. 22, 2016 (JP) 2016-123240
Sep. 20, 2016 (JP) 2016-183179

(51) Int. Cl. B32B 17/06; B32B 37/12; C09J 7/29

(52) U.S. Cl. CPC B32B 17/064; C09J 7/29; B32B 37/12

(57) ABSTRACT

A laminate, including at least a resin film and a pressure sensitive adhesive layer provided on one surface of the resin film, in which the resin film in the laminated state has a surface roughness Sa equal to or lower than 30 nm that is measured in a visual field of 4 mm×5 mm within a surface opposite to the surface having the pressure sensitive adhesive layer, a thickness of the pressure sensitive adhesive layer is equal to or smaller than 100 μm, and a maximum value of a loss tangent of the pressure sensitive adhesive layer at a frequency of 1 Hz is found in a temperature range of 0° C. to −40° C. and is equal to or greater than 1.3.

### CROSS-REFERENCE TO RELATED APPLICATIONS

This application is a Continuation of PCT International Application No. PCT/JP2017/019277 filed on May 23, 2017, which claims priority under 35 U.S.C. § 119 (a) to Japanese Patent Application No. 2016-103762 filed on May 24, 2016, Japanese Patent Application No. 2016-123240 filed on Jun. 22, 2016, and Japanese Patent Application No. 2016-183179 filed on Sep. 20, 2016. The above applications are hereby expressly incorporated by reference, in its entirety, into the present application.

### BACKGROUND OF THE INVENTION

### 1. Field of the Invention

The present invention relates to a laminate and a front panel of an image display apparatus using the laminate, an image display apparatus, a mirror with an image display function, a resistive film-type touch panel, and a capacitance-type touch panel which have the laminate.

### 2. Description of the Related Art

For the uppermost surface an image display apparatus such as a touch panel, for the purpose of preventing breaking, scratching, and the like, glass such as chemically strengthened glass is used. In recent years, from the viewpoint of reducing thickness and weight, imparting bending properties, and the like, a plastic film which is a substitute material for the glass has been increasingly used. The plastic film (hereinafter, simply referred to as film as well) as a glass substitute is required to demonstrate functions such as hardness and rub resistance equivalent to those of glass. Furthermore, the plastic film is required to have quality close to that of glass in terms of the appearance and texture, and the like (the quality means so-called “classiness” of glass; hereinafter, the quality will be referred to as “glass quality”).

For example, JP2016-020415A describes an acrylic elastomer resin film which has transparency and surfaces that appears smooth.

As a result of conducting an examination, the inventors of the present invention have found that the glass quality is correlated with the asperities of a macro region within the film surface. Generally, the smoothness of a film is related to the asperities of a micro region (for example, a visual field of 120 μm² for measurement). However, the inventors have found that the glass quality is influenced not by the asperities of a micro region but by the asperities of a macro region (for example, a visual field of 4 mm×5 mm order for measurement), and the smoother the asperities of the macro region, the closer the quality of the film to the classiness of glass.

As a result of further carrying out the examination on the plastic film as a glass substitute, the inventors of the present invention have found that even though the film is originally smooth, after the film is laminated on another member to constitute a display, unfortunately, the smoothness of the film is reduced, the appearance of the display is poorer than that of a display using glass, and the classiness of glass cannot be obtained.

An object of the present invention is to provide a laminate which exhibits excellent glass quality even in a case where the laminate is laminated on another member, and a front panel of an image display apparatus, an image display apparatus, a mirror with an image display function, a resistive film-type touch panel, and a capacitance-type touch panel which exhibit excellent glass quality.

### SUMMARY OF THE INVENTION

As a result of conducting a thorough examination, the inventors of the present invention have found that the glass quality is influenced by the physical properties of a pressure sensitive adhesive used for lamination on another member. Furthermore, the inventors have found that a laminate of a pressure sensitive adhesive layer, which has specific thickness and loss tangent, and a resin film having a surface roughness equal to or smaller than a specific value in a macro region exhibits excellent glass quality even in a case where the laminate is laminated on another member. In addition, the inventors have found that by using the laminate, it is possible to provide a front panel of an image display apparatus, an image display apparatus, a mirror with an image display function, a resistive film-type touch panel, and a capacitance-type touch panel which exhibit excellent glass quality. The inventors further repeated the examination based on the findings and have accomplished the present invention.

That is, the object was achieved by the following means.
(1) A laminate comprising at least a resin film and a pressure sensitive adhesive layer provided on one surface of the resin film, in which the resin film in the laminated state has a surface roughness Sa equal to or lower than 30 nm that is measured in a visual field of 4 mm×5 mm within a surface opposite to the surface having the pressure sensitive adhesive layer, a thickness of the pressure sensitive adhesive layer is equal to or smaller than 100 μm, and a maximum value of a loss tangent of the pressure sensitive adhesive layer at a frequency of 1 Hz is found in a temperature range of 0° C. to −40° C. and is equal to or greater than 1.3.
(2) The laminate described in (1), in which the resin film in the laminated state has a surface roughness Sa equal to or lower than 20 nm that is measured in a visual field of 120 μm×120 μm within a surface opposite to the surface having the pressure sensitive adhesive layer.
(3) The laminate described in (1) or (2), in which a thickness of the resin film is equal to or greater than 80 μm.
(4) The laminate described in any one of (1) to (3), further comprising a hardcoat layer on the surface, which is opposite to the surface provided with the pressure sensitive adhesive layer, of the resin film.
(5) The laminate described in (4) in which a thickness of the hardcoat layer is equal to or greater than 10 μm and equal to or smaller than 50 μm.
(6) The laminate described in (4) or (5), in which a pencil hardness of the hardcoat layer is equal to or higher than 5H.
(7) The laminate described in any one of (1) to (6), further comprising a linear polarization reflection layer or a circular polarization reflection layer on a surface, which is opposite to a surface having the resin film, of the pressure sensitive adhesive layer.
(8) The laminate described in (7), in which the circular polarization reflection layer includes at least one cholesteric liquid crystal layer, and the cholesteric liquid crystal layer is a layer obtained by curing a liquid crystal composition containing a polymerizable liquid crystal compound and a polymerization initiator.
(9) A front panel of an image display apparatus, comprising the laminate described in any one of (1) to (8).
(10) An image display apparatus comprising the front panel described in (9) and an image display device.
(11) The image display apparatus described in (10), in which the image display device is a liquid crystal display device.
(12) The image display apparatus described in (10), in which the image display device is an organic electroluminescence display device.
(13) The image display apparatus described in any one of (10) to (12), in which the image display device is an in-cell touch panel display device.
(14) The image display apparatus described in any one of (10) to (12), in which the image display device is an on-cell touch panel display device.
(15) A resistive film-type touch panel comprising the front panel described in (9).
(16) A capacitance-type touch panel comprising the front panel described in (9).
(17) A mirror with an image display function in which the image display apparatus described in (10) is used.

In the present specification, a range of numerical values described using “to” means a range including numerical values listed before and after “to” as an upper limit and a lower limit respectively.

In the present specification, “acryl” or “(meth)acryl” means methacryl and/or acryl, and “acryloyl” or “(meth)acryloyl” means methacryloyl and/or acryloyl.

In the present specification, unless otherwise specified, a weight-average molecular weight (Mw) can be measured by GPC as a molecular weight expressed in terms of polystyrene. At this time, by using HLC-8220 (manufactured by Tosoh Corporation) as a GPC apparatus and using G3000HXL+G2000HXL as columns, the weight-average molecular weight is measured by detecting RI at 23° C. and a flow rate of 1 mL/min. The eluent can be selected from tetrahydrofuran (THF), chloroform, N-methyl-2-pyrrolidone (NMP), and m-cresol/chloroform (manufactured by Shonan Wako Junyaku K.K.). As the eluent, THF can be used as long as it dissolves a sample.

In the present specification, the thickness, surface roughness, and a loss tangent (tan δ) of each layer are measured by the methods described in Examples.

The laminate of the embodiment of the present invention can exhibit excellent glass quality even in a case where the laminate is laminated on another member. Furthermore, the front panel of an image display apparatus, the image display apparatus, the mirror with an image display function, the resistive film-type touch panel, and the capacitance-type touch panel that have the laminate of the embodiment of the present invention can exhibit excellent glass quality.

The characteristics and other characteristics of the present invention as well as the advantages of the present invention will be further clarified by the following description with reference to the attached drawing as appropriate.

### BRIEF DESCRIPTION OF THE DRAWINGS

FIG. 1 is a vertical cross-sectional view showing the constitution of a laminate of the embodiment of the present invention.

FIG. 2 is a vertical cross-sectional view showing an embodiment of the constitution of a laminate of the embodiment of the present invention having a hardcoat layer.

FIG. 3 is a schematic cross-sectional view showing an embodiment of a capacitance-type touch panel.

FIG. 4 is a schematic view of a conductive film for a touch panel.

FIG. 5 is a schematic view showing portions in which a first electrode 11 and a second electrode 21 in FIG. 4 cross each other.

FIG. 6 is a schematic view showing an embodiment of a first dummy electrode 11A that a first conductive layer 8 in an active area S1 in FIG. 4 may have.

### DESCRIPTION OF THE PREFERRED EMBODIMENTS

### Preferable Embodiment

[Laminate]

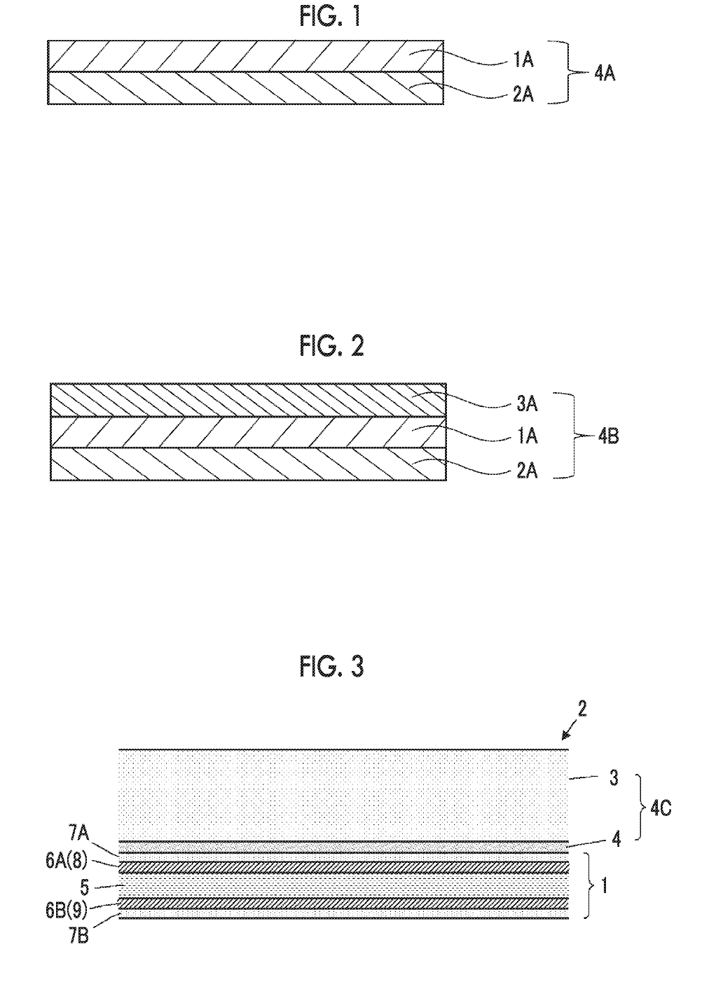

FIG. 1 shows a preferable embodiment of the laminate of the present invention. A laminate 4A shown in FIG. 1 is a laminate which has at least a resin film 1A and a pressure sensitive adhesive layer 2A on one surface of the resin film (that is, a laminate which has at least the resin film 1A and the pressure sensitive adhesive layer 2A disposed on one surface of the resin film 1A). In the laminate, the resin film in the laminated state has a surface roughness Sa equal to or lower than 30 nm that is measured in a visual field of 4 mm×5 mm within a surface opposite to the surface having the pressure sensitive adhesive layer (that is, in FIG. 1, a surface, which is opposite to a surface contacting the pressure sensitive adhesive layer 2A, of the resin film 1A), a thickness of the pressure sensitive adhesive layer is equal to or smaller than 100 μm, and a maximum value of a loss tangent of the pressure sensitive adhesive layer at a frequency of 1 Hz is found in a temperature range of 0° C. to −40° C. and is equal to or greater than 1.3.

In a case where the laminate of the embodiment of the present invention has the constitution, the laminate can exhibit excellent glass quality even in a case where the laminate is laminated on another member. The reason is unclear, but assumed to be as below.

Generally, in a case where a film and another member are laminated, a pressure sensitive adhesive such as Optical Clear Adhesive (OCA) is used for bonding. In the bonding process, the pressure sensitive adhesive and the film are pressure-bonded by a roller or the like, and accordingly, a variation in pressure is expected to occur. It is considered that at this time, because a portion to which high pressure is applied is deformed to have a size such that the portion can be visually recognized as asperities, the glass quality may deteriorate.

Meanwhile, in a case where the maximum value of the loss tangent (tan δ) of the pressure sensitive adhesive layer becomes equal to or greater than a specific value in a specific temperature range, the pressure sensitive adhesive layer can consume the pressure in the bonding process not by deformation but by conversion into heat. Presumably, this mechanism may work together with the reduction of an absolute amount of the pressure sensitive adhesive by decreasing the thickness of the pressure sensitive adhesive layer to a certain extent, and as a result, the occurrence of asperities of the resin film may be inhibited.

(Surface Roughness Sa of Resin Film in Laminate)

The surface roughness Sa of the resin film in the laminate means a surface roughness of a surface, which is opposite to the surface having the pressure sensitive adhesive layer, measured in a state where the resin film and the pressure sensitive adhesive layer are laminated (hereinafter, simply referred to as surface roughness Sa as well). The surface roughness Sa is different from a surface roughness of a simple resin film that will be described later.

The surface roughness Sa of the resin film measured in a visual field of 4 mm×5 mm is equal to or lower than 30 nm, preferably equal to or lower than 20 nm, more preferably less than 15 nm, even more preferably less than 10 nm, still more preferably equal to or lower than 9 nm, yet more preferably equal to or lower than 8 nm, much more preferably equal to or lower than 7 nm, particularly preferably equal to or lower than 6 nm, and most preferably equal to or lower than 5 nm. The lower limit of the surface roughness Sa is substantially equal to or higher than 1 nm. Furthermore, the surface roughness Sa of the resin film measured in a visual field of 120 μm×120 μm is preferably equal to or lower than 20 nm, more preferably equal to or lower than 5 nm, and even more preferably equal to or lower than 3 nm. The lower limit of the surface roughness Sa is substantially equal to or higher than 1 nm.

In a case where the resin film has another layer such as a hardcoat layer, which will be described later, on a surface (hereinafter, referred to as surface of a viewing side surface as well) which is opposite to the surface having the pressure sensitive adhesive layer, “surface roughness Sa of the resin film” described above means a surface roughness Sa of the resin film that is measured in the state of the laminate in which the resin film is positioned on the uppermost surface of the viewing side of the laminate. That is, in the laminate of the embodiment of the present invention having a hardcoat layer, the surface roughness Sa means a surface roughness Sa of the resin film in the state of the laminate of the resin film, on which the hardcoat layer is not yet being laminated, and the pressure sensitive adhesive layer.

(Thickness of Resin Film)

The thickness of the resin film is preferably equal to or greater than 80 μm, more preferably equal to or greater than 90 μm, and even more preferably equal to or greater than 100 μm. The upper limit of the thickness of the resin film is substantially equal to or smaller than 300 μm.

Hereinafter, each layer constituting the laminate of the embodiment of the present invention will be specifically described.

(1) Resin Film

(Material of Resin Film)

The material of the resin film used in the present invention is not particularly limited, as long as the surface roughness Sa of the resin film in the laminated state that is measured in a visual field of 4 mm×5 mm is equal to or lower than 30 nm in a case where the laminate is formed.

Examples of the resin film include an acrylic resin film, a polycarbonate (PC)-based resin film, a triacetyl cellulose (TAC)-based resin film, a polyethylene terephthalate (PET)-based resin film, a polyolefin-based resin film, a polyester-based resin film, and an acrylonitrile-butadiene-styrene copolymer film. Among these, a resin film selected from an acrylic resin film, a triacetyl cellulose-based resin film, a polyethylene terephthalate-based resin film, and a polycarbonate-based resin film is preferable.

The acrylic resin film refers to a resin film of a polymer or a copolymer formed of one or more kinds of compounds selected from the group consisting of an acrylic acid ester and a methacrylic acid ester. Examples of the acrylic resin film include a polymethyl methacrylate resin (PMMA) film.

(Constitution of Resin Film)

The constitution of the resin film is not limited. The resin film may be a single layer film or a laminated film including two or more layers, and is preferably a laminated film including two or more layers, the number of layers laminated to constitute the laminated film is preferably 2 to 10, more preferably 2 to 5, and even more preferably 2 or 3. In a case where the resin film includes three or more layers, it is preferable that outer layers and layers (core layers and the like) other than the outer layers are films of different compositions. Furthermore, it is preferable that the outer layers are films of the same composition.

Specifically, examples thereof include films having laminated structures of TAC-a/TAC-b/TAC-a, acryl-a/PC/acryl-a, and PET-a/PET-b/PET-a, and a film constituted with one polycarbonate-based resin layer. Herein, the films (for example, Tac-a) marked with the same reference (a or b) are films of the same composition.

(Additives)

The resin film may contain additives in addition to the resin described above. Examples of the additives include inorganic particles, matt particles, an ultraviolet absorber, a fluorine-containing compound, a surface conditioner, a leveling agent, and the like described later regarding the hardcoat layer which will be described later.

In a melt film-forming method which will be described later, a molten resin obtained by mixing and melting the aforementioned additives and resin together can be used for forming the resin film. In a solution film-forming method which will be described later, a dope solution obtained by mixing a solvent (description regarding a hardcoat which will be described later can be adopted), the resin, and the above additives together can be used for forming the resin film.

(Surface Roughness of Simple Resin Film)

A surface roughness of a simple resin film measured in a visual field of 4 mm×5 mm before the resin film and a pressure sensitive adhesive layer are laminated is equal to or lower than 30 nm, more preferably equal to or lower than 20 nm, even more preferably equal to or lower than 10 μm, and most preferably equal to or lower than 5 nm. Furthermore, a surface roughness of the simple resin film measured in a visual field of 120 μm×120 μm is preferably equal to or lower than 20 nm, more preferably equal to or lower than 5 nm, and even more preferably equal to or lower than 3 nm. In a case where the simple resin film has the aforementioned preferable surface roughness, it is easy for the resin film to have the aforementioned specific surface roughness Sa even in the laminate of a specific pressure sensitive adhesive layer and the resin film used in the present invention, and the laminate readily exhibits excellent glass quality.

(Thickness of Simple Resin Film)

The thickness of the resin film substantially does not change before and after the preparation of the laminate of the embodiment of the present invention. Therefore, from the viewpoint of pencil hardness or keystroke durability, the thickness of the simple resin film measured before the resin film and the pressure sensitive adhesive layer are laminated is preferably equal to or greater than 80 run, more preferably equal to or greater than 90 μm, and even more preferably equal to or greater than 100 μm. The upper limit of the thickness of the simple resin film is substantially equal to or smaller than 300 μm.

(Easily Adhesive Layer)

The resin film used in the present invention may have an easily adhesive layer. For the easily adhesive layer, the details of an easily adhesive layer on a polarizer side and a manufacturing method of the easily adhesive layer on a polarizer side described in paragraphs “0098” to “0133” in JP2015-224267A can be combined with the present invention and incorporated into the present specification.

(Method for Forming Resin Film)

The resin film may be formed by any method as long as the surface roughness Sa of the resin film (preferably the surface roughness Sa of the resin film and the surface roughness of the simple resin film) is within the aforementioned range. For example, a melt film-forming method and a solution film-forming method can be used.

<Melt Film-Forming Method and Smoothing>

In a case where the resin film is formed by a melt film-forming method, the method preferably includes a melting step of melting a resin by using an extruder, a step of extruding the molten resin in the form of a sheet from a die, and a step of forming the resin into a film. Depending on the material of the resin, a step of filtering the molten resin may be performed after the melting step, or the molten resin may be cooled at the time of being extruded in the form of a sheet.

Hereinafter, the melt film-forming method will be specifically described, but the present invention is not limited thereto.

[Method for Forming Resin Film]

The method for manufacturing the resin film includes a melting step of melting a resin by using an extruder, a filtering step of filtering the molten resin through a filtering apparatus equipped with a filter, a film forming step of forming a non-stretched resin film by extruding the filtered resin in the form of a sheet from a die and then bringing the resin into close contact with the surface of a cooling drum so as to cool and solidify the resin, and a stretching step of uniaxially or biaxially stretching the non-stretched resin film.

The resin film can be manufactured by the above constitution. It is preferable that the pore size of the filter used in the filtering step of the molten resin is equal to or smaller than 1 μm, because then foreign substances can be thoroughly removed, and as a result, the surface roughness of the obtained resin film in the film width direction can be controlled.

Specifically, the method for forming the resin film can include the following steps.

<Melting Step>

The method for manufacturing the resin film includes a melting step of melting a resin by using an extruder.

It is preferable that a resin or a mixture of a resin and additives is dried until the moisture content becomes equal to or lower than 200 ppm and then melted by being introduced into a single screw (one screw) or double screw extruder. At this time, in order to inhibit the decomposition of the resin, it is also preferable to melt the resin or the mixture in nitrogen or a vacuum. Specifically, the melting can be performed according to JP4962661B by adopting the conditions described in paragraphs “0051” and “0052” in the same publication (paragraphs “0085” and “0086” in US2013/0100378). The details described in the publication are incorporated into the present specification.

As the extruder, a single screw kneading extruder is preferable.

Furthermore, in order to improve transport accuracy of the molten resin (melt), it is preferable to use a gear pump.

<Filtering Step>

The method for manufacturing the resin film includes a filtering step of filtering the molten resin through a filtering apparatus equipped with a filter. The pore size of the filter used in the filtering step is preferably equal to or smaller than 1 μm.

As the filtering apparatus used in the filtering step that includes a filter having a pore size within the above range, one set of filtering apparatus or two or more sets of filtering apparatuses may be provided.

<Film Forming Step>

The method for manufacturing the resin film includes a film forming step of forming a non-stretched resin film by extruding the filtered resin in the form of a sheet from a die and bringing the resin into close contact with the surface of a cooling drum so as to cool and solidify the resin.

In a case where the resin (melt containing the resin), which has been melted (and kneaded) and filtered, is extruded in the form of a sheet from a die, the resin may be extruded as a single layer or multiple layers. In a case where the resin is extruded as multiple layers, for example, a layer containing an ultraviolet absorber and a layer free of an ultraviolet absorber may be laminated. It is preferable that the resin is extruded as a sheet constituted with three layers in which a layer containing an ultraviolet absorber becomes an inner layer, because such a constitution can inhibit a polarizer from deteriorating due to ultraviolet rays and can inhibit the bleed out of the ultraviolet absorber.

In a case where the resin film is manufactured by being extruded as multiple layers, the ratio of the thickness of the inner layer of the obtained resin film to the total thickness of all the layers is preferably equal to or higher than 50% and equal to or lower than 98%, more preferably equal to or higher than 50% and equal to or lower than 95%, even more preferably equal to or higher than 60% and equal to or lower than 95%, particularly preferably equal to or higher than 60% and equal to or lower than 90%, and most preferably equal to or higher than 70% and equal to or lower than 85%. These layers can be laminated by using a feed block die, a multi-manifold die, or the like.

The non-stretched resin film (original film) is preferably obtained by extruding the resin (melt containing the resin), which has been extruded in the form of a sheet from a die, on a cooling drum (casting drum) and cooling and solidifying the resin according to paragraph “0059” in JP2009-269301A.

In the method for manufacturing the resin film, the temperature of the resin extruded from a die is preferably equal to or higher than 280° C. and equal to or lower than 320° C., and more preferably equal to or higher than 285° C. and equal to or lower than 310° C. It is preferable that the temperature of the resin extruded from a die in the melting step is equal to or higher than 280° C., because then the occurrence of foreign substances is inhibited by the reduction of melting residues of the raw material resin, the surface roughness in the film width direction can be controlled to be low in the following cross-direction stretching step, and hence the glass quality of the laminate can be improved. Furthermore, it is preferable that the temperature of the resin extruded from a die in the melting step is equal to or lower than 320° C., because then the occurrence of foreign substances is inhibited by suppressing the decomposition of the resin, the surface roughness in the film width direction can be controlled and to be low in the following cross-direction stretching step, and hence the glass quality of the laminate can be unproved.

The temperature of the resin extruded from a die can be measured on the surface of the resin in a non-contact manner by using a radiation thermometer (manufactured by Hayashi Denko co ltd., model number: RT61-2, used at a radiation factor of 0.95).

In a case where the resin is brought into close contact with the surface of the cooling drum in the film forming step of the method for manufacturing the resin film, it is preferable to use a static electricity applying electrode. In a case where such an electrode is used, the resin can be strongly brought into close contact with the surface of the cooling drum such that the surface shape of the film is not destroyed, the surface roughness in the film width direction can be controlled to be low in the following cross-direction stretching step, and as a result, the glass quality of the laminate can be improved.

In the method for manufacturing the resin film, at the time of bringing the resin into close contact with the surface of the cooling drum (at a point in time when the molten resin having extruded from a die contacts the cooling drum for the first time), the temperature of the resin is preferably equal to or higher than 280° C. In a case where the temperature of the resin is as described above, the electrical conductivity of the resin is improved, the resin can be strongly brought into close contact with the cooling drum by applying static electricity, and the destruction of the surface shape of the film can be inhibited. Therefore, the glass quality of the laminate can be improved.

The temperature of the resin at the time of bringing the resin into close contact with the surface of the cooling drum can be measured on the surface of the resin in a non-contact manner by using a radiation thermometer (manufactured by Hayashi Denko co ltd., model number: RT61-2, used at a radiation factor of 0.95).

<Stretching Step>

The method for manufacturing the resin film includes a stretching step of uniaxially or biaxially stretching the non-stretched resin film.

In a vertical stretching step (step of stretching the resin film in the same direction as the transport direction of the film), the resin film is preheated, and then in a state where the resin film stays hot, the resin film is stretched in the transport direction by a group of rollers having different circumferential speeds (that is, rollers having different transport speeds).

In the vertical stretching step, the preheating temperature is preferably equal to or higher than the glass transition temperature (Tg) of the resin film −40° C. and equal to or lower than Tg +60° C., more preferably equal to or higher than Tg −20° C. and equal to or lower than Tg +40° C., and even more preferably equal to or higher than Tg and equal to or lower than Tg +30° C. Furthermore, in the vertical stretching step, the stretching temperature is preferably equal to or higher than Tg and equal to or lower than Tg −60° C., more preferably Tg +2° C. and equal to or lower than Tg +40° C., and even more preferably equal to or higher than Tg+5° C. and equal to or lower than Tg +30° C. The stretching ratio in the vertical direction is preferably equal to or higher than 100% and equal to or lower than 250%, and more preferably equal to or higher than 110% and equal to or lower than 200%.

By the cross-direction stretching step (step of stretching the resin film in a direction perpendicular to the transport direction of the film) performed in addition to or instead of the vertical stretching step, the film is horizontally stretched in the width direction. In the cross-direction stretching step, for example, a tenter can be suitably used. By using the tenter, both ends of the resin film in the width direction are held by grips, and the resin film is stretched in the cross direction. By the cross-direction stretching, the surface roughness of the simple resin film can be adjusted, and the surface roughness Sa of the resin film in the laminate can be made fall into the aforementioned specific range.

The cross-direction stretching is preferably performed using a tenter. The stretching temperature is preferably equal to or higher than the glass transition temperature (Tg) of the resin film and equal to or lower than Tg +60° C., more preferably equal to or higher than Tg+2° C. and equal to or lower than Tg +40° C., and even more preferably equal to or higher than Tg +4° C. and equal to or lower than Tg +30° C. The stretching ratio is preferably equal to or higher than 100% and equal to or lower than 500%, and more preferably equal to or higher than 110% and equal to or lower than 400%. It is also preferable to allow the resin film to relax in either or both of the vertical direction and the cross direction after the cross-direction stretching.

It is preferable that the resin film is stretched such that the change in the thickness becomes equal to or smaller than 10%, preferably becomes equal to or smaller than 8%, more preferably becomes equal to or smaller than 6%, even more preferably becomes equal to or smaller than 4%, and most preferably becomes equal to or smaller than 2% in both a place in the width direction and a place in the longitudinal direction.

The change in the thickness can be determined as below.

A 10 m (meter) sample is taken from the stretched resin film. Except for 20% of both ends of the resin film in the film width direction, from the central portion of the film, 50 spots are sampled at equal intervals in the width direction and the longitudinal direction respectively, and thicknesses thereof are measured.

An average thickness Th_{TD-av}, a maximum thickness Th_{TD-max}, and a minimum thickness Th_{TD-min} in the width direction are determined, and the change in the thickness in the width direction is calculated by (Th_{TD-max}−Th_{TD-min})÷Th_{TD-av}×100 [%].

Furthermore, an average thickness Th_{MD-av}, a maximum thickness Th_{MD-max}, and a minimum thickness Th_{MD-min} in the longitudinal direction are determined, and the change in the thickness in the longitudinal direction is calculated by (Th_{MD-max}−Th_{MD-min})+Th_{MD-av}×100 [%].

By the aforementioned stretching step, the thickness accuracy of the resin film can be improved, and the surface roughness of the simple resin film can be reduced.

The resin film having undergone stretching can be wound up in the form of a roll by a winding step. At this time, the winding tension of the resin film is preferably set to be equal to or lower than 0.02 kg/mm².

Regarding the details of other conditions, for the melt film-forming method, the contents described in paragraphs “0134” to “0148” in JP2015-224267A can be combined with the present invention and incorporated into the present specification, and for the stretching step, the contents described in JP2007-137028A can be combined with the present invention and incorporated into the present specification.

<Solution Film-Forming Method and Smoothing>

In a case where the resin film is formed by a solution film-forming method, it is preferable that the method includes a step of forming a casting film by casting a dope solution on a casting band, a step of drying the casting film, and a step of stretching the casting film. Specifically, it is preferable to form the resin film by the method described in JP4889335B.

In the present invention, it is preferable to adopt the following method such that the surface roughness Sa of the resin film obtained by the solution film-forming method falls into the specific range described above.

For example, it is possible to adopt the method described in JP1999-123732A (JP-H11-123732A) in which a drying rate of the casting film is set to be equal to or lower than 300% by mass/min (=5% by mass/s) in terms of the content of a solvent based on the dry measure such that the film is gradually dried. Furthermore, for example, it is possible to adopt the method described in JP2003-276037A in which in a co-casting method of a casting film having a multilayer structure including a skin layer (outer layer) on both surfaces of a core layer as an interlayer, the viscosity of a dope solution for forming the core layer is increased such that the hardness of the casting film is secured while the viscosity of a dope for forming the outer layer is reduced. In addition, for examples, a method of forming a film on the surface of a casting film by rapidly drying the casting film and smoothing the surface shape by the leveling effect of the formed film, a method of stretching a casting film, and the like are also preferable.

(2) Pressure Sensitive Adhesive Layer

The material of the pressure sensitive adhesive layer used in the present invention is not particularly limited, as long as the maximum value of the loss tangent (tan δ) of the pressure sensitive adhesive layer at a frequency of 1 Hz is found in a temperature range of 0° C. to −40° C., and is equal to or greater than 1.3. The pressure sensitive adhesive layer may be a pressure sensitive adhesive or an adhesive. Examples thereof include an acrylic pressure sensitive adhesive, a urethane-based pressure sensitive adhesive, a synthetic rubber-based pressure sensitive adhesive, a natural rubber-based pressure sensitive adhesive, and a silicon-based pressure sensitive adhesive. Among these, an acrylic pressure sensitive adhesive is preferable. Particularly, from the viewpoint of the productivity, a pressure sensitive adhesive is preferable which contains an ionizing radiation-curable group (functional group which can be cured by causing a polymerization reaction, a crosslinking reaction, or the like by being irradiated with ionizing radiation, such as an ethylenically unsaturated linking group (—CH═CH₂) like a (meth)acryloyl group, a vinyl group, or an allyl group, an epoxy group, and the like) and can be cured by ionizing radiation.

The thickness of the pressure sensitive adhesive layer is equal to or smaller than 100 μm, preferably equal to or smaller than 50 μm, and more preferably equal to or smaller than 15 μm. Provided that the pressure sensitive adhesive layer is too thick, in a case where a laminate is formed by pressure-bonding the resin film and the pressure sensitive adhesive layer by using a roller or the like, a variation in pressure occurs, and as a result, sometimes a laminate having a predetermined surface roughness Sa cannot be obtained.

Hereinafter, as a specific aspect, a pressure sensitive adhesive layer containing an acrylic pressure sensitive adhesive will be described, but the present invention is not limited to the following specific aspect.

(Specific Aspect of Pressure Sensitive Adhesive Layer)

Examples of the acrylic pressure sensitive adhesive include an acrylic pressure sensitive adhesive containing at least a (meth)acrylic acid ester polymer A having a weight-average molecular weight of 500,000 to 3,000,000, and an acrylic pressure sensitive adhesive containing a component (hereinafter, referred to as “crosslinked polymer”) obtained by crosslinking the (meth)acrylic acid ester polymer A and a (meth)acrylic acid ester polymer B having a weight-average molecular weight of 8,000 to 300,000.

By increasing the proportion of the (meth)acrylic acid ester polymer B having a smaller weight-average molecular weight between the (meth)acrylic acid ester polymer A and the (meth)acrylic acid ester polymer B constituting the crosslinked polymer, the stress relaxation efficiency of the pressure sensitive adhesive layer can be increased. By decreasing the proportion of the (meth)acrylic acid ester polymer B, the stress relaxation efficiency of the pressure sensitive adhesive layer can be reduced. In the constituent components of the crosslinked polymer, the proportion of the (meth)acrylic acid ester polymer B with respect to 100 parts by mass of the (meth)acrylic acid ester polymer A is preferably within a range of 5 to 50 parts by mass, and more preferably within a range of 10 to 30 parts by mass.

For the details of the (meth)acrylic acid ester polymer A and the (meth)acrylic acid ester polymer B, paragraphs “0020” to “0046” in JP2012-214545A can be referred to. Furthermore, for the details of crosslinking agents for crosslinking these, paragraphs “0049” to “0058” in JP2012-214545A can be referred to.

The acrylic pressure sensitive adhesive can contain and preferably contains a silane coupling agent. For the details of the silane coupling agent, paragraphs “0059” to “0061” in JP2012-214545A can be referred to. Furthermore, for the details of the method for preparing the acrylic pressure sensitive adhesive and the additives and solvents which can be optionally incorporated into the acrylic pressure sensitive adhesive, paragraphs “0062” to “0071” in JP2012-214545A can be referred to.

In an aspect, the acrylic pressure sensitive adhesive is applied to a release-treated surface of a release sheet having undergone a release treatment and dried so as to form a pressure sensitive adhesive layer, and in this way, a pressure sensitive adhesive sheet including the pressure sensitive adhesive layer can be formed. By bonding the pressure sensitive adhesive layer of the pressure sensitive adhesive sheet to the resin film, the laminate of the embodiment of the present invention can be formed.

(3) Hardcoat Layer (HC Layer)

In another preferable aspect, a laminate 4B of the embodiment of the present invention preferably has at least a hardcoat layer (hereinafter, referred to as “HC layer” as well) 3A on a surface, which is opposite to the surface having the pressure sensitive adhesive layer 2A, of the resin film 1A (that is, the laminate preferably has at least the pressure sensitive adhesive layer 2A, the resin film 1A disposed on one surface of the pressure sensitive adhesive layer 2A, and the HC layer 3A disposed on the resin film 1A) as shown in FIG. 2. The HC layer may be constituted with any material as long as desired pencil hardness can be imparted to the laminate.

Hereinafter, a specific aspect of the HC layer will be described, but the present invention is not limited to the following aspect.

(HC Layer Obtained by Curing a Curable Composition for Forming Hardcoat Layer (HC Layer))

The HC layer used in the present invention can be obtained by curing a curable composition for forming an HC layer by irradiating the composition with active energy rays. In the present invention and in the present specification, “active energy rays” refer to ionizing radiation, and include X-rays, ultraviolet rays, visible light, infrared rays, electron beams, a rays, β rays, γ rays, and the like.

The curable composition for forming an HC layer used for forming the HC layer contains at least one kind of component (hereinafter, described as “active energy ray-curable component” as well) having a property of being cured by the irradiation of active energy rays. As the active energy ray-curable component, at least one kind of polymerizable compound is preferable which is selected from the group consisting of a radically polymerizable compound and a cationically polymerizable compound. In the present invention and the present specification, “polymerizable compound” is a compound containing one or more polymerizable groups in one molecule. The polymerizable group is a group which can take a part in a polymerization reaction, and specific examples thereof include groups contained in various polymerizable compounds which will be described later. Examples of the polymerization reaction include various polymerization reactions such as radical polymerization, cationic polymerization, and anionic polymerization.

The HC layer used in the present invention may have a single layer structure or a laminated structure including two or more layers, but is preferably an HC layer having a single layer structure or a laminated structure including two or more layers that will be specifically described below.

1) Single Layer Structure

Examples of the preferable aspect of the curable composition for forming an HC layer having a single layer structure include, as a first aspect, a curable composition for forming an HC layer containing at least one kind of polymerizable compound having two or more ethylenically unsaturated groups in one molecule. The ethylenically unsaturated group refers to a functional group containing an ethylenically unsaturated double bond. Furthermore, as a second aspect, a curable composition for forming an HC layer can be exemplified which contains at least one kind of radically polymerizable compound and at least one kind of cationically polymerizable compound.

Hereinafter, the curable composition for forming an HC layer of the first aspect will be described.

Examples of the polymerizable compound having two or more ethylenically unsaturated groups in one molecule that is contained in the curable composition for forming an HC layer of the first aspect include ester compounds of a polyhydric alcohol and (meth)acrylic acid [for example, ethylene glycol di(meth)acrylate, butanediol di(meth)acrylate, hexanediol di(meth)acrylate, (cyclohexane-1,4-diyl)diacrylate, pentaerythritol tetra(meth)acrylate, pentaerythritol tri(meth)acrylate, trimethylolpropane tri(meth)acrylate, trimethylolethane tri(meth)acrylate, dipentaerythritol tetra(meth)acrylate, dipentaerythritol penta(meth)acrylate, dipentaerythritol hexa(meth)acrylate, pentaerythritol hexa(meth)acrylate, (cyclohexane-1,2,3-toluyl)trimethacrylate, polyurethane polyacrylate, and polyester polyacrylate], ethylene oxide-modified products, polyethylene oxide-modified products, and caprolactone-modified products of the above ester compounds, vinyl benzene and derivatives thereof [for example, 1,4-divinylbenzene, 4-vinylbenzoic acid-2-acryloyl ethyl ester, and 1,4-divinylcyclohexanone], vinyl sulfone [for example, divinyl sulfone], acrylamide [for example, methylenebisacrylamide], and methacrylamide.

In the present specification, “(meth)acrylate” means either or both of acrylate and methacrylate. Furthermore, “(meth)acryloyl group” which will be described later means either or both of an acryloyl group and a methacryloyl group. “(Meth)acryl” means either or both of acryl and methacryl.

One kind of polymerizable compound described above may be used singly, or two or more kinds of polymerizable compounds described above having different structures may be used in combination. Likewise, regarding each component described in the present specification, one kind of component may be used singly, or two or more kinds of components having different structures may be used in combination. In a case where two or more kinds of components having different structures are used in combination, the content of each component means the total content thereof.

The polymerizable compound having an ethylenically unsaturated group can be polymerized by the irradiation of active energy rays in the presence of a radical photopolymerization initiator. As the radical photopolymerization initiator, a radical photopolymerization initiator which will be described later is preferably used. As the ratio of the content of the radical photopolymerization initiator to the content of polymerizable compound having an ethylenically unsaturated group in the curable composition for forming an HC layer, the description of the ratio of the content of the radical photopolymerization initiator to the content of the radically polymerizable compound that will be explained layer is preferably adopted.

Next, the curable composition for forming an HC layer of the second aspect will be described.

The curable composition for forming an HC layer of the second aspect contains at least one kind of radically polymerizable compound and at least one kind of cationically polymerizable compound. As a preferable aspect, a curable composition for forming an HC layer can be exemplified which contains a radically polymerizable compound containing two or more radically polymerizable groups selected from the group consisting of an acryloyl group and a methacryloyl group in one molecule; and a cationically polymerizable compound.

It is preferable that the curable composition for forming an HC layer contains a radical photopolymerization initiator and a cationic photopolymerization initiator. As a preferable aspect of the second aspect, a curable composition for forming an HC layer can be exemplified which contains a radically polymerizable compound containing two or more radically polymerizable groups selected from the group consisting of an acryloyl group and a methacryloyl group in one molecule; a cationically polymerizable compound; a radical photopolymerization initiator; and a cationic photopolymerization initiator. Hereinafter, this aspect will be described as second aspect (1).

In the second aspect (1), it is preferable that the radically polymerizable compound contains two or more radically polymerizable groups in one molecule and one or more urethane bonds in one molecule.

As another preferable aspect of the second aspect, a curable composition for forming an HC layer can be exemplified which contains a) cationically polymerizable compound containing an alicyclic epoxy group and an ethylenically unsaturated group and having a molecular weight equal to or smaller than 300, in which the number of alicyclic epoxy groups contained in one molecule is 1 and the number of ethylenically unsaturated groups contained in one molecule is 1; b) radically polymerizable compound containing three or more ethylenically unsaturated groups in one molecule; c) radical polymerization initiator; and d) cationic polymerization initiator. Hereinafter, this aspect will be described as second aspect (2). Regarding the HC layer obtained by curing the curable composition for forming an HC layer of the second aspect (2), provided that the total solid content of the HC layer is equal to or greater than 100% by mass, the HC layer can contain a structure derived from a) in an amount of 15% to 70% by mass, a structure derived from b) in an amount of 25% to 80% by mass, a structure derived from c) in an amount of 0.1% to 10% by mass, and a structure derived from d) in an amount of 0.1% to 10% by mass. In an aspect, provided that the total solid content of the curable composition for forming an HC layer is 100% by mass, it is preferable that the curable composition for forming an HC layer of the second aspect (2) contains a) in an amount of 15% to 70% by mass. “Alicyclic epoxy group” means a monovalent functional group having a cyclic structure in which an epoxy ring and a saturated hydrocarbon-based ring are fused.

Hereinafter, each of the components which can be contained in the curable composition for forming an HC layer of the second aspect and preferably the second aspect (1) or the second aspect (2) will be more specifically described.

—Radically Polymerizable Compound—

The curable composition for forming an HC layer of the second aspect contains at least one kind of radically polymerizable compound and at least one kind of cationically polymerizable compound.

(Radically Polymerizable Compound in Second Aspect (1))

The radically polymerizable compound in the second aspect (1) contains two or more radically polymerizable groups selected from the group consisting of an acryloyl group and a methacryloyl group in one molecule. The number of radically polymerizable groups selected from the group consisting of an acryloyl group and a methacryloyl group that can be contained in one molecule of the radically polymerizable compound is preferably 2 to 10 for example, and more preferably 2 to 6.

As the radically polymerizable compound, a radically polymerizable compound having a molecular weight equal to or greater than 200 and less than 1,000 is preferable. In the present invention and the present specification, for a multimer, “molecular weight” refers to a weight-average molecular weight which is measured by Gel Permeation Chromatography (GPC) and expressed in terms of polystyrene. As an example of specific measurement conditions of the weight-average molecular weight, the following measurement conditions can be exemplified.
GPC apparatus: HLC-8120 (manufactured by Tosoh Corporation)
Column: TSK gel Multipore HXL-M (manufactured by Tosoh Corporation, inner diameter of 7.8 mm×column length of 30.0 cm)
Eluent: tetrahydrofuran

As described above, the radically polymerizable compound preferably contains one or more urethane bonds in one molecule. The number of urethane bonds contained in one molecule of the radically polymerizable compound is preferably equal to or greater than 1, more preferably equal to or greater than 2, and even more preferably 2 to 5. For example, the radically polymerizable compound can contain two urethane bonds in one molecule. In the radically polymerizable compound containing two urethane bonds in one molecule, the radically polymerizable group selected from the group consisting of an acryloyl group and a methacryloyl group may be bonded to one of the urethane bonds directly or through a linking group or may be bonded to each of the two urethane bonds directly or through a linking group. In an aspect, it is preferable that one or more radically polymerizable groups selected from the group consisting of an acryloyl group and a methacryloyl group are bonded to each of two urethane bonds bonded to each other through a linking group.

More specifically, in the radically polymerizable compound, a urethane bond and a radically polymerizable group selected from the group consisting of an acryloyl group and a methacryloyl group may be directly bonded to each other, or a linking group may be present between a urethane bond and a radically polymerizable group selected from the group consisting of an acryloyl group and a methacryloyl group. The linking group is not particularly limited, and examples thereof include a linear or branched saturated or unsaturated hydrocarbon group, a cyclic group, a group obtained by combining two or more of these groups, and the like. The number of carbon atoms on the hydrocarbon group is about 2 to 20 for example but is not particularly limited. As an example of a cyclic structure contained in the cyclic group, an aliphatic ring (such as a cyclohexane ring), an aromatic ring (such as a benzene ring or a naphthalene ring), or the like can be exemplified. These groups may be unsubstituted or may have a substituent. Unless otherwise specified, a group described in the present invention and the present specification may have a substituent or may be unsubstituted. In a case where a certain group has a substituent, examples of the substituent include an alkyl group (such as an alkyl group having 1 to 6 carbon atoms), a hydroxyl group, an alkoxy group (such as an alkoxy group having 1 to 6 carbon atoms), a halogen atom (such as a fluorine atom, a chlorine atom, or a bromine atom), a cyano group, an amino group, a nitro group, an acyl group, a carboxy group, and the like.

The radically polymerizable compound described so far can be synthesized by a known method, or may be obtained as a commercial product. As an example of the synthesis method, a method can be exemplified in which an alcohol, a polyol, and/or a hydroxyl group-containing compound such as hydroxyl group-containing (meth)acrylate are reacted with an isocyanate, and then, if necessary, a urethane compound obtained by the reaction is esterified using (meth)acrylic acid. Herein, “(meth)acrylic acid” means either or both of acrylic acid and methacrylic acid.

Examples of commercial products of the radically polymerizable compound containing one or more urethane bonds in one molecule include, but are not limited to, UA-306H, UA-306I, UA-306T, UA-510H, UF-8001G, UA-101I, UA-101T, AT-600, AH-600, AI-600, BPZA-66, and BPZA-100 (trade names) manufactured by KYOEISHA CHEMICAL Co., LTD., U-4HA, U-6HA, U-6LPA, UA-32P, U-15HA, and UA-1100H manufactured by SHIN-NAKAMURA CHEMICAL CO., LTD., SHIKOH UV-1400B, SHIKOH UV-1700B, SHIKOH UV-6300B, SHIKOH UV-7550B, SHIKOH UV-7600B, SHIKOH UV-7605B, SHIKOH UV-7610B, SHIKOH UV-7620EA, SHIKOH UV-7630B, SHIKOH UV-7640B, SHIKOH UV-6630B, SHIKOH UV-7000B, SHIKOH UV-7510B, SHIKOH UV-7461TE, SHIKOH UV-3000B, SHIKOH UV-3200B, SHIKOH UV-3210EA, SHIKOH UV-3310EA, SHIKOH UV-3310B. SHIKOH UV-3500BA, SHIKOH UV-3520TL, SHIKOH UV-3700B, SHIKOH UV-6100B, SHIKOH UV-6640B, SHIKOH UV-2000B, SHIKOH UV-2010B, SHIKOH UV-2250EA, and SHIKOH UV-2750B (trade names) manufactured by NIPPON GOHSEI, UL-503LN manufactured by KYOEISHA CHEMICAL Co., LTD., UNIDIC 17-806. UNIDIC 17-813, UNIDIC V-4030, and UNIDIC V-4000BA manufactured by DIC Corporation, EB-1290K manufactured by Daicel-UCB Company. Ltd., HI-COAP AU-2010 and HI-COAP AU-2020 manufactured by TOKUSHIKI Co., Ltd., and the like.

As specific examples of the radically polymerizable compound containing one or more urethane bond in one molecule, example compounds A-1 to A-8 will be shown below, but the present invention is not limited to the following specific examples.

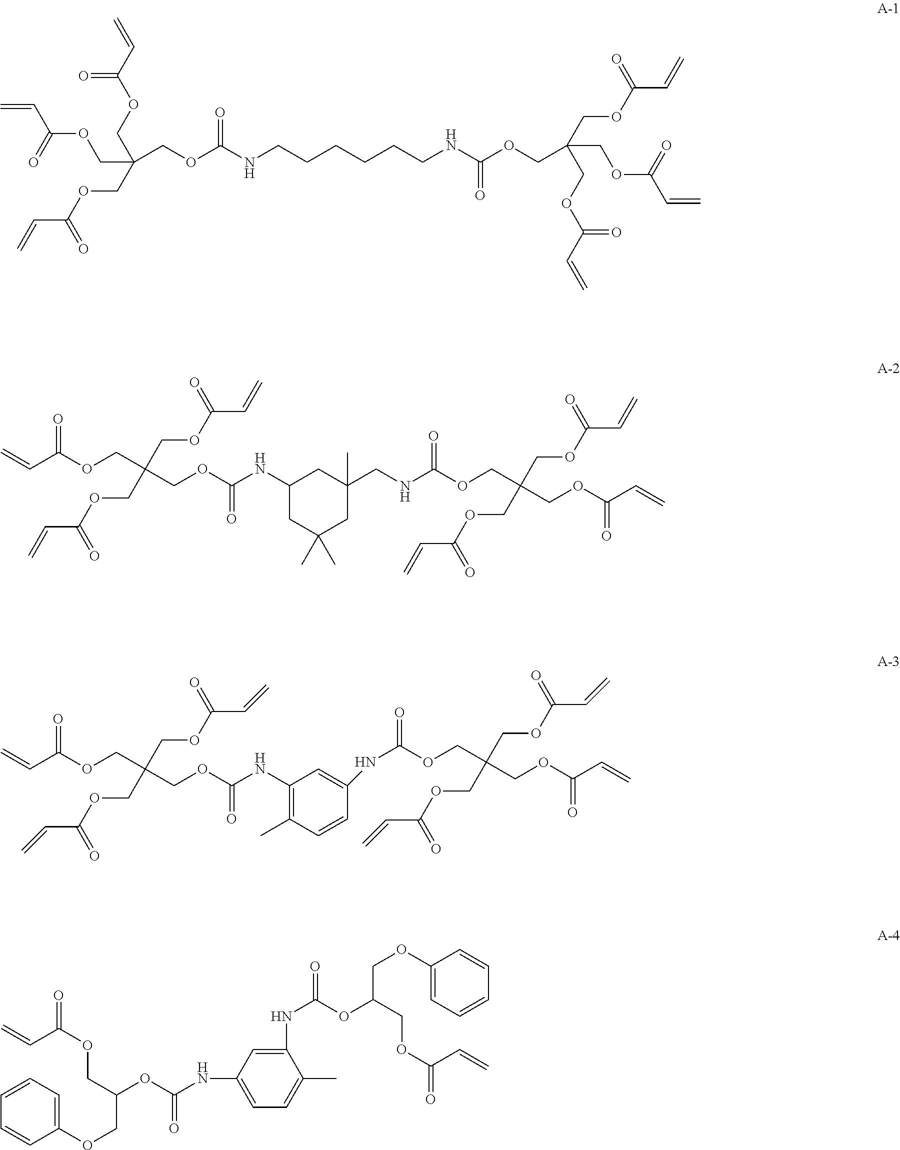

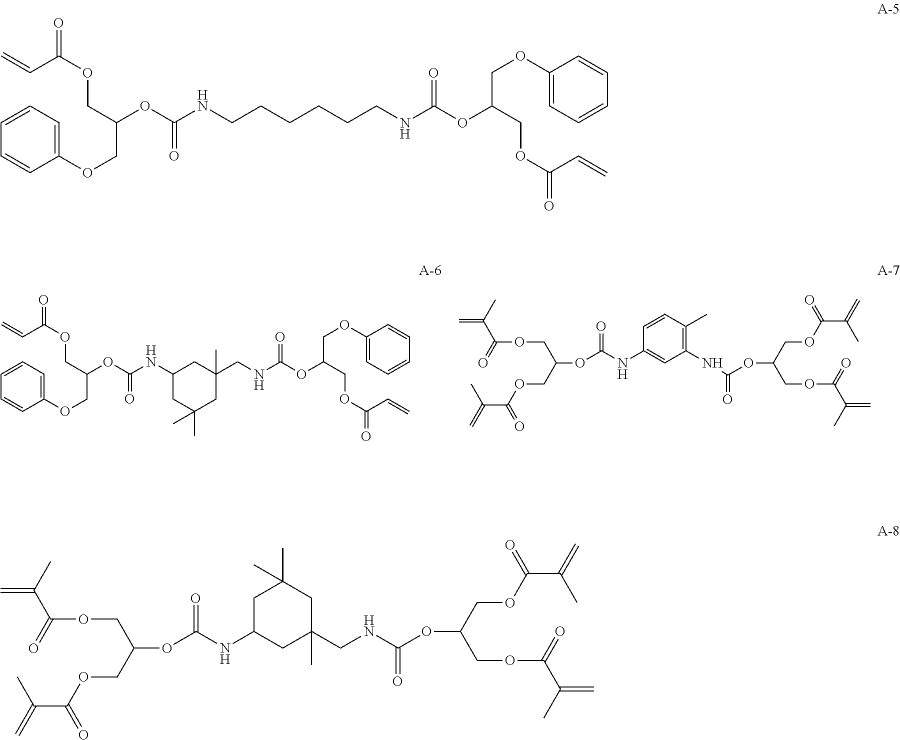 [SMILES: C=CC(=O)OCC(COc1ccccc1)OC(=O)NCCCCCCNC(=O)OC(COC(=O)C=C)COc1ccccc1 ; C=CC(=O)OCC(COc1ccccc1)OC(=O)NCC1(C)CC(NC(=O)OC(COC(=O)C=C)COc2ccccc2)CC(C)(C)C1 ; C=C(C)C(=O)OCC(COC(=O)C(=C)C)OC(=O)Nc1ccc(C)c(NC(=O)OC(COC(=O)C(=C)C)COC(=O)C(=C)C)c1 ; C=C(C)C(=O)OCC(COC(=O)C(=C)C)OC(=O)NCC1(C)CC(NC(=O)OC(COC(=O)C(=C)C)COC(=O)C(=C)C)CC(C)(C)C1]

Hitherto, the radically polymerizable compound containing one or more urethane bonds in one molecule has been described. The radically polymerizable compound containing two or more radically polymerizable groups selected from the group consisting of an acryloyl group and a methacryloyl group in one molecule may not have a urethane bond. Furthermore, the curable composition for forming an HC layer of the second aspect (1) may contain, in addition to the radically polymerizable compound containing two or more radically polymerizable groups selected from the group consisting of an acryloyl group and a methacryloyl group in one molecule, one or more kinds of radically polymerizable compounds other than the above radically polymerizable compound.

Hereinafter, the radically polymerizable compound which contains two or more radically polymerizable groups selected from the group consisting of an acryloyl group and a methacryloyl group in one molecule and contains one or more urethane bonds in one molecule will be described as “first radically polymerizable compound”, and a radically polymerizable compound which does not correspond to the first radically polymerizable compound will be described as “second radically polymerizable compound” regardless of whether or not the radically polymerizable compound contains two or more radically polymerizable groups selected from the group consisting of an acryloyl group and a methacryloyl group in one molecule. The second radically polymerizable compound may have one or more urethane bonds in one molecule or may not have a urethane bond. In a case where the first radically polymerizable compound and the second radically polymerizable compound are used in combination, the mass ratio of first radically polymerizable compound/second radically polymerizable compound is preferably 3/1 to 1/30, more preferably 2/1 to 1/20, and even more preferably 1/1 to 1/10.

In the curable composition for forming an HC layer of the second aspect (1), the content of the radically polymerizable compound (it does not matter whether or not this compound contains a urethane bond) containing two or more radically polymerizable groups selected from the group consisting of an acryloyl group and a methacryloyl group in one molecule is preferably equal to or greater than 30% by mass, more preferably equal to or greater than 50% by mass, and even more preferably equal to or greater than 70% by mass, with respect to the total amount, 100% by mass, of the composition. Furthermore, in the curable composition for forming an HC layer of the second aspect (1), the content of the radically polymerizable compound (it does not matter whether or not this compound contains a urethane bond) containing two or more radically polymerizable groups selected from the group consisting of an acryloyl group and a methacryloyl group in one molecule is preferably equal to or smaller than 98% by mass, more preferably equal to or smaller than 95% by mass, and even more preferably equal to or smaller than 90% by mass, with respect to the total amount, 100% by mass, of the composition.

The content of the first radically polymerizable compound in the curable composition for forming an HC layer of the second aspect (1) with respect to the total amount, 100% by mass, of the composition is preferably equal to or greater than 30% by mass, more preferably equal to or greater than 50% by mass, and even more preferably equal to or greater than 70% by mass. Meanwhile, the content of the first radically polymerizable compound with respect to the total amount, 100% by mass, of the composition is preferably equal to or smaller than 98% by mass, more preferably equal to or smaller than 95% by mass, and even more preferably equal to or smaller than 90% by mass.

In an aspect, the second radically polymerizable compound is preferably a radically polymerizable compound which contains two or more radically polymerizable groups in one molecule and does not have a urethane bond. The radically polymerizable group contained in the second radically polymerizable compound is preferably an ethylenically unsaturated group. In an aspect, the radically polymerizable group is preferably a vinyl group. In another aspect, the ethylenically unsaturated group is preferably a radically polymerizable group selected from the group consisting of an acryloyl group and a methacryloyl group. That is, it is preferable that the second radically polymerizable compound has one or more radically polymerizable groups selected from the group consisting of an acryloyl group and a methacryloyl group in one molecule and does not have a urethane bond. Furthermore, as a radically polymerizable compound, the second radically polymerizable compound can contain one or more radically polymerizable groups selected from the group consisting of an acryloyl group and a methacryloyl group and one or more radically polymerizable groups other than this in one molecule.

The number of radically polymerizable groups contained in one molecule of the second radically polymerizable compound is preferably at least 2, more preferably equal to or greater than 3, and even more preferably equal to or greater than 4. In an aspect, the number of radically polymerizable groups contained in one molecule of the second radically polymerizable compound is equal to or less than 10 for example, but may be greater than 10. As the second radically polymerizable compound, a radically polymerizable compound having a molecular weight equal to or greater than 200 and less than 1,000 is preferable.

The following compounds can be exemplified as the second radically polymerizable compound, but the present invention is not limited to the following example compounds.

Examples of the second radically polymerizable compound include bifunctional (meth)acrylate compounds such as polyethylene glycol 200 di(meth)acrylate, polyethylene glycol 300 di(meth)acrylate, polyethylene glycol 400 di(meth)acrylate, polyethylene glycol 600 di(meth)acrylate, triethylene glycol di(meth)acrylate, epichlorohydrin-modified ethylene glycol di(meth)acrylate (as a commercial product, for example, DENACOL DA-811 (trade name) manufactured by NAGASE & CO., LTD.), polypropylene glycol 200 di(meth)acrylate, polypropylene glycol 400 di(meth)acrylate, polypropylene glycol 700 di(meth)acrylate, Ethylene Oxide (hereinafter, abbreviated to “EO” as well). Propylene Oxide (hereinafter, abbreviated to “PO” as well) block polyether di(meth)acrylate (as a commercial product, for example, a BLEMMER PET (trade name) series manufactured by NOF CORPORATION), dipropylene glycol di(meth)acrylate, bisphenol A EO addition-type di(meth)acrylate (as a commercial product, for example, M-210 (trade name) manufactured by TOACGOSEI CO., LTD, or NK ESTER A-BPE-20 (trade name) manufactured by SHIN-NAKAMURA CHEMICAL CO., LTD.), hydrogenated bisphenol A EO addition-type di(meth)acrylate (such as NK ESTER A-HPE-4 (trade name) manufactured by SHIN-NAKAMURA CHEMICAL CO., LTD.), bisphenol A PO-addition type di(meth)acrylate (as a commercial product, for example, LIGHT ACRYLATE BP-4PA (trade name) manufactured by KYOEISHA CHEMICAL Co., LTD.), bisphenol A epichlorohydrin addition-type di(meth)acrylate (as a commercial product, for example, EBECRYL 150 (trade name) manufactured by Daicel-UCB Company, Ltd.), bisphenol A EO-PO addition-type di(meth)acrylate (as a commercial product, for example, BP-023-PE (trade name) manufactured by TOHO Chemical Industry Co., Ltd.), bisphenol F EO addition-type di(meth)acrylate (as a commercial product, for example, ARONIX M-208 (trade name) manufactured by TOAGOSEI CO., LTD.), 1,6-hexanediol di(meth)acrylate, 1,6-hexanediol di(meth)acrylate modified with epichlorohydrin, neopentyl glycol di(meth)acrylate, hydroxypivalic acid neopentyl glycol di(meth)acrylate, hydroxypivalic acid neopentyl glycol di(meth)acrylate modified with caprolactone, 1,4-butanediol di(meth)acrylate, 1,9-nonanediol di(meth)acrylate, trimethylolpropane di(meth)acrylate, tricyclodecane dimethanol di(meth)acrylate, pentaerythritol di(meth)acrylate monostearate, trimethylolpropane acrylic acid-benzoic acid ester, and isocyanuric acid EO-modified di(meth)acrylate (as a commercial product, for example, ARONIX M-215 (trade name) manufactured by TOAGOSEI CO., LTD.).

Examples of the second radically polymerizable compound also include trifunctional (meth)acrylate compounds such as trimethylolpropane tri(meth)acrylate, trimethylolpropane tri(meth)acrylate modified with EO, PO, or epichlorohydrin, pentaerythritol tri(meth)acrylate, glycerol tri(meth)acrylate, glycerol tri(meth)acrylate modified with EO, PO, or epichlorohydrin, isocyanuric acid EO-modified tri(meth)acrylate (as a commercial product, for example, ARONLX M-315 (trade name) manufactured by TOAGOSEI CO., LTD.), tris(meth)acryloyloxyethyl phosphate, (2,2,2-tri-(meth)acryloyloxymethyl)ethyl hydrogen phthalate, glycerol tri(meth)acrylate, and glycerol tri(meth)acrylate modified with EO, PO, or epichlorohydrin; tetrafunctional (meth)acrylate compounds such as pentaerythritol tetra(meth)acrylate, pentaerythritol tetra(meth)acrylate modified with EO. PO, or epichlorohydrin, and ditrimethylolpropane tetra(meth)acrylate; pentafunctional (meth)acrylate compounds such as dipentaerythritol penta(meth)acrylate and dipentaerythritol penta(meth)acrylate modified with EO, PO, epichlorohydrin, fatty acid, or alkyl; and hexafunctional (meth)acrylate compounds such as dipentaerythritol hexa(meth)acrylate, dipentaerythritol hexa(meth)acrylate modified with EO, PO, epichlorohydrin, fatty acid, or alkyl, sorbitol hexa(meth)acrylate, and sorbitol hexa(meth)acrylate modified with EO, PO, epichlorohydrin, fatty acid, or alkyl.

Two or more kinds of second radically polymerizable compounds may be used in combination. In this case, a mixture “DPHA” (trade name, manufactured by Nippon Kayaku Co., Ltd) of dipentaerythritol pentaacrylate and dipentaerythritol hexaacrylate and the like can be preferably used.

As the second radically polymerizable compound, polyester (meth)acrylate and epoxy (meth)acrylate having a weight-average molecular weight equal to or greater than 200 and less than 1,000 are also preferable. Examples thereof include commercial polyester (meth)acrylate products such as a BEAMSET (trade name) 700 series (such as BEAMSET 700 (hexafimctional), BEAMSET 710 (tetrafunctional), and BEAMSET 720 (trifunctional)) manufactured by Arakawa Chemical Industries, Ltd. Examples of the epoxy (meth)acrylate include an SP series (such as SP-1506, 500, SP-1507, and 480 (trade names)) as well as a VR series (such as VR-77) manufactured by Showa Highpolymer Co., Ltd., EA-1010/ECA, EA-11020, EA-1025, EA-6310ECA (trade names) manufactured by SHIN-NAKAMURA CHEMICAL CO., LTD., and the like.

Specific examples of the second radically polymerizable compound also include the following example compounds A-9 to A-11.

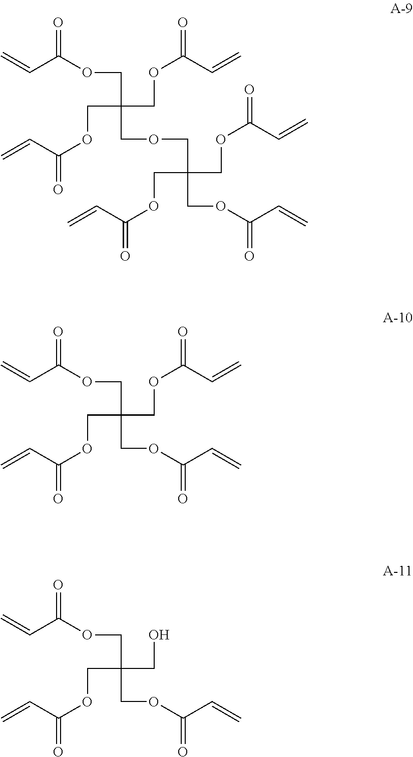

(Radically Polymerizable Compound in Second Aspect (2))

The curable composition for forming an HC layer of the second aspect (2), which is a preferable aspect of the second aspect, contains b) radically polymerizable compound containing three or more ethylenically unsaturated groups in one molecule. Hereinafter, b) compound containing three or more ethylenically unsaturated groups in one molecule will be described as “b) component” as well.

Examples of b) component include an ester of a polyhydric alcohol and (meth)acrylic acid, vinyl benzene and a derivative thereof, vinyl sulfone, (meth)acrylamide, and the like. Among these, a radically polymerizable compound containing three or more radically polymerizable groups selected from the group consisting of an acryloyl group and a methacryloyl group in one molecule is preferable. Specifically, examples thereof include a compound which is an ester of a polyhydric alcohol and (meth)acrylic acid and contains three or more ethylenically unsaturated groups in one molecule. More specifically, examples thereof include (di)pentaerythritol tetra(meth)acrylate, (di)pentaerythritol tri(meth)acrylate, trimethylolpropane tri(meth)acrylate, EO-modified trimethylolpropane tri(meth)acrylate, PO-modified trimethylolpropane tri(meth)acrylate, EO-modified phosphoric acid tri(meth)acrylate, trimethylolethane tri(meth)acrylate, ditrimethylolpropane tetra(meth)acrylate, dipentaerythritol tetra(meth)acrylate, (di)pentacrythritol penta(meth)acrylate, dipentaerythritol hexa(meth)acrylate, pentaerythritol hexa(meth)acrylate, (cyclohexane-1,2,3-triyl) trimethacrylate, polyurethane polyacrylate, polyester polyacrylate, caprolactone-modified tris(acryloxyethyl)isocyanurate, tripentaerythritol triacrylate, tripentaerythritol hexatriacrylate, (cyclohexane-1,2,4-triyl) tri(meth)acrylate, pentaglycerol triacrylate, and the like. “(Di)pentaerythritol” described above means either or both of pentaerythritol and dipentaerythritol.

Furthermore, a resin is also preferable which contains three or more radically polymerizable groups selected from the group consisting of an acryloyl group and a methacryloyl group in one molecule.

Examples of the resin containing three or more radically polymerizable groups selected from the group consisting of an acryloyl group and a methacryloyl group in one molecule include a polyester-based resin, a polyether-based resin, an acrylic resin, an epoxy-based resin, a urethane-based resin, an alkyd-based resin, a spiroacetal-based resin, a polybutadiene-based resin, a polythiol polyene-based resin, a polymer of a polyfunctional compound such as a polyhydric alcohol, and the like.

Specific examples of the radically polymerizable compound containing three or more radically polymerizable groups selected from the group consisting of an acryloyl group and a methacryloyl group in one molecule include example compounds described in paragraph “0096” in JP2007-256844A, and the like.

Specific examples of the radically polymerizable compound containing three or more radically polymerizable groups selected from the group consisting of an acryloyl group and a methacryloyl group in one molecule include esterified substances of a polyol and (meth)acrylic acid such as KAYARAD DPHA, KAYARAD DPHA-2C, KAYARAD PET-30, KAYARAD TMPTA, KAYARAD TMPTA-320, KAYARAD TPA-330, KAYARAD RP-1040, KAYARAD T-1420, KAYARAD D-310, KAYARAD DPCA-20, KAYARAD DPCA-30, KAYARAI DPCA-60, and KAYARAD GPO-303 (trade names) manufactured by Nippon Kayaku Co., Ltd., and V#400 and V#36095D (trade names) manufactured by OSAKA ORGANIC CHEMICAL INDUSTRY LTD. Furthermore, it is also possible to suitably use urethane acrylate compounds having three or more functional groups such as SHIKOH UV-1400B, SHIKOH UV-1700B, SHIKOH UV-6300B, SHIKOH UV-7550B, SHIKOH UV-7600B, SHIKOH UV-7605B, SHIKOH UV-7610B, SHIKOH UV-7620EA, SHIKOH UV-7630B, SHIKOH UV-7640B, SHIKOH UV-6630B, SHIKOH UV-7000B, SHIKOH UV-7510B, SHIKOH UV-7461TE, SHIKOH UV-3000B, SHIKOH UV-3200B, SHIKOH UV-3210EA, SHIKOH UV-3310EA, SHIKOH UV-3310B, SHIKOH UV-3500BA, SHIKOH UV-3520TL. SHIKOH UV-3700B, SHIKOH UV-6100B, SHIKOH UV-6640B, SHIKOH UV-2000B, SHIKOH UV-2010B, SHIKOH UV-2250EA, and SHIKOH UV-2750B (trade names, manufactured by NIPPON GOHSEI), UL-503LN (trade name, manufactured by KYOEISHA CHEMICAL Co., LTD), UNIDIC 17-806, UNIDIC 17-813, UNIDIC V-4030, and UNIDIC V-4000BA (trade names, manufactured by DIC Corporation), EB-1290K, EB-220, EB-5129, EB-1830, and EB-4358 (trade names, manufactured by Daicel-UCB Company, Ltd.), HI-COAP AU-2010 and HI-COAP AU-2020 (trade names, manufactured by TOKUSHIKI Co., Ltd.), ARONIX M-1960 (trade name, manufactured by TOAGOSET CO., LTD.), and ART RESIN UN-3320HA, UN-3320HC, UN-3320HS, UN-904, and HDP-4T (trade names), polyester compounds having three or more functional groups such as ARONIX M-8100, M-8030, and M-9050 (trade names, manufactured by TOAGOSEI CO., LTD.) and KBM-8307 (trade name, manufactured by Daicel SciTech), and the like.

As b) component, one kind of component may be used singly, or two or more kinds of components having different structures may be used in combination.

As described above, regarding the HC layer obtained by curing the curable composition for forming an HC layer of the second aspect (2), provided that the total solid content of the HC layer is 100% by mass, the HC layer can contain a structure derived from a) in an amount of 15% to 70% by mass, a structure derived from b) in an amount of 25% to 80% by mass, a structure derived from c) in an amount of 0.1% to 10% by mass, and a structure derived from d) in an amount of 0.1% to 10% by mass. Provided that the total solid content of the HC layer is 100% by mass, the content of the structure derived from b) in the HC layer is preferably 40% to 75% by mass, and more preferably 60% to 75% by mass. Furthermore, provided that the total solid content of the curable composition for forming an HC layer of the second aspect (2) is 100% by mass, the content of b) component in the composition is preferably 40% to 75% by mass, and more preferably 60% to 75% by mass.

—Cationically Polymerizable Compound—

The curable composition for forming an HC layer of the second aspect contains at least one kind of radically polymerizable compound and at least one kind of cationically polymerizable compound. Any of cationically polymerizable compounds can be used without limitation as long as the compounds have a polymerizable group which can be cationically polymerized (cationically polymerizable group). The number of cationically polymerizable groups contained in one molecule is at least 1. The cationically polymerizable compound may be a monofunctional compound containing one cationically polymerizable group or a polyfunctional compound containing two or more cationically polymerizable groups. The number of cationically polymerizable groups contained in the polyfunctional compound is not particularly limited. For example, the polyfunctional compound contains 2 to 6 cationically polymerizable groups in one molecule. Furthermore, the polyfunctional compound may contain two or more kinds of cationically polymerizable groups, which are the same as each other or have different structures, in one molecule.

In addition, in an aspect, it is preferable that the cationically polymerizable compound has one or more radically polymerizable groups in one molecule together with the cationically polymerizable groups. Regarding the radically polymerizable group that the cationically polymerizable compound has, the above description for the radically polymerizable compound can be referred to. The radically polymerizable group is preferably an ethylenically unsaturated group, and the ethylenically unsaturated group is more preferably a radically polymerizable group selected from the group consisting of a vinyl group, an acryloyl group, and a methacryloyl group. The number of radically polymerizable groups in one molecule of the cationically polymerizable compound having a radically polymerizable group is at least 1, preferably 1 to 3, and more preferably 1.

As the cationically polymerizable group, an oxygen-containing heterocyclic group and a vinyl ether group can be preferably exemplified. The cationically polymerizable compound may contain one or more oxygen-containing heterocyclic groups and one or more vinyl ether groups in one molecule.

The oxygen-containing heterocyclic ring may be a monocyclic ring or a condensed ring. Furthermore, it is also preferable that the oxygen-containing heterocyclic ring has a bicyclo skeleton. The oxygen-containing heterocyclic ring may be a non-aromatic ring or an aromatic ring, and is preferably a non-aromatic ring. Specific examples of the monocyclic ring include an epoxy ring, a tetrahydrofuran ring, and an oxetane ring. Examples of the oxygen-containing heterocyclic ring having a bicyclo skeleton include an oxabicyclo ring. The cationically polymerizable group containing the oxygen-containing heterocyclic ring is contained in the cationically polymerizable compound as a monovalent substituent or a polyvalent substituent with a valency of 2 or higher. The aforementioned condensed ring may be a ring formed by the condensation of two or more oxygen-containing heterocyclic rings or a ring formed by the condensation of one or more oxygen-containing heterocyclic rings and one or more ring structures other than the oxygen-containing heterocyclic ring. The ring structure other than the oxygen-containing heterocyclic ring is not limited to the above, and examples thereof include a cycloalkane ring such as a cyclohexane ring.

Specific examples of the oxygen-containing heterocyclic ring will be shown below, but the present invention is not limited to the following specific examples.

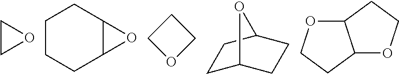

The cationically polymerizable compound may have a partial structure other than the cationically polymerizable group. The partial structure is not particularly limited, and may be a linear, branched, or cyclic structure. The partial structure may contain one or more heteroatoms such as oxygen atoms or nitrogen atoms.

As a preferable aspect of the cationically polymerizable compound, a compound (hereinafter, referred to as “cyclic structure-containing compound” as well) can be exemplified which has a cyclic structure as the cationically polymerizable group or as a partial structure other than the cationically polymerizable group. The cyclic structure-containing compound may have one cyclic structure in one molecule for example. The cyclic structure-containing compound may have two or more cyclic structures in one molecule. The number of cyclic structures contained in the cyclic structure-containing compound is preferably 1 to 5 for example, but is not particularly limited. In a case where the compound contains two or more cyclic structures in one molecule, the cyclic structures may be the same as each other. Alternatively, the compound may contain two or more kinds of cyclic structures having different structures.

As an example of the cyclic structure contained in the cyclic structure-containing compound, an oxygen-containing heterocyclic ring can be exemplified. The details of the oxygen-containing heterocyclic ring are as described above.

A cationically polymerizable group equivalent determined by dividing the molecular weight (hereinafter, described as “B”) by the number of cationically polymerizable groups (hereinafter, described as “C”) contained in one molecule of the cationically polymerizable compound (=B/C) is equal to or smaller than 300, for example. From the viewpoint of improving the adhesiveness between the HC layer obtained by curing the curable composition for forming an HC layer and the resin film, the cationically polymerizable group equivalent is preferably less than 150. In contrast, from the viewpoint of the hygroscopicity of the HC layer obtained by curing the curable composition for forming an HC layer, the cationically polymerizable group equivalent is preferably equal to or greater than 50. Furthermore, in an aspect, the cationically polymerizable group contained in the cationically polymerizable compound for which the cationically polymerizable group equivalent is determined is preferably an epoxy group (epoxy ring). That is, in an aspect, the cationically polymerizable compound is an epoxy ring-containing compound. For the epoxy ring-containing compound, from the viewpoint of improving the adhesiveness between the HC layer obtained by curing the curable composition for forming an HC layer and the resin film, an epoxy group equivalent, which is determined by dividing the molecular weight by the number of epoxy rings contained in one molecule, is preferably less than 150. The epoxy equivalent of the epoxy ring-containing compound is preferably equal to or greater than 50, for example.

The molecular weight of the cationically polymerizable compound is preferably equal to or smaller than 500, and more preferably equal to or smaller than 300. The lower limit of the molecular weight is not particularly limited, but is preferably equal to or greater than 100. Presumably, the cationically polymerizable compound whose molecular weight is within the above range tends to easily permeate the resin film and can make a contribution to the improvement of the adhesiveness between the HC layer obtained by curing the curable composition for forming an HC layer and the resin film.

The curable composition for forming an HC layer of the second aspect (2) contains a) cationically polymerizable compound containing an alicyclic epoxy group and an ethylenically unsaturated group and having molecular weight equal to or smaller than 300, in which the number of alicyclic epoxy groups contained in one molecule is 1, and the number of ethylenically unsaturated groups contained in one molecule is 1. Hereinafter, a) will be described as “a) component”.

Examples of the ethylenically unsaturated group include a radically polymerizable group including an acryloyl group, a methacryloyl group, a vinyl group, a styryl group, an allyl group, and the like. Among these, an acryloyl group, a methacryloyl group, or C(O)OCH═CH₂ is preferable, and an acryloyl group or a methacryloyl group is more preferable. Each of the number of alicyclic epoxy groups in one molecule and the number of ethylenically unsaturated groups in one molecule is preferably 1.

The molecular weight of a) component is equal to or smaller than 300, preferably equal to or smaller than 210, and more preferably equal to or smaller than 200. The lower limit of the molecular weight is not particularly limited, but is preferably equal to or greater than 100.

As a preferable aspect of a) component, a compound represented by the following General Formula (1) can be exemplified.

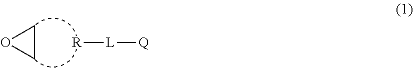

In General Formula (1), R represents a monocyclic hydrocarbon group or a crosslinked hydrocarbon group, L represents a single bond or a divalent linking group, and Q represents an ethylenically unsaturated group. Herein, R represents the entire ring represented by the broken line, and forms a fused ring structure together with the epoxy ring described in General Formula (1).

In a case where R in General Formula (1) is a monocyclic hydrocarbon group, the monocyclic hydrocarbon group is preferably an alicyclic hydrocarbon group, more preferably an alicyclic ring having 4 to 10 carbon atoms, even more preferably an alicyclic ring having 5 to 7 carbon atoms, and particularly preferably an alicyclic ring having 6 carbon atoms. Preferable specific examples thereof include a cyclobutyl group, a cyclopentyl group, a cyclohexyl group, a cycloheptyl group, and the like. Among these, a cyclohexyl group is more preferable.

In a case where R in General Formula (1) is a crosslinked hydrocarbon group, the crosslinked hydrocarbon group is preferably a bicyclic crosslinked hydrocarbon (bicyclo ring) group or a tricyclic crosslinked hydrocarbon (tricyclo ring) group. Specific examples thereof include a crosslinked hydrocarbon group having 5 to 20 carbon atoms such as a norbornyl group, a bornyl group, an isobornyl group, a tricyclodecyl group, a dicyclopentenyl group, a dicyclopentanyl group, a tricyclopentenyl group, a tricyclopentanyl group, an adamantyl group, or a lower alkyl group (having 1 to 6 carbon atoms for example)-substituted adamantyl group.

In a case where L represents a divalent linking group, the divalent linking group is preferably a divalent aliphatic hydrocarbon group. The number of carbon atoms in the divalent aliphatic hydrocarbon group is preferably within a range of 1 to 6, more preferably within a range of 1 to 3, and even more preferably 1. As the divalent aliphatic hydrocarbon group, a linear, branched, or cyclic alkylene group is preferable, a linear or branched alkylene group is more preferable, and a linear alkylene group is even more preferable.

Examples of Q include an ethylenically unsaturated group including an acryloyl group, a methacryloyl group, a vinyl group, a styryl group, an allyl group, or the like. Among these, an acryloyl group, a methacryloyl group, or C(O)OCH═CH₂ is preferable, and an acryloyl group or a methacryloyl group is more preferable.

Specific examples of a) component include various compounds exemplified in paragraph “0015” in JP1998-017614A (JP-H10-017614A), a compound represented by the following General Formula (1A) or (1B), 1,2-epoxy-4-vinylcyclohexane, and the like. Among these, the compound represented by the following General Formula (1A) or (1B) is more preferable. As the compound represented by the following General Formula (1A), an isomer thereof is also preferable.

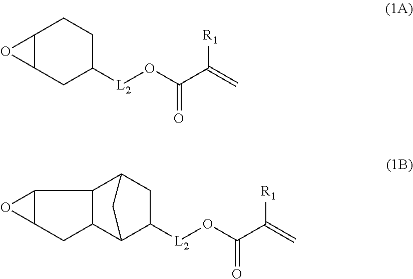

In General Formulae (1A) and (1B), R₁ represents a hydrogen atom or a methyl group, and L₂ represents a divalent aliphatic hydrocarbon group having 1 to 6 carbon atoms.

The number of carbon atoms in the divalent aliphatic hydrocarbon group represented by L₂ in General Formulae (1A) and (1B) is within a range of 1 to 6, more preferably in a range of 1 to 3, and even more preferably 1. As the divalent aliphatic hydrocarbon group, a linear, branched, or cyclic alkylene group is preferable, a linear or branched alkylene group is more preferable, and a linear alkylene group is even more preferable.

Regarding the HC layer obtained by curing the curable composition for forming an HC layer of the second aspect (2), provided that the total solid content of the HC layer is 100% by mass, the HC layer contains a structure derived from a) preferably in an amount of 15% to 70% by mass, more preferably in an amount of 18% to 50% by mass, and even more preferably in an amount of 22% to 40% by mass. Furthermore, provided that the total solid content of the curable composition for forming an HC layer of the second aspect (2) is 100% by mass, the composition contains a) component preferably in an amount of 15% to 70% by mass, more preferably in an amount of 18% to 50% by mass, and even more preferably in an amount of 22% to 40% by mass.

As another example of the cyclic structure contained in the cyclic structure-containing compound, a nitrogen-containing heterocyclic ring can be exemplified. The nitrogen-containing heterocyclic ring-containing compound is the cationically polymerizable compound which is preferable from the viewpoint of improving the adhesiveness between the HC layer obtained by curing the curable composition for forming an HC layer and the resin film. As the nitrogen-containing heterocyclic ring-containing compound, a compound is preferable which has one or more nitrogen-containing heterocyclic rings selected from the group consisting of an isocyanurate ring (nitrogen-containing heterocyclic ring contained in example compounds B-1 to B-3 which will be described later) and a glycoluril ring (nitrogen-containing heterocyclic ring contained in an example compound B-10 which will be described later) in one molecule. Among these, from the viewpoint improving the adhesiveness between the HC layer obtained by curing the curable composition for forming an HC layer and the resin film, the compound containing an isocyanurate ring (hereinafter, referred to as “isocyanurate ring-containing compound” as well) is a more preferably a cationically polymerizable compound. The inventors of the present invention assume that this is because the isocyanurate ring has excellent affinity with the resin constituting the resin film. In this respect, a resin film including an acrylic resin film is more preferable, and a resin film is more preferable which includes an acrylic resin film as a surface directly contacting the HC layer obtained by curing the curable composition for forming an HC layer.

As another example of the cyclic structure contained in the cyclic structure-containing compound, an alicyclic structure can be exemplified. Examples of the alicyclic structure include a cyclo ring structure, a dicyclo ring structure, and a tricyclo ring structure. Specific examples thereof include a dicyclopentanyl ring, a cyclohexane ring, and the like.

The cationically polymerizable compound described so far can be synthesized by a known method, and can be obtained as a commercial product.

Specific examples of the cationically polymerizable compound containing an oxygen-containing heterocyclic ring as a cationically polymerizable group include 3,4-epoxycyclohexylmethylmethacrylate (commercial products such as CYCLOMER M100 (trade name) manufactured by Daicel Corporation), 3,4-epoxycyclohexylmethyl-3′,4′-epoxycyclohexane carboxylate (for example, commercial products such as UVR 6105 and UVR 6110 (trade names) manufactured by Union Carbide Corporation and CELLOXIDE 2021 (trade name) manufactured by Daicel Corporation), bis(3,4-epoxycyclohexylmethyl)adipate (such as UVR 6128 (trade name) manufactured by Union Carbide Corporation), vinylcyclohexene monoepoxide (such as CELLOXIDE 2000 (trade name) manufactured by Daicel Corporation), ε-caprolactam-modified 3,4-epoxycyclohexylmethyl 3′,4′-epoxycyclohexane carboxylate (such as CELLOXIDE 2081 (trade name) manufactured by Daicel Corporation), 1-methyl-4-(2-methyloxiranyl)-7-oxabicyclo[4,1,0]heptane (such as CELLOXIDE 3000 (trade name) manufactured by Daicel Corporation), 7,7′-dioxa-3,3′-bi[bicyclo[4.1.0]heptane] (such as CELLOXIDE 8000 (trade name) manufactured by Daicel Corporation). 3-ethyl-3-hydroxymethyloxetane, 1,4 bis {[(3-ethyl-3-oxetanyl)methoxy]methyl}benzene, 3-ethyl-3-(phenoxymethyl)oxetane, 3-ethyl-3-(2-ethylhexyloxymethyl)oxetane, di[1-ethyl(3-oxetanyl)]methyl ether, and the like.

Specific examples of the cationically polymerizable compound containing a vinyl ether group as a cationically polymerizable group include 1,4-butanediol divinyl ether, 1,6-hexanediol divinyl ether, nonanediol divinyl ether, cyclohexanediol divinyl ether, cyclohexane dimethanol divinyl ether, triethylene glycol divinyl ether, trimethylolpropane trivinyl ether, pentaerythritol tetravinyl ether, and the like. As the cationically polymerizable compound containing a vinyl ether group, those having an alicyclic structure are also preferable.

Furthermore, as the cationically polymerizable compound, it is possible to use the compounds exemplified in JP1996-143806A (JP-H08-143806A), JP1996-283320A (JP-H08-283320A), JP2000-186079A, JP2000-327672A, JP2004-315778A, JP2005-029632A, and the like.

As specific examples of the cationically polymerizable compound, example compounds B-1 to B-14 will be shown below, but the present invention is not limited to the following specific examples.

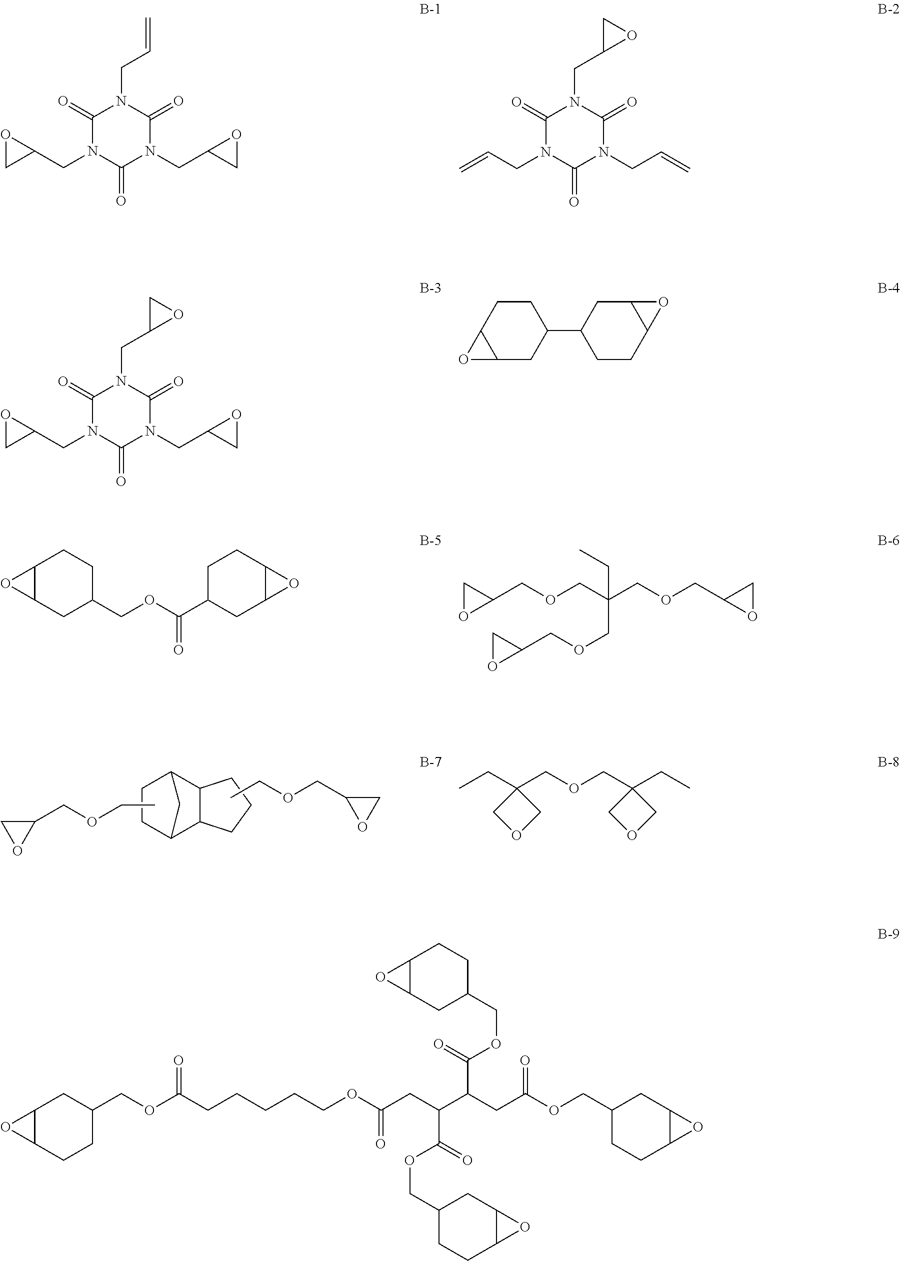

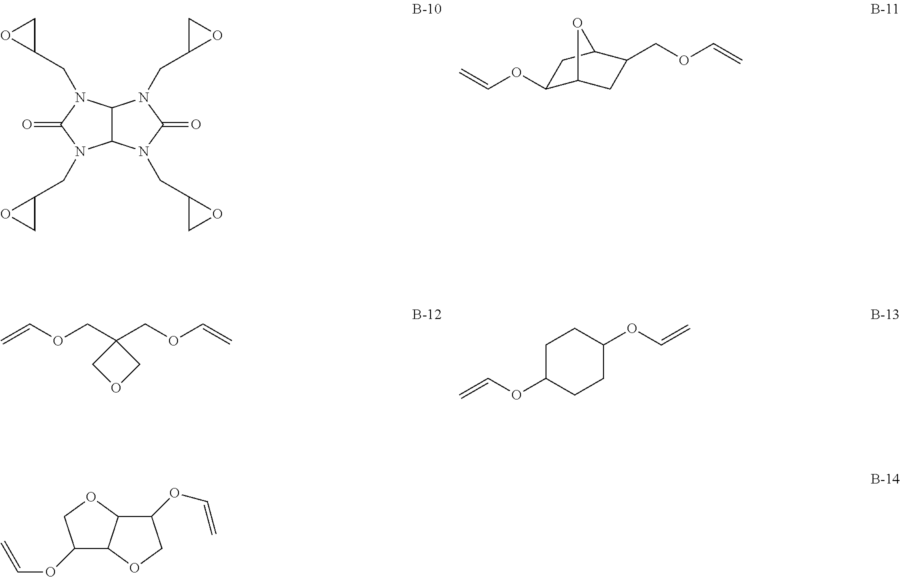 [SMILES: O=C1N(CC2CO2)C2C(N1CC1CO1)N(CC1CO1)C(=O)N2CC1CO1 ; C=COCC1CC2OC1CC2OC=C ; C=COCC1(COC=C)COC1 ; C=COC1CCC(OC=C)CC1 ; C=COC1COC2C(OC=C)COC12]

From the viewpoint of improving the adhesiveness between the HC layer obtained by curing the curable composition for forming an HC layer and the resin film, as preferable aspects of the curable composition for forming an HC layer, the following aspects (1) to (4) can be exemplified. The curable composition for forming an HC layer more preferably satisfies one or more aspects among the following aspects, even more preferably satisfies two or more aspects, still more preferably satisfies three or more aspects, and yet more preferably satisfies all of the following aspects. It is preferable that one cationically polymerizable compound satisfies a plurality of aspects. For example, an aspect is preferable in which the cationically polymerizable group equivalent of the nitrogen-containing heterocyclic ring-containing compound is less than 150.

(1) The curable composition for forming an HC layer contains a nitrogen-containing heterocyclic ring-containing compound as a cationically polymerizable compound. The nitrogen-containing heterocyclic ring contained in the nitrogen-containing heterocyclic ring-containing compound is preferably selected from the group consisting of an isocyanurate ring and a glycoluril ring. The nitrogen-containing heterocyclic ring-containing compound is more preferably an isocyanurate ring-containing compound. The isocyanurate ring-containing compound is even more preferably an epoxy ring-containing compound containing one or more epoxy rings in one molecule.

(2) The curable composition for forming an HC layer contains a cationically polymerizable compound having a cationically polymerizable group equivalent less than 150 as a cationically polymerizable compound, and preferably contains an epoxy group-containing compound having an epoxy group equivalent less than 150.

(3) The cationically polymerizable compound contains an ethylenically unsaturated group.

(4) The curable composition for forming an HC layer contains, as cationically polymerizable compounds, an oxetane ring-containing compound containing one or more oxetane rings in one molecule in addition to another cationically polymerizable compound. The oxetane ring-containing compound is preferably a compound which does not contain a nitrogen-containing heterocyclic ring.

The lower limit of the content of the cationically polymerizable compound in the curable composition for forming an HC layer with respect to the total content, 100 parts by mass, of the radically polymerizable compound and the cationically polymerizable compound is preferably equal to or greater than 10 parts by mass, more preferably equal to or greater than 15 parts by mass, and even more preferably equal to or greater than 20 parts by mass. The upper limit of the content of the cationically polymerizable compound in the curable composition for forming an HC layer with respect to the total content, 100 parts by mass, of the radically polymerizable compound and the cationically polymerizable compound is preferably equal to or smaller than 50 parts by mass.

The lower limit of the content of the cationically polymerizable compound in the curable composition for forming an HC layer with respect to the total content, 100 parts by mass, of the first radically polymerizable compound and the cationically polymerizable compound is preferably equal to or greater than 0.05 parts by mass, more preferably equal to or greater than 0.1 parts by mass, and even more preferably equal to or greater than 1 part by mass. Meanwhile, the upper limit of the content of the cationically polymerizable compound with respect to the total content, 100 parts by mass, of the first radically polymerizable compound and the cationically polymerizable compound is preferably equal to or smaller than 50 parts by mass, and more preferably equal to or smaller than 40 parts by mass.

In the present invention and the present specification, a compound having both the cationically polymerizable group and the radically polymerizable group is classified as a cationically polymerizable compound so as to specify content thereof in the curable composition for forming an HC layer.

—Polymerization Initiator—

The curable composition for forming an HC layer preferably contains a polymerization initiator, and more preferably contains a photopolymerization initiator. The curable composition for forming an HC layer containing the radically polymerizable compound preferably contains a radical photopolymerization initiator, and the curable composition for forming an HC layer containing the cationically polymerizable compound preferably contains a cationic photopolymerization initiator. Only one kind of radical photopolymerization initiator may be used, or two or more kinds of radical photopolymerization initiators having different structures may be used in combination. The same shall be applied for the cationic photopolymerization initiator.

Hereinafter, each of the photopolymerization initiators will be sequentially described.

(i) Radical Photopolymerization Initiator

The radical photopolymerization initiator may be a compound that generates a radical as an active species by light irradiation, and known radical photopolymerization initiators can be used without limitation. Specific examples thereof include acetophenones such as diethoxyacetophenone, 2-hydroxy-2-methyl-1-phenylpropan-1-one, benzyl dimethyl ketal, 4-(2-hydroxyethoxy)phenyl-(2-hydroxy-2-propyl)ketone, 1-hydroxycyclohexyl phenyl ketone, 2-methyl-2-morpholino-1-[4-(methylthio)phenyl]propan-1-one, 2-benzyl-2-dimethylamino-1-(4-morpholinophenyl)-1-butane, a 2-hydroxy-2-methyl-1-[4-(1-methylvinyl)phenyl]-1-propane oligomer, and 2-hydroxy-1-{4-[4-(2-hydroxy-2-methyl-propionyl)-benzyl]phenyl}-2-methyl-propan-1-one; oxime esters such as 1,2-octanedione, 1-[4-(phenylthio)phenyl]-,2-(O-benzoyloxime)], and ethanone, l-[9-ethyl-6-(2-methylbenzoyl)-9H-carbazol-3-yl]-, 1-(O-acetyloxime); benzoins such as benzoin, benzoin methyl ether, benzoin ethyl ether, benzoin isopropyl ether, and benzoin isobutyl ether, benzophenones such as benzophenone, methyl o-benzoyl benzoate, 4-phenylbenzophenone, 4-benzoyl-4′-methyl-diphenyl sulfide, 3,3′,4,4′-tetra(t-butylperoxycarbonyl)benzophenone, 2,4,6-trimethylbenzophenone, 4-benzoyl-N,N-dimethyl-N-[2-(1-oxo-2-propenyloxy)ethyl]benzene methanaminium bromide, and (4-benzoylbenzyl)trimethyl ammonium chloride; thioxanthones such as 2-isopropylthioxanthone, 4-isopropylthioxanthone, 2,4-diethylthioxanthone, 2,4-dichlorothioxanthone, 1-chloro-4-propoxythioxanthone, and 2-(3-dimethylamino-2-hydroxy)-3,4-dimethyl-9H-thioxanthone-9-one methochloride; acylphosphine oxides such as 2,4,6-trimethylbenzoyl-diphenylphosphine oxide, bis(2,6-dimethoxybenzoyl)-2,4,4-trimethyl-pentylphosphine oxide, and bis(2,4,6-trimethylbenzoyl)-phenylphosphine oxide; and the like.

Furthermore, as an aid for the radical photopolymerization initiator, triethanolamine, triisopropanolamine, 4,4′-dimethylaminobenzophenone (Michler's ketone). 4,4′-diethylaminobenzophenone, 2-dimethylaminoethyl benzoate, ethyl 4-dimethylaminobenzoate, (n-butoxy)ethyl 4-dimethylaminobenzoate, isoamyl 4-dimethylaminobenzoate, 2-ethylhexyl 4-dimethylaminobenzoate, 2,4-diethylthioxanthone, 2,4-diisopropylthioxanthone, and the like may be used in combination.

The aforementioned radical photopolymerization initiators and aids can be synthesized by a known method or can be obtained as commercial products. Examples of preferable commercial radical photopolymerization initiators include IRGACURE (trade name, 127, 651, 184, 819, 907, 1870 (CGI-403/Irg184=7/3 mixed initiator), 500, 369, 1173, 2959, 4265, 4263, OXE01, and the like) manufactured by BASF SE, KAYACURE (trade name, DETX-S, BP-100, BDMK, CTX, BMS, 2-EAQ, ABQ, CPTX, EPD, ITX, QTX, BTC, MCA, and the like) manufactured by Nippon Kayaku Co., Ltd., Esacure (trade name, KIP100F, KB1, EB3, BP, X33, KT046, KT37, KIPi50, TZT, and the like) manufactured by Sartomer, and the like.

The content of the radical photopolymerization initiator in the curable composition for forming an HC layer may be appropriately adjusted within a range in which the polymerization reaction (radical polymerization) of the radically polymerizable compound is excellently carried out, and is not particularly limited. The content of the radical photopolymerization initiator with respect to 100 parts by mass of the radically polymerizable compound contained in the curable composition for forming an HC layer is within a range of 0.1 to 20 parts by mass for example, preferably within a range of 0.5 to 10 parts by mass, and even more preferably within a range of 1 to 10 parts by mass.

(ii) Cationic Photopolymerization Initiator

As the cationic photopolymerization initiator, a compound which can generate a cation as an active species by light irradiation is preferable, and known cationic photopolymerization initiators can be used without limitation. Specific examples thereof include a sulfonium salt, an ammonium salt, an iodonium salt (such as a diaryl iodonium salt), a triaryl sulfonium salt, a diazonium salt, an iminium salt, and the like that are known. More specifically, examples thereof include the cationic photopolymerization initiators represented by Formulae (25) to (28) shown in paragraphs “0050” to “0053” in JP1996-143806A (JP-H08-143806A), the compounds exemplified as cationic polymerization catalysts in paragraph “0020” in JP1996-283320A (JP-H08-283320A), and the like. The cationic photopolymerization initiator can be synthesized by a known method, or can be obtained as a commercial product. For example, as the commercial product, it is possible to use CI-1370, CI-2064, CI-2397, CI-2624, CI-2639, CI-2734, CI-2758, CI-2823, CI-2855, CI-5102 (trade names), and the like manufactured by NIPPON SODA CO., LTD., PHOTOINITIATOR 2047 (trade name) and the like manufactured by Rhodia, UVI-6974 and UVI-6990 (trade names) manufactured by Union Carbide Corporation), CPI-IOP (trade name) manufactured by San-Apro Ltd., and the like.

In view of the sensitivity of the photopolymerization initiator with respect to light, the compound stability, and the like, a diazonium salt, an iodonium salt, a sulfonium salt, and an iminium salt are preferable as the cationic photopolymerization initiator. In view of weather fastness, an iodonium salt is most preferable.

Specific examples of commercial products of the iodonium salt-based cationic photopolymerization initiator include B2380 (trade name) manufactured by TOKYO CHEMICAL INDUSTRY CO., LTD., BBI-102 (trade name) manufactured by Midori Kagaku Co., Ltd., WPI-113, WPI-124, WPI-169, WPI-170 (trade names) manufactured by Wako Pure Chemical Industries, Ltd., and DTBPI-PFBS (trade name) manufactured by Toyo Gosei Co., Ltd.

Specific examples of iodonium salt compounds which can be used as the cationic photopolymerization initiator include the following compounds PAG-1 and PAG-2.

Cationic Photopolymerization Initiator (Iodonium Salt Compound) PAG-1

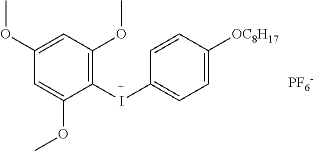

Cationic Photopolymerization Initiator (Iodonium Salt Compound) PAG-2

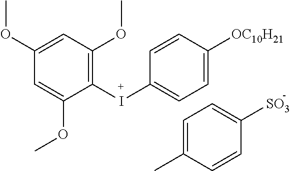

The content of the cationic photopolymerization initiator in the curable composition for forming an HC layer may be appropriately adjusted within a range in which the polymerization reaction (cationic polymerization) of the cationically polymerizable compound is excellently carried out, and is not particularly limited. The content of the cationic photopolymerization initiator with respect to 100 parts by mass of the cationically polymerizable compound is within a range of 0.1 to 200 parts by mass for example, preferably within a range of 1 to 150 parts by mass, and more preferably within a range of 2 to 100 parts by mass.

As other photopolymerization initiators, the photopolymerization initiators described in paragraphs “0052” to “0055” in JP2009-204725A can be exemplified, and the content of the publication is incorporated into the present invention.

—Components which can be Optionally Incorporated into Curable Composition for Forming HC Layer—

The curable composition for forming an HC layer contains at least one kind of component having a property of being cured by being irradiated with active energy rays, and can optionally contain at least one kind of polymerization initiator. It is preferable that the composition contains the polymerization initiator. The details of the polymerization initiator are as described above.

Next, each of the components that can be optionally incorporated into the curable composition for forming an HC layer will be described.

(i) Inorganic Particles

The curable composition for forming an HC layer can contain inorganic particles having an average primary particle diameter less than 2 μm. From the viewpoint of improving the hardness of the front panel having the HC layer obtained by curing the curable composition for forming an HC layer (and improving the hardness of a liquid crystal panel having the front panel), it is preferable that the curable composition for forming an HC layer and the HC layer obtained by curing the composition contain inorganic particles having an average primary particle diameter less than 2 μm. The average primary particle diameter of the inorganic particles is preferably within a range of 10 nm to 1 μm, more preferably within a range of 10 nm to 100 nm, and even more preferably within a range of 10 nm to 50 nm. For determining the average primary particle diameter of the inorganic particles and matt particles which will be described later, the particles are observed using a transmission electron microscope (500,000× to 2,000,000× magnification), randomly selected 100 particles (primary particles) are observed, and the average of the particle diameters thereof is taken as the average primary particle diameter.

Examples of the inorganic particles include silica particles, titanium dioxide particles, zirconium oxide particles, aluminum oxide particles, and the like. Among these, silica particles are preferable.

In order to improve the affinity of the inorganic particles with organic components contained in the curable composition for forming an HC layer, it is preferable that the surface of the inorganic particles is treated with a surface modifier including an organic segment. It is preferable that the surface modifier has a functional group, which can form a bond with the inorganic particles or can be adsorbed onto the inorganic particles, and a functional group, which has high affinity with an organic component, in the same molecule. As the surface modifier having a functional group which can form a bond with the inorganic particles or can be adsorbed onto the inorganic particles, a silane-based surface modifier, a metal alkoxide surface modifier having a metal alkoxide group such as aluminum, titanium, and zirconium, or a surface modifier having an anionic group such as a phosphoric acid group, a sulfuric acid group, a sulfonic acid group, or a carboxylic acid group is preferable. Examples of the functional group having high affinity with an organic component include a functional group having the same hydrophilicity and hydrophobicity as those of the organic component, a functional group which can be chemically bonded to the organic component, and the like. Among these, the functional group which can be chemically bonded to the organic component and the like are preferable, and an ethylenically unsaturated group or a ring-opening polymerizable group is more preferable.

As the surface modifier for the inorganic particles, a polymerizable compound is preferable which has a metal alkoxide group or an anionic group and an ethylenically unsaturated group or a ring-opening polymerizable group in the same molecule. By chemically bonding the inorganic particles and the organic components to each other by using these surface modifiers, and crosslinking density of the HC layer can be increased. As a result, the hardness of the front panel (and the hardness of a liquid crystal panel including the front panel) can be improved.

Specific examples of the surface modifier include the following example compounds S-1 to S-8.
S-1 H₂C═C(X)COOC₃H₆Si(OCH₃)₃
S-2 H₂C═C(X)COOC₂H₄OTi(OC₂H₅)₃
S-3 H₂C═C(X)COOC₂H₄OCOC₅H₁₀OPO(OH)₂
S-4 (H₂C═C(X)COOC₂H₄OCOC₅H₁₀O)₂POOH
S-5 H₂C═C(X)COOC₂H₄OSO₃H
S-6 H₂C═C(X)COO(C₅H₁₀COO)₂H
S-7 H₂C═C(X)COOC₅H₁₀COOH
S-8 CH₂—CH(O)CH₂OC₃H₆Si(OCH₃)₃
(X represents a hydrogen atom or a methyl group.)

It is preferable that the surface modification for the inorganic particles by the surface modifier is performed in a solution. The surface modification may be performed by a method in which a surface modifier is allowed to coexist at the time of mechanically dispersing the inorganic particles, a method in which the inorganic particles are mechanically dispersed and then a surface modifier is added thereto and stirred, or a method in which the surface modification is performed before the inorganic particles are mechanically dispersed (if necessary, the inorganic particles are warmed and dried and then subjected to heating or changing of pH (power of hydrogen)) and then the inorganic particles are dispersed. As a solvent for dissolving the surface modifier, an organic solvent having high polarity is preferable, and specific examples thereof include known solvents such as an alcohol, a ketone, and an ester.

Provided that the total solid content in the curable composition for forming an HC layer is 100% by mass, the content of the inorganic particles is preferably 5% to 40% by mass, and more preferably 10% to 30% by mass. It does not matter whether the primary particles of the inorganic particles have a spherical shape or a non-spherical shape. However, it is preferable that the primary particles of the inorganic particles have a spherical shape. From the viewpoint of further improving the hardness, it is more preferable that in the HC layer obtained by curing the curable composition for forming an HC layer, the inorganic particles are present as non-spherical high-order particles of the order equal to or higher than that of secondary particles in which two to ten spherical inorganic particles (primary particles) are linked to each other.

Specific examples of the inorganic particles include ELCOM V-8802 (trade name, spherical silica particles having an average primary particle diameter of 15 nm manufactured by JGC CORPORATION), ELCOM V-8803 (trade name, silica particles of irregular shapes manufactured by JGC CORPORATION), MiBK-SD (trade name, spherical silica particles having an average primary particle diameter of 10 to 20 nm manufactured by NISSAN CHEMICAL INDUSTRIES, LTD.), MEK-AC-2140Z (trade name, spherical silica particles having an average primary particle diameter of 10 to 20 nm manufactured by NISSAN CHEMICAL INDUSTRIES, LTD.), MEK-AC-4130 (trade name, spherical silica particles having an average primary particle diameter of 45 nm manufactured by NISSAN CHEMICAL INDUSTRIES, LTD.), MiBK-SD-L (trade name, spherical silica particles having an average primary particle diameter of 40 to 50 nm manufactured by NISSAN CHEMICAL INDUSTRIES, LTD.), MEK-AC-5140Z (trade name, spherical silica particles having an average primary particle diameter of 85 nm manufactured by NISSAN CHEMICAL INDUSTRIES, LTD.), and the like. Among these, from the viewpoint of further improving hardness, ELCOM V-8802 manufactured by JGC CORPORATION is preferable.

(ii) Matt Particles

The curable composition for forming an HC layer can also contain matt particles. The matt particles mean particles having an average primary particle diameter equal to or greater than 2 μm. The matt particles may be inorganic particles or organic particles, or may be particles of an inorganic-organic composite material. It does not matter whether the matt particles have a spherical shape or a non-spherical shape. The average primary particle diameter of the matt particles is preferably within a range of 2 to 20 μm, more preferably within a range of 4 to 14 μm, and even more preferably within a range of 6 to 10 μm.

Specific examples of the matt particles preferably include inorganic particles such as silica particles and TiO₂ particles and organic particles such as crosslinked acryl particles, crosslinked acryl-styrene particles, crosslinked styrene particles, melamine resin particles, and benzoguanamine resin particles. Among these, organic particles are preferable as the matt particles, and crosslinked acryl particles, crosslinked acryl-styrene particles, or crosslinked styrene particles are more preferable.

The content of the matt particles per unit volume of the HC layer obtained by curing the curable composition for forming an HC layer is preferably equal to or greater than 0.10 g/cm³, more preferably 0.10 g/cm³ to 0.40 g/cm³, and even more preferably 0.10 g/cm³ to 0.30 g/cm³.

(iii) Ultraviolet Absorber

It is also preferable that the curable composition for forming an HC layer contains an ultraviolet absorber. Examples of the ultraviolet absorber include a benzotriazole compound and a triazine compound. The benzotriazole compound mentioned herein is a compound having a benzotriazole ring, and specific examples thereof include various benzotriazole-based ultraviolet absorbers described in paragraph “0033” in JP2013-111835A. The triazine compound is a compound having a triazine ring, and specific examples thereof include various triazine-based ultraviolet absorbers described in paragraph “0033” in JP2013-111835A. The content of the ultraviolet absorber in the HC layer is, for example, about 0.1 to 10 parts by mass with respect to 100 parts by mass of the resin contained in HC layer, but is not particularly limited. Regarding the ultraviolet absorber, paragraph “0032” in JP2013-111835A can also be referred to. In the present invention and the present specification, the ultraviolet rays mean the light having a central emission wavelength in a wavelength range of 200 to 380 nm.

(iv) Fluorine-Containing Compound

It is also preferable that the curable composition for forming an HC layer contains a fluorine-containing compound such as a leveling agent and an antifoulant.

As the leveling agent, a fluorine-containing polymer is preferably used. Examples thereof include the fluoroaliphatic group-containing polymer described in JP5175831B. Furthermore, a fluoroaliphatic group-containing polymer, in which the content of a fluoroaliphatic group-containing monomer represented by General Formula (1) in JP5175831B in all polymerization units constituting the fluoroaliphatic group-containing polymer is equal to or smaller than 50% by mass, can also be used as a leveling agent.

In a case where the HC layer contains an antifoulant, the adhesion of finger print or contaminant is suppressed, the contaminant that has adhered can be easily wiped off, and rub resistance can be further improved by enhancing sliding properties of the surface of the HC layer.

It is preferable that the antifoulant contains a fluorine-containing compound. The fluorine-containing compound preferably has a perfluoropolyether group and a polymerizable group (preferably a radically polymerizable group), and more preferably has a perfluoropolyether group and a plurality of polymerizable groups in one molecule. In a case where the above constitution is adopted, the rub resistance improving effect can be more effectively exerted.

In the present specification, even in a case where the antifoulant has a polymerizable group, the antifoulant is regarded as not corresponding to polymerizable compounds 1 to 3, which will be described later, and other polymerizable compounds.

The fluorine-containing compound may be any of a monomer, an oligomer, and a polymer, but is preferably an oligomer (fluorine-containing oligomer).

The curable composition for forming an HC layer can also contain the leveling agent and the antifoulant described in (vi) Other components, which will be described later, in addition to the above components.

As the antifoulant which can be used in the present invention, in addition to the above antifoulant, it is possible to use the materials described in paragraphs “0012” to “0101” in JP2012-088699A, and the content of the publication is incorporated into the present specification.

As the antifoulant described so far, those synthesized by known methods or commercial products may be used. As the commercial products, RS-90 and RS-78 (trade names) manufactured by DIC Corporation and the like can be preferably used.

In a case where the curable composition for forming an HC layer contains an antifoulant, the content of the antifoulant with respect to the total solid content of the curable composition for forming an HC layer is preferably 0.01% to 7% by mass, more preferably 0.05% to 5% by mass, and even more preferably 0.1% to 2% by mass.

The curable composition for forming an HC layer may contain only one kind of antifoulant or two or more kinds of antifoulants. In a case where the composition contains two or more kinds of antifoulants, it is preferable that the total content thereof is within the above range.

In addition, the curable composition for forming an HC layer can have a constitution which substantially does not contain an antifoulant.

(v) Solvent

It is also preferable that the curable composition for forming an HC layer contains a solvent. As the solvent, an organic solvent is preferable. One kind of organic solvent can be used, or two or more kinds of organic solvents can be used by being mixed together at any ratio. Specific examples of the organic solvent include alcohols such as methanol, ethanol, propanol, n-butanol, and iso-butanol; ketones such as acetone, methyl isobutyl ketone, methyl ethyl ketone, and cyclohexanone; cellosolves such as ethyl cellosolve; aromatic solvents such as toluene and xylene; glycol ethers such as propylene glycol monomethyl ether; acetic acid esters such as methyl acetate, ethyl acetate, and butyl acetate; diacetone alcohol; and the like. Among these, methyl ethyl ketone, methyl isobutyl ketone, or methyl acetate is preferable, and a mixture of methyl ethyl ketone, methyl isobutyl ketone, and methyl acetate which are mixed at any ratio is more preferably used. In a case where the above constitution is adopted, a laminate having better rub resistance, punching properties, and adhesiveness is obtained.

The amount of the solvent in the curable composition for forming an HC layer can be appropriately adjusted within a range in which coating suitability of the composition can be secured. For example, the content of the solvent with respect to the total amount, 100 parts by mass, of the polymerizable compound and the photopolymerization initiator can be 50 to 500 parts by mass, and preferably 80 to 200 parts by mass.

The amount of solid contents in the curable composition for forming an HC layer is preferably 10% to 90% by mass, more preferably 50% to 80% by mass, and particularly preferably 65% to 75% by mass.

(vi) Other Components

The curable composition for forming an HC layer can contain one or more kinds of known additives in any amount, in addition to the above components. Examples of the additives include a surface conditioner, a leveling agent, a polymerization inhibitor, polyrotaxane, and the like. For the details of these, paragraphs “0032” to “0034” in JP2012-229412A can be referred to. Furthermore, the curable composition for forming an HC layer can also contain a commercial antifoulant or an antifoulant which can be prepared by a known method. However, the additives are not limited to these, and various additives generally added to the curable composition for forming an HC layer can be used. In addition, the curable composition for forming an HC layer can also contain a known solvent in any amount, in addition to (v) solvent described above.

The curable composition for forming an HC layer can be prepared by simultaneously mixing together the various components described above or by sequentially mixing them together in an arbitrary order. The preparation method is not particularly limited, and a known stirrer or the like can be used.

2) Laminated Structure Including Two or More Layers

For the laminate of the embodiment of the present invention, an aspect is also preferable in which the HC layer 3A shown in FIG. 2 has at least a first HC layer and a second HC layer in this order from the resin film 1A side.

The first HC layer may be positioned on the surface of the resin film 1A, or there may be another layer between the resin film 1A and the first HC layer. Likewise, the second HC layer may be positioned on the surface of the first HC layer, or there may be another layer between the first HC layer and the second HC layer. From the viewpoint of improving the adhesiveness between the first HC layer and the second HC layer, it is preferable that the second HC layer is positioned on the surface of the first HC layer, that is, the first and second HC layers contact each other in at least a portion within the film surface.

Each of the first HC layer and the second HC layer may be constituted with one layer or two or more layers, and is preferably constituted with one layer.

In a case where the laminate of the embodiment of the present invention is used in a touch panel as will be specifically described later, it is preferable that the laminate is disposed such that the second HC layer becomes the front surface side of the image display device. In order to improve the rub resistance and the punching properties of the surface of the laminate, it is preferable that the second HC layer is disposed on the surface side, particularly, on the uppermost surface of the laminate.

<First HC Layer and Curable Composition for Forming First HC Layer>

The first HC layer used in the present invention is formed of a curable composition for forming a first HC layer.

The curable composition for forming a first HC layer contains a polymerizable compound 1 having a radically polymerizable group and a polymerizable compound 2 which has a cationically polymerizable group and a radically polymerizable group in the same molecule and is different from the polymerizable compound 1. The content of the polymerizable compound 2 between the polymerizable compounds contained in the curable composition for forming a first HC layer is equal to or greater than 51% by mass.

(Polymerizable Compound)

As the polymerizable compound 1, the description of the aforementioned radically polymerizable compound is preferably adopted, and as the polymerizable compound 2, the description of a) component in the aforementioned cationically polymerizable compound is preferably adopted.

The curable composition for forming a first HC layer may have another polymerizable compound different from the polymerizable compound 1 and the polymerizable compound 2.

Another polymerizable compound described above is preferably a polymerizable compound having a cationically polymerizable group. The cationically polymerizable group has the same definition as the cationically polymerizable group described above regarding the polymerizable compound 2, and the preferable range thereof is also the same. Particularly, in the present invention, as another polymerizable compound described above, a nitrogen-containing heterocyclic ring-containing compound containing a cationically polymerizable group is preferable. In a case where such a compound is used, the adhesiveness between the resin film and the first HC layer can be more effectively improved.

Examples of the nitrogen-containing heterocyclic ring include a nitrogen-containing heterocyclic ring selected from the group consisting of isocyanurate rings (nitrogen-containing heterocyclic rings contained in the example compounds B-1 to B-3 described above) and glycoluril rings (nitrogen-containing heterocyclic rings contained in the example compound B-10 described above). As the nitrogen-containing heterocyclic ring, an isocyanurate ring is more preferable. The number of cationic groups contained in another polymerizable compound described above is preferably 1 to 10, and more preferably 2 to 5. In a case where a polymerizable compound having a cationically polymerizable group and a nitrogen-containing heterocyclic ring structure is used as another polymerizable compound described above, as the resin film, a resin film including an acrylic resin film is preferable. In a case where this constitution is adopted, the adhesiveness between the resin film and the first HC layer tends to be further improved.

Specific examples of another polymerizable compound described above include example compounds B-1 to B-14 described above, but the present invention is not limited to the specific examples.

(Others)

In addition, the description of the polymerization initiator, the inorganic particles, the matt particles, the ultraviolet absorber, the fluorine-containing compound, the solvent, and other components can also be preferably adopted.

Particularly, the curable composition for forming a first HC layer preferably contains a solvent, and a curable composition for forming a second HC layer preferably contains an antifoulant.

(Thickness of HC Layer)

The thickness of the HC layer is preferably equal to or greater than 3 μm and equal to or smaller than 100 μm, more preferably equal to or greater than 5 μm and equal to or smaller than 70 μm, and even more preferably equal to or greater than 10 μm and equal to or smaller than 50 μm.

(Pencil Hardness of HC Layer)

The higher the pencil hardness of the HC layer, the better. Specifically, the pencil hardness of the HC layer is preferably equal to or higher than 5H, and more preferably equal to or higher than 7H.

The pencil hardness can be measured by the method described in Examples.

—Method for Forming HC Layer—

By coating the resin film with the curable composition for forming an HC layer directly or through another layer such as an easily adhesive layer and irradiating the composition with active energy rays, the HC layer can be formed. The coating can be performed by known coating methods such as a dip coating method, an air knife coating method, a curtain coating method, a roller coating method, a die coating method, a wire bar coating method, and a gravure coating method. By simultaneously or sequentially coating the resin film with two or more kinds of compositions having different makeups, an HC layer having a laminated structure including two or more layers (for example, about two to five layers) can also be formed.

By irradiating the curable composition for forming an HC layer, with which the resin film is coated, with active energy rays, the HC layer can be formed. For example, in a case where the curable composition for forming an HC layer contains a radically polymerizable compound, a cationically polymerizable compound, a radical photopolymerization initiator, and a cationic photopolymerization initiator, a polymerization reaction between the radically polymerizable compound and the cationically polymerizable compound can be initiated and proceed by the action of a radical photopolymerization initiator and a cationic photopolymerization initiator respectively. The wavelength of radiated light may be determined according to the type of the polymerizable compound and the polymerization initiator used. Examples of light sources for light irradiation include a high-pressure mercury lamp, an ultrahigh-pressure mercury lamp, a carbon arc lamp, a metal halide lamp, a xenon lamp, a chemical lamp, an electrodeless discharge lamp, a Light Emitting Diode (LED), and the like that emit light in a wavelength range of 150 to 450 nm. The light irradiation amount is generally within a range of 30 to 3,000 mJ/cm², and preferably within a range of 100 to 1,500 mJ/cm². If necessary, a drying treatment may be performed before or after the light irradiation or before and after the light irradiation. The drying treatment can be performed by hot air blowing, disposing the resin film with the composition in a heating furnace, or transporting the resin film with the composition in a heating furnace, and the like. In a case where the curable composition for forming an HC layer contains a solvent, the heating temperature may be set to be a temperature at which the solvent can be dried and removed, but the heating temperature is not particularly limited. Herein, the heating temperature means the temperature of hot air or the internal atmospheric temperature of the heating furnace.

(Antireflection Layer)

In the laminate having the HC layer of the embodiment of the present invention, an antireflection layer may be provided on a side, which is opposite to the resin film, of the HC layer. The antireflection layer is not particularly limited, and examples thereof include a laminate of a plurality of layers of low refractive index and a plurality of layers of high refractive index. The layers of low refractive index and the layers of high refractive index may be laminated in any order without particular limitation, but it is preferable that a layer of low refractive index becomes the layer farthest from the resin film (layer contacting air). Furthermore, from the viewpoint of improving the antireflection performance, a plurality of layers of low refractive index and a plurality of layers of high refractive index are preferably laminated, and more preferably alternately laminated.

—Layer of Low Refractive Index—

Examples of the material constituting the layer of low refractive index include materials of refractive index lower than that of the material constituting the layer of high refractive index, such as aluminum oxide (Al₂O₃), silicon dioxide (SiO₂), non-stoichiometric silicon oxide (SiO_{2-X}, 0≤X<1), magnesium fluoride (MgF₂), and a mixture of these. Among these, silicon oxide is preferable.

The refractive index of the layer of low refractive index is preferably equal to or higher than 1.35 and equal to or lower than 1.5, and more preferably equal to or higher than 1.38 and equal to or lower than 1.47. Furthermore, provided that a design wavelength λ₀ is 500 nm, the optical film thickness of the layer of low refractive index is preferably equal to or smaller than 0.44λ₀, more preferably equal to or smaller than 0.354, and even more preferably equal to or smaller than 0.14λ₀.

—Layer of High Refractive Index—

Examples of the material constituting the layer of high refractive index include materials of refractive index higher than that of the material constituting the layer of low refractive index, such as tantalum pentoxide (Ta₂O₅), niobium pentoxide (Nb₂O₅), lanthanum titanate (LaTiO₃), hafnium oxide (HfO₂), titanium oxide (TiO₂), chromium oxide (Cr₂O₃), zirconium oxide (ZrO), zinc sulfide (ZnS), tin-doped indium oxide (ITO), antimony-doped tin oxide (ATO), and a mixture of these.

The refractive index of the layer of high refractive index is preferably equal to or higher than 1.7 and equal to or lower than 2.5, and more preferably equal to or higher than 1.8 and equal to or lower than 2.2. Provided that a design wavelength λ₀ is 500 nm, the optical film thickness of the layer of high refractive index is preferably equal to or greater than 0.036λ₀ and equal to or smaller than 0.54λ₀, and more preferably equal to or greater than 0.072λ₀ and equal to or smaller than 0.43λ₀.

The method for forming the layer of low refractive index and the layer of high refractive index is not particularly limited, and any of a wet coating method and a dry coating method may be used. Among these, a dry coating method such as vacuum vapor deposition, Chemical Vapor Deposition (CVD), sputtering, or electron beam vapor deposition is preferable, and sputtering or electron beam vapor deposition is more preferable, because these methods make it possible to form a thin film having a uniform film thickness and make it easy to adjust the film thickness of the thin film at a nanometer level.

(4) Articles Having Laminate

Examples of articles including the laminate of the embodiment of the present invention include various articles required to have improved rub resistance in various industrial fields such as the field of home appliances, the field of electricity and electronics, the field of automobiles, and the field of housing. Specifically, examples of such articles include a touch sensor, a touch panel, an image display apparatus such as a liquid crystal display, window glass of automobiles, window glass for home, and the like. By providing the laminate of the embodiment of the present invention preferably as a surface protect film in these articles, it is possible to provide articles having excellent glass quality. The laminate of the embodiment of the present invention is a laminate used in a front panel of an image display apparatus, and more preferably a laminate used in a front panel of an image display device of a touch panel.

The touch panel in which the laminate of the embodiment of the present invention can be used is not particularly limited, and can be appropriately selected according to the purpose. Examples of the touch panel include a surface capacitance-type touch panel, a projected capacitance-type touch panel, a resistive film-type touch panel, and the like. The details of the touch panel will be specifically described later.

The touch panel includes a so-called touch sensor. In the touch panel, the layer constitution of a touch panel sensor-electrode portion may be established by any of a bonding method in which two sheets of transparent electrodes are bonded to each other, a method of providing a transparent electrode on both surfaces of one sheet of substrate, a method using a single-face jumper or a through hole, and a single-face lamination method.

<<Image Display Apparatus>>

The image display apparatus of the embodiment of the present invention is an image display apparatus including a front panel having the laminate of the embodiment of the present invention and an image display device.

Examples of the image display apparatus include an image display apparatus such as a Liquid Crystal Display (LCD), a plasma display panel, an electroluminescence display, a cathode tube display, and a touch panel.

Examples of the liquid crystal display include a Twisted Nematic (TN) type, a Super-Twisted Nematic (STN) type, a Triple Super Twisted Nematic (TSTN) type, a multi domain type, a Vertical Alignment (VA) type, an In Plane Switching (IPS) type, an Optically Compensated Bend (OCB) type, and the like.

It is preferable that the image display apparatus has ameliorated brittleness and excellent handleability, does not impair display quality by surface smoothness or wrinkles, and can suppress the leakage of light at the time of a moisture-heat test.

That is, the image display apparatus of the embodiment of the present invention preferably includes a liquid crystal display as an image display device. Examples of the image display apparatus having a liquid crystal display include Xperia P (trade name) manufactured by Sony Ericsson Mobile, and the like.

It is also preferable that the image display apparatus of the embodiment of the present invention has an organic Electroluminescence (EL) display device as an image display device.

For the organic electroluminescence display device, known techniques can be adopted without any limitation. Examples of the image display apparatus having an organic electroluminescence display device include GALAXY SII (trade name) manufactured by SAMSUNG ELECTRONICS CO., LTD., and the like.

It is also preferable that the image display apparatus of the embodiment of the present invention has an In-Cell touch panel display device as an image display device. The in-cell touch panel display device is a device in which the touch panel function is built in the cell of the image display device.

For the in-cell touch panel display device, for example, known techniques described in JP2011-076602A, JP2011-222009A, and the like can be adopted without any limitation. Examples of the image display apparatus having the in-cell touch panel display device include Xperia P (trade name) manufactured by Sony Ericsson Mobile, and the like.

It is also preferable that the image display apparatus of the embodiment of the present invention has an On-Cell touch panel display device as an image display device. The on-cell touch panel display device is a device in which the touch panel function is built on the outside of the cell of the image display device.

For the on-cell touch panel display device, for example, known techniques described in JP2012-088683A and the like can be adopted without any limitation. Examples of the image display apparatus having the on-cell touch panel display device include GALAXY SII (trade name) manufactured by SAMSUNG ELECTRONICS CO., LTD., and the like.

<<Touch Panel>>

The touch panel of the embodiment of the present invention is a touch panel including a touch sensor obtained by bonding a touch sensor film to the pressure sensitive adhesive layer in the laminate of the embodiment of the present invention.

The touch sensor film is not particularly limited, but is preferably a conductive film in which a conductive layer is formed.

The conductive film is preferably a conductive film obtained by forming a conductive layer on any support.

The material of the conductive layer is not particularly limited, and examples thereof include indium-tin composite oxide (Indium Tin Oxide; ITO), tin oxide, tin-titanium composite oxide, antimony-tin composite oxide (Antimony Tin Oxide; ATO), copper, silver, aluminum, nickel, chromium, an alloy of these, and the like.

It is preferable that the conductive layer has an electrode pattern. Furthermore, it is preferable that the conductive layer has a transparent electrode pattern. The electrode pattern may be obtained by patterning a transparent conductive material layer or obtained by forming a layer of non-transparent conductive material by patterning.

As the transparent conductive material, it is possible to use an oxide such as ITO or ATO, silver nanowires, carbon nanotubes, a conductive polymer, and the like.

Examples of the layer of a non-transparent conductive material include a metal layer. As the metal constituting the metal layer, any metal having conductivity can be used, and silver, copper, gold, aluminum, and the like are suitably used. The metal layer may be a simple metal or an alloy, or may be a layer in which metal particles are bonded to each other through a binder. If necessary, the surface of the metal may be subjected to a blackening treatment, a rust-proofing treatment, and the like. In a case where a metal is used, a substantially transparent sensor portion and a peripheral wiring portion can be collectively formed.

It is preferable that the conductive layer contains a plurality of metal thin wires.

The metal thin wires are preferably formed of silver or an alloy containing silver. The conductive layer containing metal thin wires formed of silver or an alloy containing silver is not particularly limited, and known conductive layers can be used. For example, it is preferable to use the conductive layer described in paragraphs “0040” and “0041” in JP2014-168886A, and the content of the publication is incorporated into the present specification.

It is also preferable that the metal thin wires are formed of copper or an alloy containing copper. The alloy is not particularly limited, and known conductive layers can be used. For example, it is preferable to use the conductive layer described in paragraphs “0038” to “0059” in JP2015-049852A, and the content of the publication is incorporated into the present specification.

It is also preferable that the conductive layer is formed of an oxide. In a case where the conductive layer is formed of an oxide, it is more preferable that the oxide is formed of indium oxide containing tin oxide or of tin oxide containing antimony. The conductive layer formed of an oxide is not particularly limited, and known conductive layers can be used. For example, it is preferable to use the conductive layer described in paragraphs “0017” to “0037” in JP2010-027293A, and the content of the publication is incorporated into the present specification.

Among these conductive layers constituted as above, a conductive layer is preferable which includes a plurality of metal thin wires that are disposed in a mesh shape or a random shape, and a conductive layer is more preferable in which the metal thin wires are disposed in a mesh shape. Particularly, a conductive layer is preferable in which the metal thin wires are disposed in a mesh shape and formed of a silver or an alloy containing silver.

It is also preferable that the touch sensor film has a conductive layer on both surfaces thereof.

Paragraphs “0016” to “0042” in JP2012-206307A describe preferable aspects of the touch sensor film, and the content of the publication is incorporated into the present specification.

<<Resistive Film-Type Touch Panel>>

The resistive film-type touch panel of the embodiment of the present invention is a resistive film-type touch panel having the front panel of the embodiment of the present invention.

Basically, the resistive film-type touch panel has a constitution in which conductive films including a pair of upper and lower substrates each having a conductive film are disposed with a spacer therebetween such that the conductive films face each other. The constitution of the resistive film-type touch panel is known, and in the present invention, known techniques can be applied without any limitation.

<<Capacitance-Type Touch Panel>>

The capacitance-type touch panel of the embodiment of the present invention is a capacitance-type touch panel having the front panel of the embodiment of the present invention.

Examples of the capacitance-type touch panel include a surface capacitance-type touch panel and a projected capacitance-type touch panel. The projected capacitance-type touch panel has a basic constitution in which an X-axis electrode and a Y-axis electrode orthogonal to the X-axis electrode are disposed having an insulator therebetween. Specific aspects thereof include an aspect in which the X electrode and the Y electrode are formed on each surface of one substrate, an aspect in which the X electrode, the insulating layer, and the Y electrode are formed in this order on one substrate, an aspect in which the X electrode is formed on one substrate and the Y electrode is formed on the other substrate (in this aspect, a constitution in which two substrates are bonded to each other is the aforementioned basic constitution), and the like. The constitution of the capacitance-type touch panel is known, and in the present invention, known techniques can be adopted without any limitation.

FIG. 3 shows an example of the constitution of an embodiment of a capacitance-type touch panel. A touch panel 2 is used in combination with a display apparatus. The display apparatus is used by being disposed on a protective layer 7B side in FIG. 3, that is, on a display apparatus side. In FIG. 3, the resin film 3 side is a viewing side (that is, a side on which a person operating the touch panel visually recognizes an image displayed on the display apparatus). The laminate of the embodiment of the present invention (represented by the reference 4C in FIG. 3) is used by bonding a conductive film 1 for a touch panel to the surface of a pressure sensitive adhesive layer 4. The conductive film 1 for a touch panel includes a conductive member 6A (first conductive layer 8) and a conductive member 6B (second conductive layer 9) on both surfaces of a flexible transparent insulating substrate 5. Each of the conductive member 6A and the conductive member 6B at least constitutes an electrode, peripheral wiring, an external connection terminal, and a connector portion as a touch panel which will be described later.

As shown in FIG. 3, for the purpose of flattening or protecting the conductive members 6A and 6B, transparent protective layers 7A and 7B may be disposed to cover the conductive member 6A and the conductive member 6B.

In the laminate 4C, a decorative layer for shielding a peripheral region S2, which will be described later, from light may be formed.

As the material of the transparent insulating substrate 5, glass, polyethylene terephthalate (PET), polyethylene naphthalate (PEN), a cycloolefin polymer (COP), a cycloolefin copolymer (COC), polycarbonate (PC), and the like can be used. The thickness of the transparent insulating substrate 5 is preferably 20 to 200 μm.

As the pressure sensitive adhesive layer 4, it is possible to use an Optical Clear Adhesive or an Optical Clear Resin satisfying the specification of the pressure sensitive adhesive layer used in the present invention. The film thickness of the pressure sensitive adhesive layer 4 is preferably 10 to 100 μm. As the optical clear adhesive, for example, an 8146 series manufactured by 3M can be preferably used. The relative permittivity of the pressure sensitive adhesive layer 4 is preferably 4.0 to 6.0, and more preferably 5.0 to 6.0. As the protective layer 7A and the protective layer 7B, for example, it is possible to use an organic film such as gelatin, an acrylic resin, or a urethane resin and an inorganic film such as silicon dioxide. The film thickness thereof is preferably equal to or greater than 10 nm and equal to or smaller than 100 nm, and the relative permittivity thereof is preferably 2.5 to 4.5.

The concentration of halogen impurities in the protective layer 7A and the protective layer 7B is preferably equal to or lower than 50 ppm. It is more preferable that the protective layer 7A and the protective layer 7B do not contain halogen impurities. According to this aspect, it is possible to inhibit the corrosion of the conductive member 6A and the conductive member 6B.

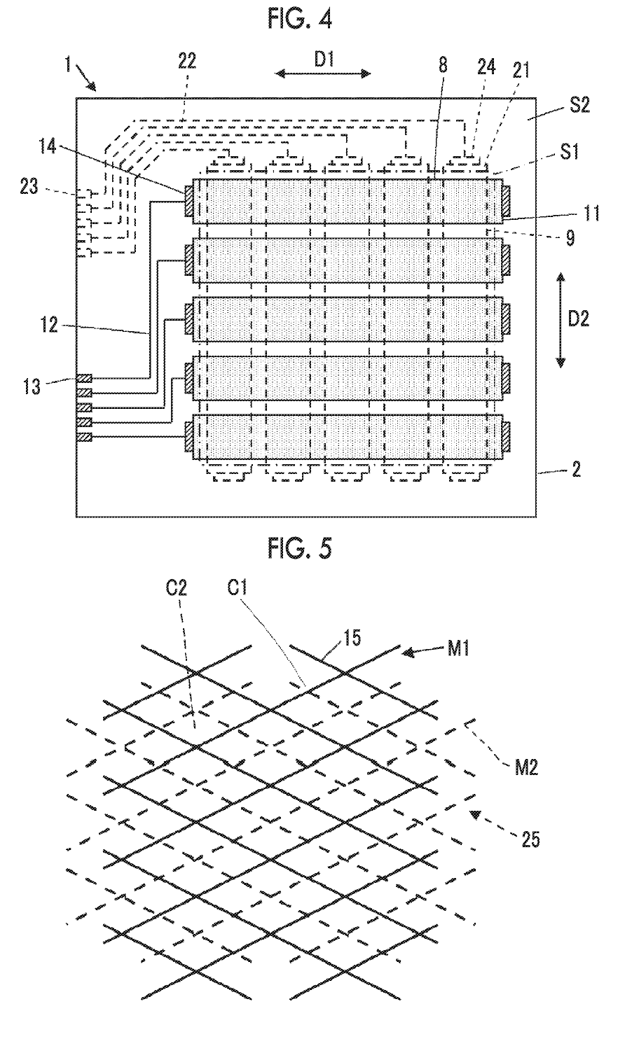

As shown in FIG. 4, the conductive film 1 for a touch panel is divided into a transparent active area S1 and a peripheral region S2 which is on the outside of the active area S1.

Within the active area S1, the first conductive layer 8 formed on the front surface (first surface) of the transparent insulating substrate 5 and the second conductive layer 9 formed on the rear surface (second surface) of the transparent insulating substrate 5 are disposed such that they overlap each other. The first conductive layer 8 and the second conductive layer 9 are disposed in a state where they are insulated from each other through the transparent insulating substrate 5.

The first conductive layer 8 on the front surface of the transparent insulating substrate 5 forms a plurality of first electrodes 11 which each extend along a first direction D1 and are disposed in parallel to each other along a second direction D2 orthogonal to the first direction D1. The second conductive layer 9 on the rear surface of the transparent insulating substrate 5 forms a plurality of second electrodes 21 which each extend along the second direction D2 and are disposed in parallel to each other along the first direction D1.

The plurality of first electrodes 11 and the plurality of second electrodes 21 constitute detection electrodes of the touch panel 2. Each of the first electrode 11 and the second electrode 21 preferably has an electrode width of 1 to 5 mm, and an interelectrode pitch thereof is preferably 3 to 6 mm.

On the front surface of the transparent insulating substrate 5 in the peripheral region S2, a plurality of first peripheral wiring 12 connected to the plurality of first electrodes 11 are formed, and a plurality of first external connection terminals 13 are arrayed and formed in the border portion of the transparent insulating substrate 5. Furthermore, at both ends of each of the first electrodes 11, a first connector portion 14 is formed. The first connector portion 14 is connected to one end of the corresponding first peripheral wiring 12, and the other end of the first peripheral wiring 12 is connected to the corresponding first external connection terminal 13.

Likewise, on the rear surface of the transparent insulating substrate 5 in the peripheral region S2, a plurality of second peripheral wiring 22 connected to the plurality of second electrodes 21 are formed, and a plurality of second external connection terminals 23 are arrayed and formed in the border portion of the transparent insulating substrate 5. Furthermore, at both ends of each of the second electrodes 21, a second connector portion 24 is formed. The second connector portion 24 is connected to one end of the corresponding second peripheral wiring 22, and the other end of the second peripheral wiring 22 is connected to the corresponding second external connection terminal 23.

The conductive film 1 for a touch panel has a conductive member 6A which has the first electrode 11, the first peripheral wiring 12, the first external connection terminal 13, and the first connector portion 14 on the front surface of the transparent insulating substrate 5 and the conductive member 6B which has the second electrode 21, the second peripheral wiring 22, the second external connection terminal 23, and the second connector portion 24 on the rear surface of the transparent insulating substrate 5.

In FIG. 4, although the first electrode 11 and the first peripheral wiring 12 are connected to each other through the first connector portion 14, a constitution may also be adopted in which the first connector portion 14 is not provided such that the first electrode 11 and the first peripheral wiring 12 are directly connected to each other. Furthermore, a constitution may also be adopted in which the second connector portion 24 is not provided such that the second electrode 21 and the second peripheral wiring 22 are directly connected to each other.

In a case where the first connector portion 14 and the second connector portion 24 are provided, electricity can be effectively excellently conducted at the site where the electrode and the peripheral wiring are connected to each other. Particularly, in a case where the electrode and the peripheral wiring are formed of different materials, it is preferable to provide the first connector portion 14 and the second connector portion 24. The width of each of the first connector portion 14 and the second connector portion 24 is preferably equal to or greater than ⅓ of the width of the electrode connected to each of the connector portions and equal to or smaller than the width of the electrode. The first connector portion 14 and the second connector portion 24 may have the shape of a solid film, the frame shape shown in WO2013/089085A, or a mesh shape.

The wiring width of the first peripheral wiring 12 and the second peripheral wiring 22 is equal to or greater than 10 μm and equal to or smaller than 200 μm, and the minimum wiring interval (minimum interwiring distance) is preferably equal to or greater than 20 μm and equal to or smaller than 100 μm.

Each of the peripheral wiring may be covered with a protective insulating film formed of a urethane resin, an acryl resin, an epoxy resin, or the like. In a case where the protective insulating film is provided, it is possible to prevent the migration, rusting, and the like of the peripheral wiring. It is preferable that the insulating film does not contain halogen impurities because the impurities are likely to cause the corrosion of the peripheral wiring. The film thickness of the protective insulating film is preferably 1 to 20 μm.

In a case where the conductive film 1 for a touch panel is used as a touch panel, the first external connection terminal 13 and the second external connection terminal 23 are electrically connected to Flexible Printed Circuits through an Anisotropic Conductive Film. The flexible printed circuits are connected to a touch panel control board having a driving function and a position detection function.

For the purpose of improving the electric connectivity with respect to the flexible printed circuits, the first external connection terminal 13 and the second external connection terminal 23 are formed to have a terminal width larger than the wiring width of the first peripheral wiring 12 and the second peripheral wiring 22. Specifically, each of the first external connection terminal 13 and the second external connection terminal 23 preferably has a terminal width equal to or greater than 0.1 mm and equal to or smaller than 0.6 mm and a terminal length equal to or greater than 0.5 mm and equal to or smaller than 2.0 mm.

The transparent insulating substrate 5 corresponds to a substrate having a first surface and a second surface facing the first surface. The first conductive layer 8 is disposed on the first surface (front surface), and the second conductive layer 9 is disposed on the second surface (rear surface). Although FIG. 3 shows a state where the transparent insulating substrate 5 directly contact the first conductive layer 8 and the second conductive layer 9, one or more functional layers such as an adhesion enhancing layer, an undercoat layer, a hardcoat layer, and an optical adjustment layer can be formed between the transparent insulating substrate 5 and the first conductive layer 8 as well as the second conductive layer 9.

FIG. 5 shows portions in which the first electrode 11 and the second electrode 21 cross each other. The first electrode 11 disposed on the front surface of the transparent insulating substrate 5 is formed of a mesh pattern M1 formed of a first metal thin wire 15, and the second electrode 21 disposed on the rear surface of the transparent insulating substrate 5 is formed of a mesh pattern M2 formed of a second metal thin wire 25. In a case where the touch panel is viewed from the viewing side, the first metal thin wire 15 and the second metal thin wire 25 are found to be disposed such that they cross each other in the portions in which the first electrode 11 and the second electrode 21 cross each other. In FIG. 5, in order to make it easy for the first metal thin wire 15 and the second metal thin wire 25 to be differentiated from each other, the second metal thin wire 25 is indicated by a dotted line, but in reality, the second metal thin wire 25 is formed of a connected wire just like the first metal thin wire 15.

It is preferable that the mesh pattern has a pattern shape in which the same mesh (regular cell) as shown in FIG. 5 is repeatedly disposed, and the mesh shape is particularly preferably a diamond shape. The pattern shape may be a quadrangular shape such as a parallelogram, a square, or a rectangle, a regular hexagon shape, or other polygon shapes. In a case where the mesh shape is a diamond shape, from the viewpoint of reducing moire formed between the pattern and the pixels of the display apparatus, an acute angle of the diamond is preferably equal to or greater than 200 and equal to or smaller than 700. From the viewpoint of visibility, the center-to-center distance between meshes (mesh pitch) is preferably 100 to 600 μm. It is preferable that the mesh pattern M1 formed of the first metal thin wire 15 and the mesh pattern M2 formed of the second metal thin wire 25 have the same shape. Furthermore, from the viewpoint of visibility, it is preferable that the mesh pattern M1 formed of the first metal thin wire 15 and the mesh pattern M2 formed of the second metal thin wire 25 are disposed by being caused to deviate from each other by a distance corresponding to ½ of the mesh pitch as shown in FIG. 5 such that a mesh pattern having a mesh pitch that is ½ of the aforementioned mesh pitch is formed from the viewing side. In another aspect, the mesh shape may be a random pattern or a semi-random shape obtained by imparting a certain degree of randomicity to a regular cell shape as described in JP2013-214545A in which about 10% of randomicity is imparted to the pitch of regular diamond cells.

Furthermore, a dummy mesh pattern, which is insulated from the electrodes formed of the first metal thin wire 15 and the second metal thin wire 25 respectively, may be provided between the first electrodes 11 adjacent to each other and between the second electrodes 21 adjacent to each other. It is preferable that the dummy mesh pattern is formed to have the same mesh shape as that of the mesh pattern forming the electrodes.

The touch panel 2 and the display apparatus may be bonded to each other by a method of directly bonding them to each other by using a transparent pressure sensitive adhesive (direct bonding method) or a method of bonding only the peripheries of the touch panel 2 and the display apparatus to each other by using a double-sided tape (air gap method), and any of these may be used. At the time of bonding the touch panel 2 and the display apparatus to each other, a protective film may be additionally provided on the conductive member 6B or the protective layer 7B. As the protective film, for example, a PET film (thickness: 20 to 150 μm) with a hardcoat is used. It is possible to adopt a constitution in which the protective film is bonded to the surface of the conductive member 6B or the protective layer 7B by using an Optical Clear Adhesive.

As the transparent pressure sensitive adhesive used in the direct bonding method, it is possible to use an Optical Clear Adhesive or an Optical Clear Resin used as the transparent pressure sensitive adhesive layer 4 described above, and the film thickness thereof is preferably equal to or greater than 10 μm and equal to or smaller than 100 μm. As the optical clear adhesive, for example, an 8146 series manufactured by 3M can be preferably used as described above. It is preferable that the relative permittivity of the transparent pressure sensitive adhesive used in the direct bonding method is lower than the relative permittivity of the aforementioned transparent pressure sensitive adhesive layer 4, because then the detection sensitivity of the touch panel 2 is improved. The relative permittivity of the transparent pressure sensitive adhesive used in the direct bonding method is preferably 2.0 to 3.0.

In view of further improving the effects of the present invention, the visible light reflectance of each of the viewing side surface of the first metal thin wire 15 and the viewing side surface of the second metal thin wire 25 is preferably equal to or lower than 5%, and more preferably less than 1%. In a case where the visible light reflectance is within this range, the mesh can be effectively inhibited from being noticed, or haze can be effectively reduced.

The visible light reflectance is measured by the following method, for example. First, by using an ultraviolet-visible spectrophotometer V660 (single reflection measurement unit SLM-721) manufactured by JASCO Corporation, a reflectance spectrum is measured at a measurement wavelength of 350 nm to 800 nm and an incidence angle of 5°. At this time, the regular reflection light from a vapor-deposited aluminum flat mirror is used as a base line. From the obtained reflectance spectrum, the Y value in the XYZ color space (color-matching function JIS Z9701-1999) with a light source of D65 at a 2 degree field of view is calculated using a color computation program manufactured by JASCO Corporation, and the calculated value is taken as the visible light reflectance.

As the materials constituting the first metal thin wire 15 and the second metal thin wire 25, it is possible to use metals such as silver, aluminum, copper, gold, molybdenum, and chromium, and an alloy of these. These materials can be used as a single layer or a laminate. From the viewpoint of inhibiting the mesh of the metal thin wire from being noticed and reducing moire, the line width of each of the first metal thin wire 15 and the second metal thin wire 25 is preferably equal to or greater than 0.5 μm and equal to or smaller than 5 μm. The first metal thin wire 15 and the second metal thin wire 25 may be in the form of a straight line, a folded line, a curved line, or a wavy line. The film thickness of each of the first metal thin wire 15 and the second metal thin wire 25 is preferably equal to or greater than 0.1 μm from the viewpoint of the value of resistance, and preferably equal to or smaller than 3 μm from the viewpoint of the visibility in an oblique direction. From the viewpoint of the visibility in an oblique direction and from the viewpoint of the workability of patterning, the film thickness is more preferably equal to or smaller than ½ of the line width of the metal thin wire. In addition, in order to reduce the visible light reflectance of the first metal thin wire 15 and the second metal thin wire 25, a blackened layer may be provided on the viewing side of the first metal thin wire 15 and the second metal thin wire 25.

The conductive member 6A including the first electrode 11, the first peripheral wiring 12, the first external connection terminal 13, and the first connector portion 14 can be formed of the material constituting the first metal thin wire 15. Accordingly, all the conductive members 6A each including the first electrode 11, the first peripheral wiring 12, the first external connection terminal 13, and the first connector portion 14 can be simultaneously formed of the same metal at the same thickness.

The same is true for the conductive member 6B including the second electrode 21, the second peripheral wiring 22, the second external connection terminal 23, and the second connector portion 24.

The sheet resistance of the first electrode 11 and the second electrode 21 is preferably equal to or higher than 0.1 Ω/square and equal to or lower than 200 Ω/square. Particularly, in a case where the electrodes are used in a projected capacitance-type touch panel, the sheet resistance thereof is preferably equal to or higher than 10 Ω/square and equal to or lower than 100 Ω/square.

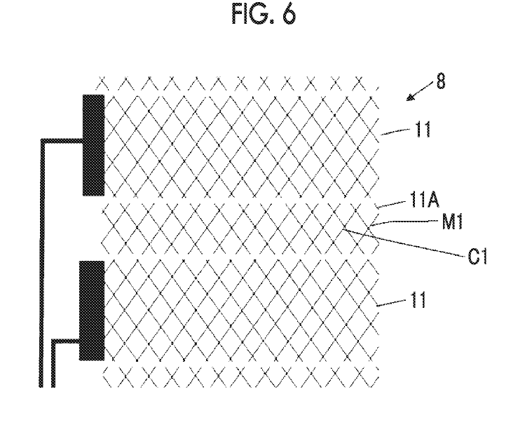

As shown in FIG. 6, the first conductive layer 8 disposed on the front surface of the transparent insulating substrate 5 in the active area S1 may have a plurality of first dummy electrodes 11A each of which is disposed between the plurality of first electrodes 11. These first dummy electrodes 11A are insulated from the plurality of first electrodes 11, and have the first mesh pattern M1 constituted with a number of first cells C1 just like the first electrodes 11.

A disconnection portion having a width equal to or greater than 5 μm and equal to or smaller than 30 μm is provided in the metal thin wire disposed along the continuous first mesh pattern M1, and in this way, the first electrode 11 and the adjacent first dummy electrode 11A are electrically insulated from each other. Although FIG. 6 shows a state where the disconnection portion is formed only in the border line between the first electrode 11 and the adjacent first dummy electrode 11A, the disconnected portion may be formed in all or some of the sides of the first cell C1 in the first dummy electrode 11A.

The second conductive layer 9 disposed on the rear surface of the transparent insulating substrate 5 in the active area S1 may have a plurality of second dummy electrodes each of which is disposed between the plurality of second electrodes 21, although second conductive layer 9 is not shown in the drawing. These second dummy electrodes are insulated from the plurality of second electrodes 21, and have the second mesh pattern M2 constituted with a number of second cells C2 just like the second electrodes 21.

A disconnection portion having a width equal to or greater than 5 μm and equal to or smaller than 30 μm is provided in the metal thin wire disposed along the continuous second mesh pattern M2, and in this way, the second electrode 21 and the adjacent second dummy electrode are electrically insulated from each other. The disconnection portion may be formed only in the border line between the second electrode 21 and the adjacent second dummy electrode, or may be formed in all or some of the sides of the second cell C2 in the second dummy electrode.

As described above, the conductive film 1 for a touch panel is manufactured by forming the conductive member 6A, which includes the first electrode 11, the first peripheral wiring 12, the first external connection terminal 13, and the first connector portion 14, on the front surface of the transparent insulating substrate 5 and forming the conductive member 6B, which includes the second electrode 21, the second peripheral wiring 22, the second external connection terminal 23, and the second connector portion 24, on the rear surface of the transparent insulating substrate 5.

At this time, the first electrode 11 is formed of the first conductive layer 8 in which the first metal thin wire 15 is disposed along the first mesh pattern M1, the second electrode 21 is formed of the second conductive layer 9 in which the second metal thin wire 25 is disposed along the second mesh pattern M2, and the first conductive layer 8 and the second conductive layer 9 are disposed such that the conductive layers overlap each other in the active area S1 as shown in FIG. 4 in a state of interposing the transparent insulating substrate 5 therebetween.

The method for forming the conductive member 6A and the conductive member 6B is not particularly limited. For example, as described in paragraphs “0067” to “0083” in JP2012-185813A, paragraphs “0115” to “0126” in JP2014-209332A, or paragraphs “0215” and “0216” in JP2015-005495A, by exposing a photosensitive material, which has an emulsion layer containing a photosensitive silver halide salt, to light and performing a development treatment, the conductive members 6A and 6B can be formed.

The conductive members can also be formed by forming a metal thin film on each of the front surface and the rear surface of the transparent insulating substrate 5 and pattern-wise printing a resist on each of the metal thin film or by performing exposure and development on a resist, with which the entire surface of the substrate is coated, such that a pattern is formed and etching the metal in the opening portion. In addition, it is possible to use a method in which a paste containing the fine particles of a material constituting the conductive member is printed on the front surface and the rear surface of the transparent insulating substrate 5 and plated with a metal, a method of using an ink jet method in which an ink containing the fine particles of a material constituting the conductive member is used, a method of forming the conductive member through screen printing by using an ink containing the fine particles of a material constituting the conductive member, a method of forming grooves in the transparent insulating substrate 5 and coating the grooves with a conductive ink, a patterning method exploiting a microcontact printing, and the like.

In the aspect described above, the conductive member 6A including the first electrode 11, the first peripheral wiring 12, the first external connection terminal 13, and the first connector portion 14 is disposed on the front surface of the transparent insulating substrate 5, and the conductive member 6B including the second electrode 21, the second peripheral wiring 22, the second external connection terminal 23, and the second connector portion 24 is disposed on the rear surface of the transparent insulating substrate 5. However, the present invention is not limited to this aspect.

For example, a constitution may be adopted in which the conductive member 6A and the conductive member 6B are disposed on one surface of the transparent insulating substrate 5 through an interlayer insulating film.

Furthermore, a constitution can be adopted in which two sheets of substrates are used. That is, the conductive member 6A can be disposed on the front surface of a first transparent insulating substrate, the conductive member 6B can be disposed on the front surface of a second transparent insulating substrate, and the first transparent insulating substrate and the second transparent insulating substrate can be used by being bonded to each other by using an Optical Clear Adhesive.

Moreover, a constitution may be adopted in which the conductive member 6A and the conductive member 6B are disposed on a surface of the pressure sensitive adhesive layer 4 in the laminate 4C shown in FIG. 3 through an interlayer insulating film without using the transparent insulating substrate 5.

It goes without saying that the electrode pattern shape of the capacitance-type touch panel can be applied to, in addition to a so-called bar-and-stripe electrode pattern shape shown in FIG. 4, for example, the diamond pattern disclosed in FIG. 16 in WO2010/012179A and the electrode pattern shape disclosed in FIG. 7 or 20 in WO2013/094728A. Furthermore, the electrode pattern shape can be applied to electrode pattern shapes of other capacitance-type touch panels.

In addition, the electrode pattern shape can be applied to a touch panel disclosed in US2012/0262414 that has a constitution in which a detection electrode is provided only on one side of a substrate as in an electrode constitution without a crossing portion.

The touch panel can be used in combination with other functional films such as the functional film for improving image quality disclosed in JP2014-013264A that prevents the occurrence of rainbow-like irregularities by using a substrate having a high retardation value, the circular polarization plate disclosed in JP2014-142462A that is for improving the visibility of a touch panel electrode, and the like.

<<Mirror with Image Display Function>>

The laminate of the embodiment of the present invention may have a reflection layer (linear polarization reflection layer or a circular polarization reflection layer) on a surface, which is opposite to a surface having the resin film, of the pressure sensitive adhesive layer. By being combined with an image display device, the laminate is preferably used as a laminate used in a front panel of a mirror with an image display function. In the present specification, the laminate having a linear polarization reflection layer or a circular polarization reflection layer that is used in a front panel of a mirror with an image display function is referred to as “half mirror” in some cases.

The image display device used in the mirror with an image display function is not particularly limited, and examples thereof include an image display device suitably used in the aforementioned image display apparatus.

The mirror with an image display function has a constitution in which an image display device is disposed on a side, which is provided with a linear polarization reflection layer or a circular polarization reflection layer, of the half mirror. In the mirror with an image display function, the half mirror and the image display device may directly contact each other, or another layer may be interposed between the half mirror and the image display device. For example, an air layer or an adhesive layer may be present between the image display device and the half mirror.

In the present specification, a surface, which is on the half mirror side, of the image display device is referred to as a front surface.

The mirror with an image display function can be used as a rearview mirror (inner mirror), for example. In order to be used as a rearview mirror, the mirror with an image display function may have a frame, a housing, a support arm for mounting the mirror on the body of a vehicle, and the like. Alternatively, the mirror with an image display function may be formed to be incorporated into a rearview mirror. In the mirror with an image display function having the aforementioned shape, generally, the directions, right and left and top and bottom, at the time of use can be specified.

The mirror with an image display function may be in the form of a plate or film and may have a curved surface. The front surface of the mirror with an image display function may be flat or curved. In a case where the mirror is curved such that the convex surface becomes the front surface side, the mirror can be used as a wide mirror which makes it possible to secure rearward visibility at a wide angle. The curved front surface can be prepared using a curved half mirror.

The mirror may be curved in either or both of a vertical direction and the horizontal direction. Furthermore, the radius of curvature of the curve may be 500 to 3,000 mm, and is preferably 1,000 to 2,500 mm. The radius of curvature is the radius of a hypothetic circumscribed circle of the curved portion in a cross section.

<<Reflection Layer>>

As the reflection layer, a reflection layer which can function as a half-transmission half-reflection layer may be used. That is, at the time of performing image display, the reflection layer may function to transmit the light emitted from a light source included in the image display device such that an image is displayed on the front surface of the mirror with an image display function. While image display is not being performed, the reflection layer may function to reflect at least some of the incoming rays in the front surface direction and transmit the light reflected from the image display device such that the front surface of the mirror with an image display function becomes a mirror.

As the reflection layer, a polarization reflection layer is used. The polarization reflection layer may be a linear polarization reflection layer or a circular polarization reflection layer.

[Linear Polarization Reflection Layer]

Examples of the linear polarization reflection layer include (i) linear polarization reflection plate having a multilayer structure, (ii) polarizer obtained by laminating thin films of different birefringences, (iii) wire grid-type polarizer, (iv) polarizing prism, and (v) scattering anisotropy-type polarizing plate.

Examples of (i) linear polarization reflection plate having a multilayer structure include a multilayer laminated thin film obtained by laminating dielectric materials of different refractive indices on a support by a vacuum vapor deposition method or a sputtering method in an oblique direction. In order to obtain a wavelength selective reflection film, it is preferable to alternately laminate a plurality of dielectric thin films of high refractive index and a plurality of dielectric thin films of low refractive index. However, the number of kinds of the thin films laminated is not limited to 2, and more kinds of thin films may be laminated. The number of thin films laminated is preferably 2 to 20, more preferably 2 to 12, even more preferably 4 to 10, and particularly preferably 6 to 8. In a case where the number of thin films laminated is greater than 20, the production efficiency is reduced, and hence the objects and effects of the present invention cannot be achieved in some cases.

The method for forming the dielectric thin film is not particularly limited, and can be appropriately selected according to the purpose. Examples thereof include a vacuum vapor deposition method such as ion plating and ion beams, a physical vapor deposition method (PVD method) such as sputtering, and a chemical vapor deposition method (CVD method). Among these, a vacuum vapor deposition method or a sputtering method is preferable, and a sputtering method is particularly preferable.

As (ii) polarizer obtained by laminating thin films of different birefringences, for example, it is possible to use the polarizer described in JP 1997-506837A (JP-H09-506837A) and the like. Furthermore, by performing processing under the condition selected to obtain a desired relationship of refractive index, the polarizer can be formed using a wide variety of materials. Generally, one first material needs to have a refractive index different from that of a second material in a selected direction. The difference in a refractive index can be achieved by various methods in steps such as the formation of a film, the stretching following the formation of a film, extrusion molding, and coating. In addition, it is preferable that the two materials have similar theological characteristics (for example, melt viscosity) such that the materials can be simultaneously extruded.

As the polarizer obtained by laminating thin films of different birefringences, commercial products can be used. Examples of the commercial products include DBEF (registered trademark) (manufactured by 3M).

(iii) wire grid-type polarizer is a polarizer which transmits one polarization while reflects the other polarization by the birefringence of metal thin wires.

The wire grid-type polarizer is a periodic array of metal wires. Therefore, this polarizer is mainly used in a terahertz wave band. In order for the wire grid to function as a polarizer, the wire interval needs to be much smaller than the wavelength of the incoming electromagnetic wave.

In the wire grid-type polarizer, metal wires are arrayed at equal intervals. A polarization component in a polarization direction parallel to the longitudinal direction of the metal wire is reflected from the wire grid-type polarizer, and a polarization component in a polarization direction perpendicular to the longitudinal direction of the metal wire is transmitted through the wire grid-type polarizer.

As the wire grid-type polarizer, commercial products can be used. Examples of the commercial products include a wire grid polarization filter 50×50, NT46-636 (trade name) manufactured by Edmund Optics.

[Circular Polarization Reflection Layer]

In a case where a circular polarization reflection layer is used in the half mirror, the incoming rays from the front surface side can be reflected as circular polarization, and the incoming rays from the image display device can be transmitted as circular polarization. Therefore, with the mirror with an image display function in which the circular polarization reflection layer is used, a display image and an image reflected from the mirror can be observed through polarized sunglasses without relying on the direction of the mirror with an image display function.

Examples of the circular polarization reflection layer include a circular polarization reflection layer including a linear polarization reflection plate and a ¼ wavelength plate and a circular polarization reflection layer including a cholesteric liquid crystal layer (hereinafter, to distinguish between the two circular polarization reflection layers, the former will be referred to as “Polλ/4 circular polarization reflection layer” in some cases, and the latter will be referred to as “cholesteric circular polarization reflection layer” in some cases).

[[Polλ/4 Circular Polarization Reflection Layer]]

In the Polλ/4 circular polarization reflection layer, the linear polarization reflection plate and the ¼ wavelength plate may be disposed such that the slow axis of the ¼ wavelength plate intersects with the polarization reflection axis of the linear polarization reflection plate at 45°. The ¼ wavelength plate and the linear polarization reflection plate may be bonded to each other through an adhesive layer, for example.

In a case where the Polλ/4 circular polarization reflection layer is used in which the linear polarization reflection plate is disposed to become a surface close to the image display device, that is, in a case where the Polλ/4 circular polarization reflection layer is used in which the ¼ wavelength plate and the linear polarization reflection plate are disposed in this order on the pressure sensitive adhesive layer, it is possible to efficiently convert the light for image display from the image display device into circular polarization and to cause the circular polarization to be emitted from the front surface of the mirror with an image display function. In a case where the light for image display from the image display device is linear polarization, the polarization reflection axis of the linear polarization reflection plate may be adjusted such that the linear polarization is transmitted.

The film thickness of the Polλ/4 circular polarization reflection layer is preferably within a range of 2.0 μm to 300 μm, and more preferably within a range of 8.0 μm to 200 μm.

As the linear polarization reflection plate, those described above as the linear polarization reflection layer can be used.

As the ¼ wavelength plate, a ¼ wavelength plate which will be described later can be used.

[Cholesteric Circular Polarization Reflection Layer]

The cholesteric circular polarization reflection layer includes at least one cholesteric liquid crystal layer. The cholesteric liquid crystal layer included in the cholesteric circular polarization reflection layer may perform selective reflection in the visible region.

The circular polarization reflection layer may include two or more cholesteric liquid crystal layers, and may include another layer such as an alignment layer. It is preferable that the circular polarization reflection layer includes only a cholesteric liquid crystal layer. In a case where the circular polarization reflection layer includes a plurality of cholesteric liquid crystal layers, it is preferable that the cholesteric liquid crystal layers adjacent to each other directly contact each other. It is preferable that the number of cholesteric liquid crystal layers included in the circular polarization reflection layer is equal to or greater than 3, such as 3 or 4.

The film thickness of the cholesteric circular polarization reflection layer is preferably within a range of 2.0 μm to 300 μm, and more preferably within a range of 8.0 to 200 μm.

In the present specification, “cholesteric liquid crystal layer” means a layer obtained by fixing a cholesteric liquid crystalline phase. The cholesteric liquid crystal layer is simply referred to as liquid crystal layer in some cases.

The cholesteric liquid crystalline phase is known to perform selective reflection of circular polarization, in which the circular polarization of one rotational sense between right circular polarization and left circular polarization is selectively reflected in a specific wavelength range while circular polarization of the other rotational sense is selectively transmitted. In the present specification, the selective reflection of circular polarization is simply referred to as selective reflection in some cases.

As films including a layer obtained by fixing a cholesteric liquid crystalline phase performing selective reflection of circular polarization, a number of films formed of a composition containing a polymerizable liquid crystal compound have been known in the related art. Regarding the cholesteric liquid crystal layer, these films can be referred to.

The cholesteric liquid crystal layer may be a layer in which the alignment of a liquid crystal compound in a state of a cholesteric liquid crystalline phase is maintained. Typically, the cholesteric liquid crystal layer may be a layer obtained by a process in which a polymerizable liquid crystal compound is aligned to be in the state of a cholesteric liquid crystalline phase and then polymerized and cured by ultraviolet irradiation, heating, or the like so as to form a layer without fluidity, and then the state of the layer is changed such that the alignment form does not change by the external field or the external force. The liquid crystal compound in the cholesteric liquid crystal layer does not need to exhibit liquid crystallinity as long as the optical properties of the cholesteric liquid crystalline phase are maintained in the layer. For example, the polymerizable liquid crystal compound may lose the liquid crystallinity by becoming a high-molecular weight compound through a curing reaction.

A central wavelength λ of selective reflection of the cholesteric liquid crystal layer depends on a pitch P (=period of helix) of the helical structure in the cholesteric liquid crystalline phase and has a relationship of λ=n×P with an average refractive index n of the cholesteric liquid crystal layer. A half-width of the central wavelength of selective reflection of the cholesteric liquid crystal layer can be determined as below.

In a case where the transmission spectrum (measured in a normal direction of the cholesteric liquid crystal layer) of the reflection layer is measured using a spectrophotometer UV3150 (manufactured by Shimadzu Corporation, trade name), transmittance falling peaks are found in a selective reflection region. Provided that the value of wavelength of a short wavelength side is 1l (nm) and the value of wavelength of a long wavelength side is λ2 (nm) between two wavelengths at which the transmittance becomes equal to a height which is ½ of the height of the highest peak, the central wavelength of selective reflection and the half-width can be represented by the following formulae.

Central wavelength of selective reflection=(λ1+λ2)/2

Half-width (λ2−λ1)

Generally, the central wavelength λ of selective reflection performed by the cholesteric liquid crystal layer that is determined as above coincides with the wavelength at the central position of the reflection peak of the circular polarization reflection spectrum measured in the normal direction of the cholesteric liquid crystal layer. In the present specification, “central wavelength of selective reflection” means the central wavelength at the time of measuring the transmission spectrum in the normal direction of the cholesteric liquid crystal layer.

As is evident from the above formulae, the central wavelength of selective reflection can be adjusted by controlling the pitch of the helical structure. By controlling the values of n and P, it is possible to control the central wavelength λ for selectively reflecting any of right-hand circular polarization and left-hand circular polarization for the light of a desired wavelength.

In a case where light obliquely comes into the cholesteric liquid crystal layer, the central wavelength of selective reflection shifts to the short wavelength side. Therefore, it is preferable to adjust the value of n×P such that λ calculated by the above formula λ=n×P becomes a long wavelength with respect to the central wavelength of selective reflection required for image display. In a case where a light ray passes through a cholesteric liquid crystal layer having a refractive index of n₂ at an angle of θ₂ with respect to the normal direction of the cholesteric liquid crystal layer (direction of the helical axis of the cholesteric liquid crystal layer), provided that the central wavelength of selective reflection is λ_{d}, λ_{d} is represented by the following formula.

λ_{d}=n₂×P×cos θ₂

In a case where the central wavelength of selective reflection of the cholesteric liquid crystal layer included in the circular polarization reflection layer is designed in consideration of the relationships described above, it is possible to prevent the reduction of the visibility of an obliquely observed image. Furthermore, it is possible to intentionally reduce the visibility of an obliquely observed image, and doing this thing is useful for preventing peeping in smartphones and personal computers, for example. In addition, due to the selective reflection properties described above, in a case where the mirror with an image display function of the embodiment of the present invention is seen in an oblique direction, sometimes tint appears in an image or an image reflected from the mirror. By incorporating the cholesteric liquid crystal layer having the central wavelength of selective reflection in the infrared region into the circular polarization reflection layer, the appearance of the tint can also be prevented. In this case, specifically, the central wavelength of selective reflection of the infrared region may be 780 to 900 nm, and preferably 780 to 850 nm.

In a case where cholesteric liquid crystal layers having the central wavelength of selective reflection in the infrared region are provided, it is preferable that all the cholesteric liquid crystal layers each having the central wavelength of selective reflection in the visible region are provided on a side which is closest to the image display device side.

The pitch of the cholesteric liquid crystalline phase depends on the type of a chiral agent used together with the polymerizable liquid crystal compound or on the concentration of the chiral agent added. Consequently, by adjusting the type and concentration of the chiral agent, an intended pitch can be obtained. For measuring the sense or pitch of the helix, it is possible to use the methods described in “Introduction to Experiment of Liquid Crystal Chemistry” (edited by The Japanese Liquid Crystal Society, Sigma Publication Ltd, 2007, p. 46) and “Handbook of Liquid Crystal” (Editorial Committee of Handbook of Liquid Crystal, MARUZEN Co., Ltd. p. 196).

In the mirror with an image display function of the embodiment of the present invention, the circular polarization reflection layer preferably includes a cholesteric liquid crystal layer having a central wavelength of selective reflection in a wavelength range of red light, a cholesteric liquid crystal layer having a central wavelength of selective reflection in a wavelength range of green light, and a cholesteric liquid crystal layer having a central wavelength of selective reflection in a wavelength range of blue light. The reflection layer preferably includes, for example, a cholesteric liquid crystal layer having a central wavelength of selective reflection in a wavelength range of 400 nm to 500 nm, a cholesteric liquid crystal layer having a central wavelength of selective reflection in a wavelength range of 500 nm to 580 nm, and a cholesteric liquid crystal layer having a central wavelength of selective reflection in a wavelength range of 580 nm to 700 nm.

In a case where the circular polarization reflection layer includes a plurality of cholesteric liquid crystal layers, it is preferable that a cholesteric liquid crystal layer closer to the image display device has a longer central wavelength of selective reflection. By this constitution, the tint that obliquely appears in an image can be inhibited.

particularly, in the mirror with an image display function in which the cholesteric circular polarization reflection layer without a ¼ wavelength plate is used, it is preferable that there is a difference equal to or greater than 5 nm between the central wavelength of selective reflection of each of the cholesteric liquid crystal layers and the emission peak wavelength of the image display device. The difference is more preferably equal to or greater than 10 nm. By causing a difference between the central wavelength of selective reflection and the emission peak wavelength for image display of the image display device, it is possible to brighten the display image without causing the light for image display from being reflected from the cholesteric liquid crystal layer. The emission peak wavelength of the image display device can be checked in an emission spectrum at the time of white display of the image display device. The peak wavelength may be a peak wavelength in a visible region of the emission spectrum. For example, as the peak wavelength, at least one or more wavelengths selected from the group consisting of an emission peak wavelength λR of red light, an emission peak wavelength λG of green light, and an emission peak wavelength λB of blue light of the image display device may be adopted. The difference between the central wavelength of selective reflection of the cholesteric liquid crystal layer and all of the emission peak wavelength λR of red light, the emission peak wavelength λG of green light, and the emission peak wavelength λB of blue light of the image display device is preferably equal to or greater than 5 nm, and more preferably equal to or greater than 10 nm. In a case where the circular polarization reflection layer includes a plurality of cholesteric liquid crystal layers, the difference between the central wavelength of selective reflection of all the cholesteric liquid crystal layers and the peak wavelength of the light emitted from the image display device is equal to or greater than 5 nm, and preferably equal to or greater than 10 nm. For example, in a case where the image display device is a full color display device showing the emission peak wavelength λR of red light, the emission peak wavelength λG of green light, and the emission peak wavelength λB of blue light in an emission spectrum at the time of white display, the difference between all the central wavelengths of selective reflection of the cholesteric liquid crystal layers and λR, λG, and λB is equal to or greater than 5 nm, and preferably equal to or greater than 10 nm.

By adjusting the central wavelength of selective reflection of the used cholesteric liquid crystal layer according to the emission wavelength range of the image display device and the aspect of using the circular polarization reflection layer, a bright image can be displayed with an excellent light use efficiency. Examples of the aspect of using the circular polarization reflection layer particularly include an incidence angle of light coming into the circular polarization reflection layer, an image observation direction, and the like.

As each of the cholesteric liquid crystal layers, a cholesteric liquid crystal layer in which the helix rotates in any of a right-hand sense and a left-hand sense is used. The sense of the circular polarization reflected from the cholesteric liquid crystal layer coincides with the sense of the helix. The senses of helices of a plurality of cholesteric liquid crystal layers may be the same as each other, or the senses of helices of some of the cholesteric liquid crystal layers may be different. That is, the cholesteric liquid crystal layers may include cholesteric liquid crystal layers of any of the right-hand sense and the left-hand sense or cholesteric liquid crystal layers of both of the right-hand sense and the left-hand sense. Here, in a mirror with an image display function including a ¼ wavelength plate, it is preferable that the senses of the helices of the plurality of cholesteric liquid crystal layers are the same as each other. In this case, the sense of the helix of each of the cholesteric liquid crystal layers may be determined according to the sense of the circular polarization obtained by the emission from the image display device and the transmission through the ¼ wavelength plate. Specifically, a cholesteric liquid crystal layer may be used which has the sense of a helix that transmits the circular polarization of a sense obtained by the emission from the image display device and the transmission through the ¼ wavelength plate.

A half-band width Δλ (nm) of a selective reflection band in which the selective reflection occurs depends on a birefringence Δn of the liquid crystal compound and the pitch P described above, and satisfies a relationship of Δλ=Δn×P. Therefore, by adjusting Δn, the width of the selective reflection band can be controlled. Δn can be controlled by adjusting the type of the polymerizable liquid crystal compound, adjusting a mixing ratio thereof, or controlling the temperature at the time of fixing the alignment.

In order to form one kind of cholesteric liquid crystal layers having the same central wavelength of selective reflection, a plurality of cholesteric liquid crystal layers having the same period P and the same helical sense may be laminated. By laminating cholesteric liquid crystal layers having the same period P and the same helical sense, the selectivity for circular polarization at a specific wavelength can be improved.

(¼ Wavelength plate)

In the mirror with an image display function in which the cholesteric circular polarization reflection layer is used, the half mirror may further include a ¼ wavelength plate. It is preferable that the half mirror includes a phase difference film of high Re (in-plane retardation), a cholesteric circular polarization reflection layer, and a ¼ wavelength plate in this order.

In a case where the half mirror includes the ¼ wavelength plate between the image display device and the cholesteric circular polarization reflection layer, particularly, the light from the image display device displaying an image by linear polarization can be converted into circular polarization and come into the cholesteric circular polarization reflection layer. Accordingly, it is possible to significantly reduce the light which is reflected from the circular polarization reflection layer and returns to the image display device side, and a bright image can be displayed. In addition, because the mirror can have a constitution in which the circular polarization of a sense that is reflected to the image display device side in the cholesteric circular polarization reflection layer is not generated by the use of the ¼ wavelength plate, the deterioration of the quality of the displayed image resulting from the multiple reflection between the image display device and the half mirror does not easily occur.

That is, for example, even though the central wavelength of selective reflection of the cholesteric liquid crystal layer included in the cholesteric circular polarization reflection layer is approximately the same as the emission peak wavelength of blue light in the emission spectrum at the time of white display of the image display device (for example, even though the difference is less than 5 nm), it is possible to allow the light emitted from the image display device to be transmitted to the front surface side without generating circular polarization of a sense that is reflected to the image display side in the circular polarization reflection layer.

It is preferable that the angle of the ¼ wavelength plate, which is used by being combined with the cholesteric circular polarization reflection layer, is adjusted such that the image becomes the brightest in a case where the ¼ wavelength plate is bonded to the image display device. That is, particularly, in order that linear polarization is transmitted best for the image display device displaying an image by the linear polarization, it is preferable that the relationship between the polarization direction (transmission axis) of the linear polarization and the slow axis of the ¼ wavelength plate is adjusted. For example, in a case where a single layer-type ¼ wavelength plate is used, it is preferable that an angle of 45° is formed between the transmission axis and the slow axis. The light emitted from the image display device displaying an image by the linear polarization is transmitted through the ¼ wavelength plate and then becomes any of circular polarization of a right-hand sense and circular polarization of a left-hand sense. The circular polarization reflection layer may be constituted with a cholesteric liquid crystal layer having a twisted direction transmitting the circular polarization of the aforementioned sense.

The ¼ wavelength plate may be a phase difference layer which functions as a ¼ wavelength plate in a visible region. Examples of the ¼ wavelength plate include a single layer-type ¼ wavelength plate, a broadband ¼ wavelength plate obtained by laminating a ¼ wavelength plate and a ½ wavelength phase difference plate, and the like.

The frontal phase difference of the former ¼ wavelength plate may be equal to a length that is ¼ of the emission wavelength of the image display device. Therefore, for example, in a case where the emission wavelength of the image display device is 450 nm, 530 nm, and 640 nm, as the ¼ wavelength plate, a phase difference layer having reverse dispersion properties is most preferable which results in a phase difference of 112.5 nm±10 nm, preferably 112.5 nm±5 nm, and more preferably 112.5 nm at a wavelength of 450 nm, a phase difference of 132.5 nm±10 nm, preferably 132.5 nm±5 nm, and more preferably 132.5 nm at a wavelength of 530 nm, and a phase difference of 160 nm±10 nm, preferably 160 nm±5 nm, and more preferably 160 nm at a wavelength of 640 nm. As the ¼ wavelength plate, it is also possible to use a phase difference plate which results in a phase difference having low wavelength dispersion properties or a phase difference plate having forward dispersion properties. “Reverse dispersion properties” mean properties in which the longer the wavelength is, the larger the absolute value of the phase difference becomes. “Forward dispersion properties” means properties in which the shorter the wavelength is, the greater the absolute value of the phase difference becomes.

In the laminate-type ¼ wavelength plate, a ¼ wavelength plate and a ½ wavelength phase difference plate are bonded to each other such that the slow axes thereof intersect at an angle of 60°, and the ½ wavelength phase difference plate is disposed such that it becomes a side into which linear polarization comes. Furthermore, the laminate-type ¼ wavelength plate is used in a state where the slow axis of the ½ wavelength phase difference plate intersects the polarization surface of the incoming linear polarization at an angle of 15° C. or 75°. Accordingly, the reverse dispersion properties of the phase difference are excellent, and hence the laminate-type ¼ wavelength plate can be suitably used.

A λ/4 wavelength plate can be appropriately selected according to the purpose without particular limitation. For example, it is possible to use a quartz plate, a stretched polycarbonate film, a stretched norbornene-based polymer film, a transparent film containing aligned inorganic particles having birefringence such as strontium carbonate, a thin film obtained by obliquely vapor-depositing inorganic dielectric material on a support, and the like.

Examples of the λ/4 wavelength plate include (1) phase difference plate described in JP1993-027118A (JP-H05-027118A) and JP1993-027119A (JP-H05-027119A) that is obtained by laminating a birefringent film having a large retardation and a birefringent film having a small retardation such that the optical axes of the films become orthogonal to each other, (2) phase difference plate described in JP1998-068816A (JP-H10-068816A) that is prepared by laminating a polymer film, which results in a λ/4 wavelength at a specific wavelength, and a polymer film, which is formed of the same material as that of the aforementioned polymer film and results in a λ/2 wavelength at the same wavelength, so as to obtain a λ/4 wavelength in a wide wavelength range, (3) phase difference plate described in JP1998-090521A (JP-H10-90521A) that can accomplish a λ/4 wavelength in a wide wavelength range by the lamination of two sheets of polymer films, (4) phase difference plate described in WO00/026705A that can accomplish a λ/4 wavelength in a wide wavelength range by using a modified polycarbonate film, (5) phase difference plate described in WO0/065384A that can accomplish a λ/4 wavelength in a wide wavelength range by using a cellulose acetate film, and the like.

As the λ/4 wavelength plate, commercial products can also be used. Examples of the commercial products include PLUREACE (registered trademark) WR (polycarbonate film manufactured by TEJIN LIMITED).

The ¼ wavelength plate may be formed by aligning and fixing a polymerizable liquid crystal compound and a high-molecular weight liquid crystal compound. For example, the ¼ wavelength plate can be formed by coating a temporary support, an alignment film, or a surface of a front panel with a liquid crystal composition, forming an nematic alignment of the polymerizable liquid crystal compound in the liquid crystal composition in a liquid crystal state, and then fixing the alignment state by means of photocrosslinking and/or thermal crosslinking. The details of the liquid crystal composition and the preparation method thereof will be described later. The ¼ wavelength plate may also be a layer obtained by coating a temporary support, an alignment film, or a surface of a front panel with a composition containing a high-molecular weight liquid crystal compound, forming a nematic alignment in a liquid crystal state, and then fixing the alignment state by cooling.

The λ/4 wavelength plate may directly contact the cholesteric circular polarization reflection layer or may be bonded to the cholesteric circular polarization reflection layer through an adhesive layer. It is preferable that the λ/4 wavelength plate directly contacts the cholesteric circular polarization reflection layer.

(Methods for Preparing Cholesteric Liquid Crystal Layer and ¼ Wavelength Plate Formed of Liquid Crystal Composition)

Hereinafter, the materials used for preparing the cholesteric liquid crystal layer and the ¼ wavelength plate formed of a liquid crystal composition and the methods for preparing the cholesteric liquid crystal layer and the ¼ wavelength plate will be described.

Examples of the material used for forming the ¼ wavelength plate include a liquid crystal composition containing a polymerizable liquid crystal compound, and the like. Examples of the material used for forming the cholesteric liquid crystal layer include a liquid crystal composition containing a polymerizable liquid crystal compound and a chiral agent (optically active compound), and the like. If necessary, by coating a temporary support, a support, an alignment film, a phase difference film of high Re, a cholesteric liquid crystal layer which will become an underlayer, a ¼ wavelength plate, and the like with the liquid crystal composition mixed with a surfactant, a polymerization initiator, and the like and then dissolved in a solvent, performing alignment and maturing, and then performing fixing by curing the liquid crystal composition, the cholesteric liquid crystal layer and/or the ¼ wavelength plate can be formed.

—Polymerizable Liquid Crystal Compound—

As the polymerizable liquid crystal compound, polymerizable rod-like liquid crystal compound may be used.

Examples of the rod-like polymerizable liquid crystal compound include rod-like nematic liquid crystal compounds. As the rod-like nematic liquid crystal compounds, azomethines, azoxys, cyanobiphenyls, cyanophenyl esters, benzoic acid esters, cyclohexanecarboxylic acid phenyl esters, cyanophenylcyclohexanes, cyano-substituted phenylpyrimidines, alkoxy-substituted phenylpyrimidines, phenyldioxanes, tolanes, and alkenylcyclohexyl benzonitriles are preferably used. Not only low-molecular weight liquid crystal compounds, but also high-molecular weight liquid crystal compounds can be used.

The polymerizable liquid crystal compound can be obtained by introducing a polymerizable group into a liquid crystal compound. Examples of the polymerizable group include an unsaturated polymerizable group, an epoxy group, and an aziridinyl group. Among these, an unsaturated polymerizable group is preferable, and an ethylenically unsaturated polymerizable group is particularly preferable. The polymerizable group can be introduced into a molecule of a liquid crystal compound by various methods. The number of polymerizable groups contained in the polymerizable liquid crystal compound is preferably 1 to 6, and more preferably 1 to 3. Examples of the polymerizable liquid crystal compound include the compounds described in Makromol. Chem., vol. 190, p. 2255 (1989), Advanced Materials, vol. 5, p. 107 (1993), U.S. Pat. Nos. 4,683,327A, 5,622,648A, 5,770,107A, WO95/022586A, WO95/024455A, WO97/000600A, WO98/023580A, WO98/052905A. JP1989-272551A (JP-H01-272551A), JP 1994-016616A (JP-H06-016616A), JP1995-110469A (JP-H07-110469A), JP1999-080081A (JP-H11-080081A), JP2001-328973A, and the like. One kind of polymerizable liquid crystal compound may be used singly, or two or more kinds of polymerizable liquid crystal compounds may be used in combination. In a case where two or more kinds of polymerizable liquid crystal compounds are used in combination, the alignment temperature can be reduced.

The content of the polymerizable liquid crystal compound in the liquid crystal composition is preferably 80% to 99.9% by mass, more preferably 85% to 99.5% by mass, and particularly preferably 90% to 99% by mass with respect to the mass (mass excluding a solvent) of the solid content of the liquid crystal composition.

—Chiral Agent: Optically Active Compound—

It is preferable that the material used for forming the cholesteric liquid crystal layer contains a chiral agent. The chiral agent has a function of inducing the helical structure of the cholesteric liquid crystalline phase. Because the sense or pitch of the induced helix varies with the compound as the chiral agent, the chiral agent may be selected according to the purpose.

The chiral agent is not particularly limited, and it is possible to use generally used compounds (for example, those described in Chapter 3, 4-3. <Chiral agents for TN and STN> in Handbook of Liquid Crystal Device, edited by the 142^{nd} committee of Japan Society for The Promotion of Science, p. 199, 1989,), isosorbide, and isomannide derivatives.

Generally, the chiral agent contains asymmetric carbon atoms. However, an axially asymmetric compound and a planarly asymmetric compound not containing asymmetric carbon atoms can also be used as the chiral agent. Examples of the axially asymmetric compound and the planarly asymmetric compound include binaphthyl, helicene, paracyclophane, and derivatives of these. The chiral agent may have a polymerizable group. In a case where both the chiral agent and the liquid crystal compound have a polymerizable group, by a polymerization reaction between the polymerizable chiral agent and the polymerizable liquid crystal compound, it is possible to form a polymer having a repeating unit derived from the polymerizable liquid crystal compound and a repeating unit derived from the chiral agent. In this aspect, the polymerizable group contained in the polymerizable chiral agent is preferably the same type of polymerizable group as the polymerizable group contained in the polymerizable liquid crystal compound. Accordingly, the polymerizable group of the chiral agent is also preferably an unsaturated polymerizable group, an epoxy group, or an aziridinyl group, more preferably an unsaturated polymerizable group, and particularly preferably an ethylenically unsaturated polymerizable group.

Furthermore, the chiral agent may be a liquid crystal compound.

In the liquid crystal composition, the content of the chiral agent with respect to 100 mol of the polymerizable liquid crystal compound is preferably 0.01 mol to 200 mol, and more preferably 1 mol to 30 mol.

—Polymerization Initiator—

It is preferable that the liquid crystal composition used in the present invention contains a polymerization initiator. In an aspect in which a polymerization reaction is caused by ultraviolet irradiation, as the polymerization initiator, it is preferable to use a photopolymerization initiator that can initiate the polymerization reaction by ultraviolet irradiation. Examples of the photopolymerization initiator include an α-carbonyl compound (described in U.S. Pat. Nos. 2,367,661A and 2,367,670A), an acyloin ether (described in U.S. Pat. No. 2,448,828A), an α-hydrocarbon-substituted aromatic acyloin compound (described in U.S. Pat. No. 2,722,512A), a polynuclear quinone compound (described in U.S. Pat. Nos. 3,046,127A and 2,951,758A), a combination of triarylimidazole dimer and p-aminophenylketone (described in U.S. Pat. No. 3,549,367A), acrydine and phenazine compounds (described in JP1985-105667A (JP-S60-105667A) and U.S. Pat. No. 4,239,850A), acylphosphine oxide compounds (described in JP1988-040799B (JP-S63-040799B, JP1993-029234B (JP-H05-029234B), JP1998-095788A (JP10-095788A), JP1988-029997A (JP-H10-029997A), oxime compounds (described in JP2000-066385A and JP4454067B) an oxadiazole compound (described in U.S. Pat. No. 4,212,970A), and the like.

The content of the photopolymerization initiator in the liquid crystal composition with respect to 100 parts by mass of the polymerizable liquid crystal compound is preferably 0.1 to 20 parts by mass, and more preferably 0.5 to 5 parts by mass.

—Crosslinking Agent—

For the purpose of improving the film hardness after curing and improving durability, the liquid crystal composition may optionally contain a crosslinking agent. As the crosslinking agent, those cured by ultraviolet rays, heat, moisture, or the like can be suitably used.

The crosslinking agent is not particularly limited and can be appropriately selected according to the purpose. Examples of the crosslinking agent include a polyfunctional acrylate compound such as trimethylolpropane tri(meth)acrylate and pentaerythritol tri(meth)acrylate; an epoxy compound such as glycidyl (meth)acrylate and ethylene glycol diglycidyl ether: an aziridine compound such as 2,2-bishydroxymethylbutanol-tris[3-(1-aziridinyl)propionate] and 4,4-bis(ethyleneiminocarbonylamino)diphenylmethane; an isocyanate compound such as hexamethylene diisocyanate and biuret-type isocyanate; a polyoxazoline compound having an oxazoline group on a side chain; an alkoxysilane compound such as vinyltrimethoxysilane and N-(2-aminoethyl)3-aminopropyl trimethoxysilane; and the like. Furthermore, depending on the reactivity of the crosslinking agent, a generally used catalyst can be used. In a case where the catalyst is used, it is possible to improve the productivity in addition to the film hardness and durability. One kind of crosslinking agent may be used singly, or two or more kinds of crosslinking agents may be used in combination.

The content of the crosslinking agent in the liquid crystal composition is preferably 3% by mass to 20% by mass, and more preferably 5% by mass to 15% by mass. In a case where the content of the crosslinking agent is equal to or greater than the lower limit described above, a crosslinking density improving effect can be obtained. Furthermore, in a case where the content of the crosslinking agent is equal to or smaller than the upper limit described above, the stability of the formed layer can be maintained.

—Alignment Control Agent—

An alignment control agent, which makes a contribution to stably and rapidly form a planar alignment, may be added to the liquid crystal composition. Examples of the alignment control agent include fluorine (meth)acrylate-based polymers described in paragraphs “0018” to “0043” in JP2007-272185A, the compounds represented by Formulae (I) to (IV) described in paragraphs “0031” to “0034” in JP2012-203237A, and the like.

One kind of alignment control agent may be used singly, or two or more kinds of alignment control agents may be used in combination.

The amount of the alignment control agent added to the liquid crystal composition with respect to a total of 100 parts by mass of the polymerizable liquid crystal compound is preferably 0.01 to 10 parts by mass, more preferably 0.01 to 5 parts by mass, and particularly preferably 0.02 to 1 part by mass.

—Other Additives—

In addition, the liquid crystal composition may contain at least one kind of component selected from various additives such as a surfactant, which is for uniformizing the film thickness by adjusting the surface tension of the coating film, and a polymerizable monomer. Furthermore, if necessary, within a range that does not deteriorate the optical performance, a polymerization inhibitor, an antioxidant, an ultraviolet absorber, a light stabilizer, a coloring material, metal oxide particles, and the like can be added to the liquid crystal composition.

—Solvent—

The solvent used for preparing the liquid crystal composition is not particularly limited and can be appropriately selected according to the purpose. However, it is preferable to use an organic solvent.

The organic solvent is not particularly limited and can be appropriately selected according to the purpose. Examples of the organic solvent include ketones, alkyl halides, amides, sulfoxides, heterocyclic compounds, hydrocarbons, esters, ethers, and the like. One kind of organic solvent may be used singly, or two or more kinds of organic solvents may be used in combination. Among these, considering the load imposed on the environment, ketones are particularly preferable.

—Coating, Alignment, and Polymerization—

The method for coating a temporary support, an alignment film, a phase difference film of high Re, a ¼ wavelength plate, and/or a cholesteric liquid crystal layer which will become an underlayer with the liquid crystal composition is not particularly limited, and can be appropriately selected according to the purpose. Examples of the coating method include a wire bar coating method, a curtain coating method, an extrusion coating method, a direct gravure coating method, a reverse gravure coating method, a die coating method, a spin coating method, a dip coating method, a spray coating method, a slide coating method, and the like. Furthermore, the coating method can be performed by transferring the liquid crystal composition which has been separately applied onto a support. By heating the liquid crystal composition used for coating, the liquid crystal molecules are aligned. At the time of forming the cholesteric liquid crystal layer, the liquid crystal molecules may be aligned in a cholesteric phase. At the time of forming the ¼ wavelength plate, the liquid crystal molecules are preferably aligned in a nematic phase. At the time of cholesteric alignment, the heating temperature is preferably equal to or lower than 200° C., and more preferably equal to or lower than 130° C. By the alignment treatment, an optical thin film is obtained in which the polymerizable liquid crystal compound is aligned in a twisted state so as to have a helical axis in a direction that is substantially perpendicular to the plane of the film. At the time of nematic alignment, the heating temperature is preferably 25° C. to 120° C., and more preferably 30° C. to 100° C.

The aligned liquid crystal compound can be further polymerized such that the liquid crystal composition is cured. The polymerization may be any of thermal polymerization and photopolymerization performed by light irradiation, but is preferably photopolymerization. It is preferable to use ultraviolet rays for the light irradiation. The irradiation energy is preferably 20 mJ/cm² to 50 J/cm², and more preferably 100 mJ/cm² to 1,500 mJ/cm². In order to accelerate the photopolymerization reaction, the light irradiation may be performed under heating conditions or in a nitrogen atmosphere. The wavelength of the ultraviolet rays for irradiation is preferably 350 nm to 430 nm. From the viewpoint of stability, it is preferable that the polymerization reaction rate is high. Specifically, the polymerization reaction rate is preferably equal to or higher than 70%, and more preferably equal to or higher than 80%. The polymerization reaction rate can be determined by measuring the consumption rate of polymerizable functional groups by using an IR absorption spectrum.

The thickness of each cholesteric liquid crystal layer is not particularly limited as long as the thickness is within a range in which the aforementioned characteristics are exhibited. The thickness of each cholesteric liquid crystal layer is preferably within a range equal to or greater than 1.0 μm and equal to or smaller than 150 μm, and more preferably within a range equal to or greater than 2.5 μm and equal to or smaller than 100 μm. Furthermore, the thickness of the ¼ wavelength plate formed of the liquid crystal composition is not particularly limited, but may be preferably 0.2 to 10 μm, and more preferably 0.5 to 2 μm.

### EXAMPLES

Hereinafter, the present invention will be more specifically described based on examples, but the present invention is not limited thereto. In the following examples, unless otherwise specified, “part” and “%” showing a composition are based on mass.

### EXAMPLES

### Example 1

<1. Preparation of Resin Film>

(1) Preparation of Cellulose Acylate Dope Solution for Core Layer

The following composition was put into a mixing tank and stirred, thereby preparing a cellulose acylate dope solution for a core layer.

Cellulose acylate dope solution for core layer

| | |
|---|---|
| Cellulose acetate with degree of acetyl substitution | 100 parts by mass |
| of 2.88 and weight-average molecular weight of | |
| 260,000 | |
| Phthalic acid ester oligomer A having the following | 10 parts by mass |
| structure | |
| Compound (A-1)represented by the following | 4 parts by mass |
| Formula I | |
| Ultraviolet absorber represented by the following | 2.7 parts by mass |
| Formula II (manufactured by BASF SE) | |
| Light stabilizer (manufacturedby BASE SE, trade | 0.18 parts by mass |
| name: TINUVIN 123) | |
| N-alkenylpropylenediamine tetraacetic acid | 0.02 parts by mass |
| (manufactured by Nagase ChemteX Corporation, | |
| trade name: TEKURAN DO) | |
| Methylene chloride (first solvent) | 430 parts by mass |
| Methanol (second solvent) | 64 parts by mass |

The used compounds will be shown below.

Phthalic acid ester oligomer A (weight-average molecular weight: 750)

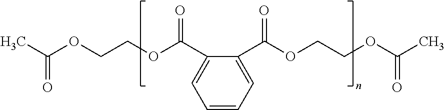

Compound (A-1) represented by the following Formula 1

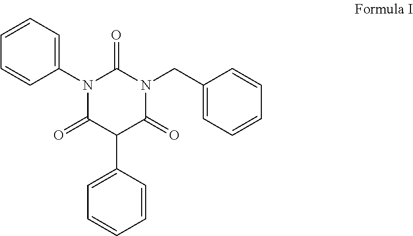 [SMILES: O=C1C(c2ccccc2)C(=O)N(c2ccccc2)C(=O)N1Cc1ccccc1]

Ultraviolet Absorber Represented by Formula II

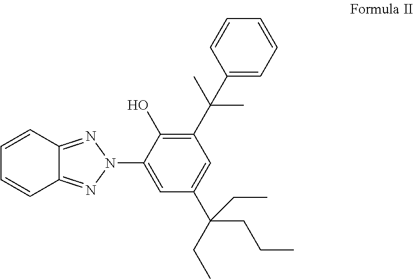 [SMILES: CCCC(CC)(CC)c1cc(-n2nc3ccccc3n2)c(O)c(C(C)(C)c2ccccc2)c1]

(2) Preparation of Cellulose Acylate Dope Solution for Outer Layer

A composition containing inorganic particles shown below (10 parts by mass) was added to 90 parts by mass of the aforementioned cellulose acylate dope solution for a core layer, thereby preparing a cellulose acylate dope solution for an outer layer.

Composition containing inorganic particles

| | |
|---|---|
| Silica particles having average primary particle | 2 parts by mass |
| diameter of 20 nm (manufactured by NIPPON | |
| AEROSIL CO., LTD, trade name: AEROSIL | |
| R972) | |
| Methylene chloride (first olvent) | 76 parts by mass |
| Methanol (second solvent) | 11 parts by mass |
| Cellulose acylate dope solution for core layer | 1 part by mass |

(3) Preparation of Resin Film (TAC-1)

In order for the cellulose acylate dope solution for an outer layer to be positioned on both sides of the cellulose acylate dope solution for a core layer, three kinds of solutions including the cellulose acylate dope solution for an outer layer, the cellulose acylate dope solution for a core layer, and the cellulose acylate dope solution for an outer layer were simultaneously cast onto a casting band with a surface temperature of 20° C. from a casting outlet.

As the casting band, an endless band was used which was made of stainless steel and had a width of 2.1 m and a length of 70 m. The casting band was polished such that it had a thickness of 1.5 mm and a surface roughness equal to or lower than 0.05 μm. The material of the casting band was SUS 316 and had sufficient corrosion resistance and hardness. The thickness unevenness of the entirety of the casting band was equal to or lower than 0.5%.

The surface of the obtained casting film was exposed to the air for fast drying with a gas concentration of 16% and a temperature of 60° C. at a wind speed of 8 m/s, thereby forming an initial film. Then, drying air with a temperature of 140° C. was blown to the film from the upstream side of the upper portion of the casting band. Furthermore, drying air with a temperature of 120° C. and drying air with a temperature of 60° C. were blown to the film from the downstream side.

After the amount of residual solvent became about 33% by mass, the film was peeled off from the band. Then, both ends of the obtained film in the width direction were fixed to tenter clips, and after the amount of residual solvent became 3% to 15% by mass, the film was dried while being stretched 106% in the cross direction. Thereafter, the film was transported between rolls of a heat treatment apparatus and then further dried, thereby preparing a resin film (TAC-1) having a thickness of 80 μm (outer layer/core layer/outer layer=3 μm/74 μm/3 μm).

<2. Preparation of Pressure Sensitive Adhesive Sheet>

### Synthesis Example 1: Synthesis of Aqueous Dispersion-Type (Meth)Acrylic Polymer (A)

A reaction container including a cooling pipe, a nitrogen introduction pipe, a thermometer, and a stirrer is filled with a substance obtained by emulsifying 96 parts of butyl acrylate (BA), 4 parts of acrylic acid (AA), 0.08 parts of t-dodecanethiol (chain transfer agent), 2 parts of sodium polyoxyethylene lauryl sulfate (emulsifier), and 153 parts of deionized water (that is, an emulsion of monomer raw materials). In a state where nitrogen gas was being introduced into the container, the substance was stirred for 1 hour at room temperature (25° C.).

Then, the emulsion was heated to 60° C., and 0.1 parts (amount of solid content) of 2,2′-azobis[N-(2-carboxyethyl)-2-methylpropionamidine]hydrate (polymerization initiator) (trade name: VA-057, manufactured by Wako Pure Chemical Industries, Ltd.) prepared as a 10% aqueous solution was added thereto, and the mixture was polymerized by being stirred for 3 hours at 60° C. Aqueous ammonia (10%) was added to the reaction solution so as to adjust the pH of the solution to be 7.5, thereby obtaining an aqueous dispersion-type (meth)acrylic polymer (A).

The aqueous dispersion-type (meth)acrylic polymer (A) (70 parts, amount of solid content) obtained in Synthesis Example 1 was mixed with 30 parts (amount of solid content) of synthetic polyisoprene latex (trade name: CEPOREX IR-100K, manufactured by Sumitomo Seika Chemicals Company. Ltd). Then, as a viscosity imparting agent, 25 parts (amount of solid content) of aromatic modified terpene resin emulsion (trade name: NANOLET R-1050, manufactured by YASUHARA CHEMICAL CO., LTD., softening point: 100° C.) was mixed with the mixture, and the mixture was further mixed with 0.07 parts of an epoxy-based crosslinking agent (trade name: TETRAD-C, manufactured by MITSUBISII GAS CHEMICAL COMPANY, INC.), thereby preparing an aqueous dispersion-type pressure sensitive adhesive composition.

A release-treated surface of a release sheet (manufactured by Lintec Corporation, trade name: SP-PET3811), which was obtained by performing a release treatment on one surface of a polyethylene terephthalate film by using a silicone-based release agent, was coated with the aqueous dispersion-type pressure sensitive adhesive composition prepared as above, such that the thickness thereof became 15 μm after drying. The release sheet was heated for 1 minute at an atmospheric temperature of 100° C., thereby forming a pressure sensitive adhesive layer. The pressure sensitive adhesive layer was bonded to a release-treated surface of another release sheet (manufactured by Lintec Corporation, trade name: SP-PET3801) obtained by performing a release treatment on one surface of a polyethylene terephthalate film by using a silicone-based release agent, thereby preparing a pressure sensitive adhesive sheet constituted with release sheet/pressure sensitive adhesive layer/release sheet laminated in this order.

<3. Preparation of Laminate (Bonding of Pressure Sensitive Adhesive Layer)>

The release sheet on one side of the pressure sensitive adhesive sheet was peeled such that the pressure sensitive adhesive layer was exposed. The exposed pressure sensitive adhesive layer and the resin film (TAC-1) were bonded to each other by a rubber roller under a load of 2 kg applied thereto such that the pressure sensitive adhesive layer became adjacent to a surface of the resin film (TAC-1) contacting the casting band, thereby preparing a laminate of Example 1 having the constitution shown in FIG. 1.

### Example 2

A laminate of Example 2 having the constitution shown in FIG. 1 was prepared by forming films in the same manner as in Example 1, except that the stretching ratio in the width direction was set to be 109% in the preparation of the resin film.

### Example 3

A laminate of Example 3 having the constitution shown in FIG. 1 was prepared by forming films in the same manner as in Example 1, except that the stretching ratio in the width direction was set to be 112% in the preparation of the resin film.

### Example 4

A laminate of Example 4 having the constitution shown in FIG. 1 was prepared by forming films in the same manner as in Example 1, except that the stretching ratio in the width direction was set to be 118% in the preparation of the resin film.

### Example 5

A laminate of Example 5 having the constitution shown in FIG. 1 was prepared by forming films in the same manner as in Example 1, except that the stretching ratio in the width direction was set to be 125% in the preparation of the resin film.

### Example 6

A laminate of Example 6 having the constitution shown in FIG. 1 was prepared by forming films in the same manner as in Example 4, except that the film thickness of the resin film obtained after drying was set to be 100 μm (outer layer/core layer/outer layer=3 μm/94 μm/3 μm).

### Example 7

A laminate of Example 7 having the constitution shown in FIG. 1 was prepared by forming films in the same manner as in Example 4, except that the film thickness of the resin film obtained after drying was set to be 120 μm (outer layer/core layer/outer layer=3 μm/114 μm/3 μm).

### Example 8

<1. Preparation of Resin Film (PMMA/PC/PMMA)>

Pellets of an acrylic resin (trade name: SUMIPEX EX) manufactured by Sumitomo Chemical Co., Ltd were put into a single-screw extruder having an extrusion diameter of 65 mm, and a polycarbonate-based resin (trade name: CALIBRE 301-10) manufactured by Sumika Styron Polycarbonate Limited was put into a single-screw extruder having an extrusion diameter of 45 mm. The resins were melted, and integrated by being melted and laminated by a multi-manifold method. Then, each layer was controlled such that the film thickness thereof became 35 μm/230 μm/35 μm after drying, and the resin was extruded through T-shaped dies at a set temperature of 260° C. The obtained film-shaped substance was molded by being sandwiched between a pair of metal rolls, thereby preparing a resin film (PMMA/PC/PMMA) which had a thickness of 300 μm and was constituted with three layers including acrylic resin film/polycarbonate-based resin film/acrylic resin film.

<2. Preparation of Laminate>

A laminate of Example 8 having the constitution shown in FIG. 1 was prepared by the same method as that in Example 1, except that the aforementioned resin film (PMMA/PC/PMMA) was used instead of the resin film (TAC-1).

### Example 9

<1. Preparation of Composition for Forming Easily Adhesive Layer>

(1) Preparation of Polyester-Based Resin

Polymerizable compounds composed as below were copolymerized, thereby obtaining a sulfonic acid-based aqueous dispersion of a polyester-based resin.

(Acid components) terephthalic acid/isophthalic acid/sodium 5-sulfoisophthalate/(diol components) ethylene glycol/diethylene glycol=44/46/10/84/16 (molar ratio)

(2) Preparation of Crosslinking Agent (Isocyanate-Based Compound A)

Nitrogen purging was performed in a 4-neck flask (reactor) equipped with a stirrer, a thermometer, a reflux cooling pipe, and a nitrogen inlet pipe. The reactor was filled with 1,000 parts by mass of hexamethylene diisocyanate (HDI) and 22 parts by mass of trimethylolpropane (molecular weight: 134) as a trihydric alcohol, and in a state where the temperature of the reaction solution in the reactor was being kept at 90° C., the reaction solution was stirred for 1 hour with stirring so as to perform urethanization. Then, in a state where the temperature of the reaction solution was being kept at 60° C., trimethylbenzyl ammonium hydroxide was added as an isocyanuration catalyst to the reaction solution being stirred. At a point in time when the isocyanurate inversion rate reached 48%, phosphoric acid was added thereto such that the reaction stopped. Thereafter, the reaction solution was filtered, and then the unreacted HDI was removed using a thin-film evaporator, thereby obtaining an isocyanate-based compound a.

The viscosity of the obtained isocyanate-based compound a at 25° C. was 25,000 mPa·s, the content of an isocyanate group in the compound was 19.9% by mass, the number-average molecular weight of the compound was 1,080, and the average number of isocyanate groups in the compound was 5.1. Through Nuclear Magnetic Resonance (NMR) analysis, the existence of a urethane bond, an allophanate bond, and an isocyanurate bond was checked.

Nitrogen purging was performed in a 4-neck flask (reactor) equipped with a stirrer, a thermometer, a reflux cooling pipe, a nitrogen inlet tube, and a dropping funnel. The reactor was filled with 100 parts by mass of the isocyanate-based compound a obtained as above, 42.3 parts by mass of methoxypolyethylene glycol having a number-average molecular weight of 400, and 76.6 parts by mass of dipropylene glycol dimethyl ether, and in a state where the temperature of the reaction solution was being kept at 80° C., the reaction solution was stirred for 6 hours. Then, the temperature of the reaction solution was cooled to 60° C., 72 parts by mass of diethyl malonate and 0.88 parts by mass of a 28% by mass methanol solution of sodium methylate were added thereto, and in a state where the temperature of the reaction solution was being maintained, the resulting solution was stirred for 4 hours. Thereafter, 0.86 parts by mass of 2-ethylhexyl acid phosphate (mixture of a monoester and a diester) was added thereto. Subsequently, 43.3 parts by mass of diisopropylamine was added thereto, and in a state where the temperature of the reaction solution was being kept at 70° C., the reaction solution was stirred for 5 hours. By analyzing the reaction solution through gas chromatography, it was confirmed that a reaction rate of diisopropylamine was 70%. In this way, an isocyanate-based compound A was obtained (concentration of solid content: 70% by mass, amount of effective NCO group: 5.3% by mass).

(3) Preparation of Composition for Forming Easily Adhesive Layer

Carboxylic acid-modified polyvinyl alcohol resin (manufactured by KURARAY CO., LTD., 57.6 parts by mass) having a degree of saponification of 77% and a degree of polymerization of 600, 28.8 parts by mass (amount of solid content) of the polyester-based resin prepared as above, 4.0 parts by mass (amount of solid content) of the isocyanate-based compound A prepared as above, 0.7 parts by mass of an organic tin-based compound (manufactured by DKS Co., Ltd., trade name: ELASTRON Cat-21), and 8.1 parts by mass (amount of solid content) of silica sol having an average primary particle diameter of 80 nm were mixed together and diluted with water such that the solid content thereof became 8.9 parts by mass, thereby preparing a composition for forming an easily adhesive layer.

<2. Preparation of Resin Film (PET)>

(1) Preparation of raw material polyester 1

Terephthalic acid and ethylene glycol were directly reacted with each other as shown below, water was distilled away, and esterification was performed. Then, by using a direct esterification method in which polycondensation is performed under reduced pressure, a raw material polyester 1 (Sb catalyst-based PET) was obtained using a continuous polymerization apparatus.

(1-1) Esterification Reaction

High-purity terephthalic acid (4.7 tons) and 1.8 tons of ethylene glycol were mixed together for 90 minutes, thereby forming a slurry. The slurry was continuously supplied to a first esterification reactor at a flow rate of 3,800 kg/h. Furthermore, antimony trioxide in an ethylene glycol solution was continuously supplied thereto, and a reaction was performed with stirring at an internal temperature of the reactor of 250° C. and an average residence time of about 4.3 hours. At this time, the antimony trioxide was continuously added such that the amount of Sb added became 150 mass parts per million (ppm) in terms of the element.

The reactant was moved to a second esterification reactor and reacted with stirring at an internal temperature of the reactor of 250° C. and an average residence time of 1.2 hours. To the second esterification reactor, magnesium acetate in an ethylene glycol solution and trimethyl phosphate in an ethylene glycol solution were continuously supplied such that the amount of Mg added and the amount of P added became 65 mass ppm and 35 mass ppm respectively in terms of the elements.

(1-2) Polycondensation Reaction

The esterification reaction product obtained as above was continuously supplied to a first polycondensation reactor and subjected to polycondensation with stirring at a reaction temperature of 270° C., an internal pressure of the reactor of 20 torr (2.67×10⁻⁴ MPa, 1 Torr equals about 133.3224 Pa), and an average residence time of about 1.8 hours.

The reactant was moved to a second polycondensation reactor and reacted (polycondensed) with stirring under the condition of an internal temperature of the reactor of 276° C., an internal pressure of the reactor of 5 torr (6.67×10⁻⁴ MPa), and a residence time of about 1.2 hours.

Then, the reactant was moved to a third polycondensation reactor. In this reactor, the reactant was reacted (polycondensed) under the condition of an internal temperature of the reactor of 278° C., an internal pressure of the reactor of 1.5 torr (2.0×10⁻⁴ MPa), and a residence time of 1.5 hours, thereby obtaining a reactant (polyethylene terephthalate (PET)).

(1-3) Preparation of Raw Material Polyester 1

Thereafter, the obtained reactant was jetted to cold water in the form of strands and immediately cut, thereby preparing polyester pellets <cross-section: major axis of about 4 mm, mirror axis of about 2 mm, and length of about 3 mm>. Intrinsic viscosity (IV) of the obtained polymer was 0.63 dL/g. The polymer was named raw material polyester 1.

(2) Preparation of Raw Material Polyester 2

Dried ultraviolet absorber (2,2′-(1,4-phenylene)bis(4H-3,1-benzoxazin-4-one)) (10 parts by mass) and 90 parts by mass of the raw material polyester 1 (IV=0.63 dL/g) were mixed together and made into pellets in the same manner as in Preparation of raw material polyester 1 by using a kneading extruder, thereby obtaining a raw material polyester 2 containing an ultraviolet absorber.

(3) Preparation of PET Film

A polyester-based resin film (laminated film) constituted with three layers (layer I/layer II/layer III) was prepared by the following method.

A composition for the layer II described below was dried until the moisture content thereof became equal to or lower than 20 mass ppm, put into a hopper of a single-screw kneading extruder having a diameter of 50 mm and melted at 300° C. in the extruder, thereby preparing a molten resin material for forming the layer II positioned between the layer I and the layer II.

Composition for layer II

| | |
|---|---|
| Raw material polyester 1 | 90 parts by mass |
| Raw material polyester 2 containing | 10 parts by mass |
| 10% by mass of ultraviolet absorber | |
| (2,2′-1,4-phenylene)bis(4H-3,1- | |
| benzoxazin-4-one)) | |

The raw material polyester 1 was dried until the moisture content thereof became equal to or lower than 20 mass ppm, put into a hopper of a single-screw kneading extruder having a diameter of 30 mm, and melted at 300° C. in the extruder, thereby preparing a molten resin material for forming the layer I and the layer III.

These two kinds of molten resin materials were passed through a gear pump and a filter (pore size: 1 μm) respectively. Then, through a block by which the two kinds of resins become confluent as three layers, the resin materials were laminated such that the molten resin material extruded from the extruder for the layer II became the inner layer and that the molten resin material extruded from the extruder for the layer I and the layer III became the outer layers, and then extruded in the form of a sheet from a die having a width of 120 mm.

The molten resin sheet extruded from the die was extruded onto a cooling casting drum set to have a surface temperature of 25° C. and caused to come into close contact with the cooling casting drum by using a method of applying static electricity. By using a peeling roll disposed to face the cooling casting drum, the film obtained after cooling was peeled from the drum, thereby obtaining a non-stretched film. At this time, the amount of resin jetted from each extruder was adjusted such that a thickness ratio of layer I:layer II:layer III in the non-stretched film became 10:80:10.

By using a group of heated rolls and an infrared heater, the non-stretched film was heated such that the surface temperature of the film became 95° C. Then, by using a group of rolls having different circumferential speeds, the film was stretched 400% in a direction perpendicular to the transport direction of the film, thereby obtaining a resin film (laminated film) having a thickness of 80 μm.

(4) Preparation of Resin Film (PET) with Easily Adhesive Layer

One surface of the resin film prepared as above was subjected to a corona discharge treatment at a throughput of 500 J/m². Then, the surface having undergone the corona discharge treatment was coated with the composition for forming an easily adhesive layer by a reverse roll method with adjusting the amount of the composition such that the thickness became 0.1 μm after drying. In this way, a resin film (PET) with an easily adhesive layer was prepared.

<3. Preparation of Laminate>

A laminate of Example 9 having the constitution shown in FIG. 1, in which easily adhesive layer/resin film/pressure sensitive adhesive layer/release film were laminated in this order, was prepared by the same method as that in Example 1, except that the resin film (PET) with an easily adhesive layer was used instead of the resin film (TAC-1).

### Example 10

A laminate of Example 10 having the constitution shown in FIG. 1 was prepared by the same method as that in Example 1, except that a polycarbonate (PC) film (in-plane retardation at 550 nm: 140 nm) having a thickness of 300 μm prepared with reference to [Example 3] in JP3325560B was used instead of the resin film (TAC-1).

### Example 11

A laminate of Example 11 having the constitution shown in FIG. 1 was prepared by forming films in the same manner as in Example 6, except that the thickness of the pressure sensitive adhesive layer was set to be 50 μm.

### Example 12

A laminate of Example 12 having the constitution shown in FIG. 1 was prepared by forming films in the same manner as in Example 6, except that the thickness of the pressure sensitive adhesive layer was set to be 75 μm.

### Example 13

A laminate of Example 13 having the constitution shown in FIG. 1 was prepared by forming films in the same manner as in Example 6, except that the thickness of the pressure sensitive adhesive layer was set to be 100 μm.

### Example 14

A laminate of Example 14 having the constitution shown in FIG. 1 was prepared by forming films in the same manner as in Example 6, except that the amount of the aromatic modified terpene resin emulsion (trade name: NANOLET R-1050, manufactured by YASUHARA CHEMICAL CO., LTD., softening point: 100° C.) mixed was set to be 16 parts in terms of the amount of solid content.

### Example 15

A laminate of Example 15 having the constitution shown in FIG. 1 was prepared by forming films in the same manner as in Example 6, except that the amount of the aromatic modified terpene resin emulsion (trade name: NANOLET R-1050, manufactured by YASUHARA CHEMICAL CO., LTD., softening point: 100° C.) mixed was set to be 11 parts in terms of the amount of solid content.

### Example 16

A laminate of Example 16 having the constitution shown in FIG. 1 was prepared by forming films in the same manner as in Example 6, except that the amount of the aromatic modified terpene resin emulsion (trade name: NANOLET R-1050, manufactured by YASUHARA CHEMICAL CO., LTD., softening point: 100° C.) mixed was set to be 4 parts in terms of the amount of solid content.

### Examples 17 to 22

By using any of the curable compositions for forming a hardcoat layer (HC layer) A-1 to A-4 shown in the following Table 1, a laminate with a hardcoat layer having the constitution shown in FIG. 2 was prepared by the method described below.

The details of each step in the preparation of the laminate with a hardcoat layer and the used compounds will be described below.

<1. Preparation of Composition for Forming Hardcoat Layer (HC Layer)>

Components were mixed together according to the composition shown in the following Table 1 and filtered through a filter made of polypropylene having a pore size of 10 μm, thereby preparing curable compositions for forming an HC layer A-1 to A-4.

TABLE 1

| | | | A-1 | A-2 | A-3 | A-4 |
|---|---|---|---|---|---|---|
| Solid | Monomer | DPHA | 95.90% | 39.40% | 38.40% | 95.00% |
| content | | CYCLOMER M100 | | 40.00% | 40.00% | |
| | Inorganic particles | MEK-AC-2140Z | | 15.00% | 15.00% | |
| | Polymerization | Irg184 | 4.00% | 4.00% | 4.00% | 4.00% |
| | initiator | PAG-1 | | 1.50% | 1.50% | |
| | UV absorber | TINUVIN928 | | | 1.00% | |
| | Fluorine-containing | RS-90 | | | | 1.00% |
| | compound | P-112 | 0.10% | 0.10% | 0.10% | |

| | | | | | |
|---|---|---|---|---|---|
| Solvent | MEK | 45.00% | 45.00% | 45.00% | 40.00% |
| | MIBK | | | | 60.00% |
| | Methyl acetate | 55.00% | 55.00% | 55.00% | |

| | | | | |
|---|---|---|---|---|
| Concentration of solid content in composition | 70% | 70% | 70% | 50% |

In Table 1, the amount of each component was described such that the total amount of the solid content and the solvent becomes 100% by mass.

The details of each compound described in Table 1 are as below.

<Polymerizable Compound>

DPHA: mixture of dipentaerythritol pentaacrylate and dipentaerythritol hexaacrylate (manufactured by Nippon Kayaku Co., Ltd., trade name: KAYARAD DPHA)

CYCLOMER M100: 3,4-epoxycyclohexylmethyl methacrylate (manufactured by DAICEL CORPORATION, trade name)

<Inorganic Particles>

MEK-AC-2140Z: organosilica sol, particle diameter of 10 to 15 nm (manufactured by NISSAN CHEMICAL INDUSTRIES, LTD., trade name)

<Polymerization Initiator>

Irg 184: 1-hydroxy-cyclohexyl-phenyl-ketone (radical photopolymerization initiator based on α-hydroxyalkylphenone, manufactured by BASF SE, trade name: IRGACURE 184)

PAG-1: cationic photopolymerization initiator as iodonium salt compound shown below

Cationic Photopolymerization Initiator (Iodonium Salt Compound)

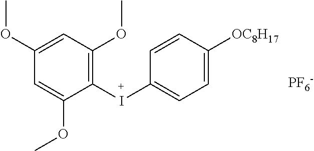

<Ultraviolet (UV) Absorber>

TINUVIN 928:

2-(2H-benzotriazol-2-yl)-6-(-methyl-1-phenylethyl)-4-(1,1,3,3-tetramethylbutyl)phenol

<Fluorine-Containing Compound>

RS-90: antifoulant, manufactured by DIC Corporation, fluorine-containing oligomer having radically polymerizable group

P-112: leveling agent, compound P-112 described in paragraph “0053” in JP5175831B

<Solvent>

MEK: methyl ethyl ketone

MIBK: methyl isobutyl ketone

<2. Preparation of Laminate (Formation of Hardcoat Layer)>

In the laminate prepared in Example 6, a surface, which was opposite to the pressure sensitive adhesive layer, of the resin film was coated with the curable composition for forming an HC layer, and the composition was cured so as to form a hardcoat layer, thereby preparing laminates of Examples 17 to 22.

Specifically, coating and curing were performed by the following method. By a die coating method using a slot die described in Example 1 in JP2006-122889A, coating was performed using the curable composition for forming an HC layer under the condition of a transport speed of 30 m/min, and the curable composition was dried for 150 seconds at an atmospheric temperature of 60° C. Then, with nitrogen purging at an oxygen concentration of about 0.1% by volume, by using an air-cooled metal halide lamp (manufactured by EYE GRAPHICS Co., Ltd.) at 160 W/cm, the curable composition for forming an HC layer used for coating was cured by being irradiated with ultraviolet rays at an illuminance of 20 mW/cm² and an irradiation amount of 30 mJ/cm² such that a hardcoat layer was formed, and the obtained film was wound up.

### Example 23

On a surface of the hardcoat layer (referred to as first HC layer) of Example 21, a second HC layer was formed by performing coating, drying, and curing under the same conditions as those in the formation of the hardcoat layer of Example 21, except that the curable composition for forming an HC layer A-4 described in Table 1 was used, and the film thickness thereof was set to be the film thickness described in Table 2. In this way, a laminate of Example 23 having the constitution shown in FIG. 2 was prepared.

### Example 47

A laminate of Example 47 having the constitution shown in FIG. 1 was prepared by forming films in the same manner as in Example 4, except that the film thickness of the resin film obtained after drying was set to be 70 μm (outer layer/core layer/outer layer=3 μm/64 μm/3 μm).

### Example 48

A laminate of Example 48 having the constitution shown in FIG. 2 was prepared in the same manner as in Example 23, except that the film thickness of the resin film obtained after drying was set to be 80 μm (outer layer/core layer/outer layer=3 μm/74 m/3 μm).

### Example 49

A laminate of Example 49 having the constitution shown in FIG. 2 was prepared in the same manner as in Example 23, except that the film thickness of the resin film obtained after drying was set to be 120 μm (outer layer/core layer/outer layer=3 μm/114 μm/3 μm).

### Example 50

A laminate of Example 50 having the constitution shown in FIG. 2 was prepared in the same manner as in Example 23, except that the film thickness of the resin film obtained after drying was set to be 150 μm (outer layer/core layer/outer layer=3 μm/144 μm/3 μm).

### Example 51

A laminate of Example 51 having the constitution shown in FIG. 2 was prepared in the same manner as in Example 23, except that the film thickness of the resin film obtained after drying was set to be 200 pan (outer layer/core layer/outer layer=3 μm/194 μm/3 μm).

### Example 52

A laminate of Example 52 having the constitution shown in FIG. 2 was prepared in the same manner as in Example 23, except that the film thickness of the resin film obtained after drying was set to be 300 μm (outer layer/core layer/outer layer=3 μm/294 μm/3 μm).

### Example 53

The laminate of Example 23 was disposed in a chamber of a magnetron sputtering apparatus such that the second HC layer was exposed. On the second HC layer, a layer of low refractive index 1 (refractive index: 1.47, thickness: 20 nm) was formed using SiO₂ by sputtering. Furthermore, on the layer of low refractive index 1, a layer of high refractive index 1 (refractive index: 2.33, thickness: 17 nm) was formed using Nb₂O₅ by sputtering. In addition, on the layer of high refractive index 1, a layer of low refractive index 2 (refractive index: 1.47, thickness: 42 nm) was formed using SiO₂ by sputtering. Moreover, on the layer of low refractive index 2, a layer of high refractive index 2 (refractive index: 2.33, thickness: 30 nm) was formed using Nb₂O₅ by sputtering. On the layer of high refractive index 2, a layer of low refractive index 3 (refractive index: 1.47, thickness: 110 nm) was formed using SiO₂ by sputtering. In this way, a laminate of Example 53 was prepared.

### COMPARATIVE EXAMPLES

### Comparative Example 1

A resin film (TAC-2) of Comparative Example 1 was prepared by forming films in the same manner as in Example 1, except that in the preparation of the resin film (TAC-1) of Example 1, the obtained casting film was not exposed to drying air, the temperature of drying air blown to the film from the upstream side of the upper portion of the casting band was set to be 80° C., and drying air with a temperature of 60° C. were blown to the film from the downstream side.

A laminate of Comparative Example 1 was prepared in the same manner as in Example 1, except that the resin film (TAC-2) was used instead of the resin film (TAC-1).

### Comparative Example 2

<1. Preparation of Pressure Sensitive Adhesive Sheet>

A reaction apparatus including a stirrer, a reflux condenser, a thermometer, and a nitrogen introduction pipe was filled with 90 parts by mass of butyl acrylate (BA), 10 parts by mass of acrylic acid (AA), and 120 parts by mass of ethyl acetate (EtAc), the reaction solution was heated to 70° C. while nitrogen gas was being introduced thereinto, and the reaction solution was stirred. Then, 0.2 parts by mass of azobisisobutyronitrile (AIBN) was added thereto, and a polymerization reaction was performed for 5 hours at 70° C. in a nitrogen atmosphere. After the reaction was finished, the reaction solution was diluted with ethyl acetate (EtAc), thereby obtaining a (meth)acrylic copolymer A having a weight-average molecular weight of 600,000.

Furthermore, a reaction apparatus including a stirrer, a reflux condenser, a thermometer, and a nitrogen introduction pipe was filled with 95 parts by mass of methyl methacrylate (MMA), 5 parts by mass of acrylamide (AM), and 100 parts by mass of toluene (To), the reaction solution was heated to 110° C. while nitrogen gas was being introduced thereinto, and the reaction solution was stirred. Then, 2 parts by mass of azobisisobutyronitrile (AIBN) was added thereto, and a polymerization reaction was performed for 5 hours at 70° C. in a nitrogen atmosphere. After the reaction was finished, the reaction solution was diluted with ethyl acetate (EtAc), thereby obtaining a (meth)acrylic copolymer B having a weight-average molecular weight of 20,000.

The (meth)acrylic copolymer B (40 parts by mass, amount of solid content) and 0.05 parts by mass of TETRAD X (manufactured by MITSUBISHI GAS CHEMICAL COMPANY, INC., trade name) as a crosslinking agent were added to 100 parts by mass (amount of solid content) of the obtained (meth)acrylic copolymer A, thereby preparing a pressure sensitive adhesive composition. A release-treated surface of a 38 μm polyethylene terephthalate (PET) film having undergone a release treatment was coated with the pressure sensitive adhesive composition such that the thickness thereof became 15 μm after drying, and the composition was dried for 2 minutes at 80° C. by using a drying machine, thereby forming a pressure sensitive adhesive layer. The pressure sensitive adhesive layer was bonded to a release-treated surface of another 38 μm PET film having undergone a release treatment, and the laminate was allowed to mature for 7 days at 23° C., thereby obtaining a pressure sensitive adhesive sheet of Comparative Example 2 constituted with release sheet/pressure sensitive adhesive layer/release sheet laminated in this order.

<2. Preparation of Laminate (Bonding of Pressure Sensitive Adhesive Layer)>

A laminate of Comparative Example 2 was prepared by forming films in the same manner as in Example 4, except that the pressure sensitive adhesive sheet of Comparative Example 2 prepared as above was used instead of the pressure sensitive adhesive sheet in Example 4.

### Comparative Example 3

A laminate of Comparative Example 3 was prepared in the same manner as in Example 4, except that the thickness of the pressure sensitive adhesive layer was set to be 110 μm.

### Comparative Example 4

A laminate of Comparative Example 4 was prepared in the same manner as in Comparative Example 2, except that the resin film (PMMA/PC/PMMA) prepared in Example 8 was used as a resin film.

### Comparative Example 5

A laminate of Comparative Example 5 was prepared in the same manner as in Comparative Example 2, except that the resin film (PET) prepared in Example 9 was used as a resin film.

### Comparative Example 6

A laminate of Comparative Example 6 was prepared in the same manner as in Comparative Example 2, except that the resin film (PC) prepared in Example 10 was used as a resin film.

### Reference Example 1

A glass plate (Gorilla glass, manufactured by Corning Incorporated, 50 mm×100 mm×0.7 mm (thickness)) was used as Reference Example 1.

<Test>

The laminates prepared as above and the glass plate were tested as below. The test results are summarized in the following Tables 2 and 3. Examples 1 to 23 and 47 to 53 are laminates of the embodiment of the present invention, and Comparative Examples 1 to 6 are comparative laminates. In each test, “viewing side” in each laminate means a surface, which is opposite to a surface bonded to the pressure sensitive adhesive layer, of the resin film.

### [Test Example 1-1] Surface Roughness (4 mm×5 mm)

For viewing side surface of the resin film, by using Vertscan 2.0 (manufactured by MITSUBISHI CHEMICAL SYSTEMS, Inc.), a surface roughness Sa in a visual field having a size of 3,724 μm×4,965 μm was measured in a Wave mode at a lens magnification of 2.5× and a lens barrel magnification of 0.5×.

### [Test Example 1-2] Surface Roughness (120 μm×120 μm)

For viewing side surface of the resin film, by using Vertscan 2.0 (manufactured by MITSUBISHI CHEMICAL SYSTEMS, Inc.), a surface roughness Sa in a visual field having a size of 120 μm×120 μm was measured in a Phase mode at a lens magnification of 10×.

In the following Table 2, the surface roughness described in the column of Resin film is the surface roughness of the simple resin film that is not yet being laminated on a pressure sensitive adhesive layer, and shows the roughness of a surface which becomes a viewing side in a case where the resin film is made into a laminate.

Furthermore, in the following Table 2, the surface roughness described in the column of Laminate is the surface roughness of the resin film on the viewing side that is measured in a state where the resin film and the pressure sensitive adhesive layer are laminated. In a case where the laminate has an HC layer, the surface roughness is a value measured in the state of the laminate of the resin film, on which the HC layer is not yet being formed, and the pressure sensitive adhesive layer.

### [Test Example 2] Thickness of Layer

Each of the laminates was cut with a microtome so as to cut off the cross-section, and stained overnight with an approximately 3% by mass aqueous osmium tetroxide solution. Then, the surface was cut off again, and the cross-section was observed using a Scanning Electron Microscope (SEM). For each layer, 10 sites were randomly extracted from the image of the cross-section, the thicknesses thereof were measured, and the average thereof was taken as the thickness thereof.

### [Test Example 3] Loss Tangent (Tan δ)

By using the pressure sensitive adhesive composition used for each of the laminates, a pressure sensitive adhesive layer having an area of 10 mm×100 mm and a thickness of 25 μm was prepared. The pressure sensitive adhesive layer was rounded off in the form of a dumpling, and a loss modulus E″, a storage modulus E′, and a tan δ of the pressure sensitive adhesive layer were measured in an environment with a temperature of −10° C. by using a dynamic viscoelasticity measurement apparatus DVA-225 (manufactured by ITK Co., Ltd, trade name) in a shearing mode at a frequency of 1 Hz within a temperature range of −100° C. to 50° C. The maximum value of tan δ in a temperature range of 0° C. to −40° C. is described in the following Table 2.

### [Test Example 4] Quality

The glass quality of the laminate was evaluated in the following procedure.

The release sheet in the laminate was peeled such that the pressure sensitive adhesive layer was exposed. The laminate and optical glass for a liquid crystal cell (manufactured by Corning Incorporated, trade name: EAGLE XG, thickness: 400 μm) were bonded to each other by a rubber roller under a load of 2 kg applied thereto such that the pressure sensitive adhesive layer and the optical glass became adjacent to each other. A surface, which was not bonded to the film of the laminate, of the optical glass and a black PET film with a pressure sensitive adhesive (trade name: KUKKIRI MIERU, manufactured by TOMOEGAWA CO., LTD.) were bonded to each other by a rubber roller under a load of 2 kg applied thereto such that the optical glass and the pressure sensitive adhesive became adjacent to each other. The light from a fluorescent lamp was projected onto the uppermost surface on the viewing side of the laminate, and the reflected image of the fluorescent lamp was observed and evaluated as below.

<Evaluation Standards>

A: The reflected image of the fluorescent lamp was not distorted (the quality of the laminate was the same as that of glass).

B: Substantially no distortion was observed in the reflected image of the fluorescent lamp.

C: Distortion was observed in the reflected image of the fluorescent lamp, but the distortion was extremely slight.

D: Distortion was observed in the reflected image of the fluorescent lamp, but the distortion was slight.

E: The reflected image of the fluorescent lamp was significantly distorted.

### [Test Example 5] Pencil Hardness

Pencil hardness was evaluated according to Japanese Industrial Standards (JIS) K 5400.

From each of the laminates, the release sheet was peeled such that the pressure sensitive adhesive layer was exposed. The exposed pressure sensitive adhesive layer and a glass plate (manufactured by Corning Incorporated, trade name: EAGLE XG, thickness: 1 mm) were bonded to each other by a rubber roller under a load of 2 kg applied thereto, and the laminate was humidified for 2 hours at a temperature of 25° C. and a relative humidity of 60%, and then 5 different sites on the uppermost surface on the viewing side of the laminate were scratched under a load of 4.9 N by using a testing pencil with hardness of 6B to 9H specified in JIS S 6006. Thereafter, among the hardnesses of the pencil by which a visually recognized scratch was formed at 0 to 2 sites, the highest pencil hardness was taken as an evaluation result. Regarding the pencil hardness, the larger the value listed before “H”, the more preferable because the large value shows that the hardness is high.

### [Test Example 6] Rub Resistance

Steel wool (manufactured by NIHON STEEL WOOL Co., Ltd., No. 0) was wound around the tip rubbing portion (1 cm×1 cm), which will contact an evaluation subject (laminate), of a rubbing tester (manufactured by TESTER SANGYO CO., LTD.) in an environment of a temperature of 25° C. and a relative humidity of 60%, and fixed using a band so as to prevent the steel wool from moving. Then, the uppermost surface on the viewing side of each laminate was rubbed under the following conditions.

Moving distance (one way): 13 cm, rubbing speed: 13 cm/sec, load: 1,000 g, contact area of tip portion: 1 cm×1 cm

After the test, an oil-based black ink was applied to a surface, which was opposite to the viewing side, of each laminate, and the reflected light was visually observed. The number of times of rubbing that caused scratches in the portion contacting the steel wool was counted, and the rub resistance was evaluated based on the following standards.

<Evaluation Standards>

A: No scratch was made even though the laminate was rubbed 10,000 times.

B: While the number of times of rubbing was exceeding 1,000 and reaching 10,000, scratches were made for the first time.

C: While the number of times of rubbing was exceeding 100 and reaching 1,000, scratches were made for the first time.

D: While the number of times of rubbing was exceeding 10 and reaching 100, scratches were made for the first time.

E: Scratches were made while the second cured layer was being rubbed 10 times.

### [Test Example 7] Keystroke Durability

From each of the laminates, the release sheet was peeled such that the pressure sensitive adhesive layer was exposed. The exposed pressure sensitive adhesive layer and a glass plate (manufactured by Corning Incorporated, trade name: EAGLE XG, thickness: 1 mm) were bonded to each other by a rubber roller under a load of 2 kg applied thereto, and the laminate was humidified for 2 hours at a temperature of 25° C. and a relative humidity of 60%. Then, by using a keystroke tester (manufactured by YSC), an input stylus (material of the stylus tip: polyacetal, R=0.8 mm, manufactured by Wacom) was pressed on the laminate from above the side opposite to the glass plate under the conditions of a keystroke speed: 2 times/min and a load: 250 g, and the keystroke durability was evaluated based on the following standards.

<Evaluation Standards>

A: No recess was made even though keystroke was performed 50,000 times.

B: While the number of times of keystroke was exceeding 10,000 and then the laminate was being pressed 50,000 times, recesses were made.

C: While the number of times of keystroke was exceeding 1,000 and then the laminate was being pressed 10,000 times, recesses were made.

D: While the number of times of keystroke was exceeding 100 and then the laminate was being pressed 1,000 times, recesses were made.

E: While the laminate was being pressed until the number of time of keystroke reached 100 times, recesses were made.

TABLE 2

| | Laminate | | | | | | | | | | |
|---|---|---|---|---|---|---|---|---|---|---|---|
| | Resin film | | | | | | Pressure sensitive | | | Surface | |
| | | Thick- | Surface | | HC layer | | adhesive layer | | Surface | roughness | Evaluation |
| | | ness | roughness | Surface roughness | Compo- | Thickness | | Thickness | roughness | 120 μm × | Glass |
| | Material | (μm) | 4 mm × 5 mm | 120 μm × 120 μm | sition | (μm) | tanδ | (μm) | 4 mm × 5 mm | 120 μm | quality |
| Example 1 | TAC-1 | 80 | 15 nm | 3 nm | N/A | N/A | 3.0 | 15 | 15 nm | 3 nm | D |
| Example 2 | TAC-1 | 80 | 10 nm | 3 nm | N/A | N/A | 3.0 | 15 | 10 nm | 3 nm | C |
| Example 3 | TAC-1 | 80 | 7 nm | 3 nm | N/A | N/A | 3.0 | 15 | 7 nm | 3 nm | B |
| Example 4 | TAC-1 | 80 | 5 nm | 3 nm | N/A | N/A | 3.0 | 15 | 5 nm | 3 nm | A |
| Example 5 | TAC-1 | 80 | 1 nm | 3 nm | N/A | N/A | 3.0 | 15 | 1 nm | 3 nm | A |
| Example 6 | TAC-1 | 100 | 5 nm | 3 nm | N/A | N/A | 3.0 | 15 | 5 nm | 3 nm | A |
| Example 7 | TAC-1 | 120 | 5 nm | 3 nm | N/A | N/A | 3.0 | 15 | 5 nm | 3 nm | A |
| Example 8 | PMMA/ | 300 | 12 nm | 5 nm | N/A | N/A | 3.0 | 15 | 12 nm | 5 nm | C |
| | PC/ | | | | | | | | | | |
| | PMMA | | | | | | | | | | |
| Example 9 | PET | 80 | 18 nm | 4 nm | N/A | N/A | 3.0 | 15 | 18 nm | 4 nm | C |
| Example 10 | PC | 300 | 22 nm | 5 nm | N/A | N/A | 3.0 | 15 | 22 nm | 5 nm | D |
| Example 11 | TAC-1 | 100 | 5 nm | 3 nm | N/A | N/A | 3.0 | 50 | 13 nm | 3 nm | B |
| Example 12 | TAC-1 | 100 | 5 nm | 3 nm | N/A | N/A | 3.0 | 75 | 22 nm | 3 nm | C |
| Example 13 | TAC-1 | 100 | 5 nm | 3 nm | N/A | N/A | 3.0 | 100 | 28 nm | 3 nm | D |
| Example 14 | TAC-1 | 100 | 5 nm | 3 nm | N/A | N/A | 2.0 | 15 | 10 nm | 3 nm | B |
| Example 15 | TAC-1 | 100 | 5 nm | 3 nm | N/A | N/A | 1.5 | 15 | 23 nm | 3 nm | C |
| Example 16 | TAC-1 | 100 | 5 nm | 3 nm | N/A | N/A | 1.3 | 15 | 30 nm | 3 nm | D |
| Example 17 | TAC-1 | 100 | 5 nm | 3 nm | A-1 | 5 | 3.0 | 15 | 5 nm | 3 nm | A |
| Example 18 | TAC-1 | 100 | 5 nm | 3 nm | A-2 | 5 | 3.0 | 15 | 5 nm | 3 nm | A |
| Example 19 | TAC-1 | 100 | 5 nm | 3 nm | A-3 | 5 | 3.0 | 15 | 5 nm | 3 nm | A |
| Example 20 | TAC-1 | 100 | 5 nm | 3 nm | A-3 | 10 | 3.0 | 15 | 5 nm | 3 nm | A |
| Example 21 | TAC-1 | 100 | 5 nm | 3 nm | A-3 | 20 | 3.0 | 15 | 5 nm | 3 nm | A |
| Example 22 | TAC-1 | 100 | 5 nm | 3 nm | A-3 | 50 | 3.0 | 15 | 5 nm | 3 nm | A |
| Example 23 | TAC-1 | 100 | 5 nm | 3 nm | A-3/A-4 | 20/5 | 3.0 | 15 | 5 nm | 3 nm | A |
| Example 47 | TAC-1 | 70 | 5 nm | 3 nm | N/A | N/A | 3.0 | 15 | 5 nm | 3 nm | A |
| Example 48 | TAC-1 | 80 | 5 nm | 3 nm | A-3/A-4 | 20/5 | 3.0 | 15 | 5 nm | 3 nm | A |
| Example 49 | TAC-1 | 120 | 5 nm | 3 nm | A-3/A-4 | 20/5 | 3.0 | 15 | 5 nm | 3 nm | A |
| Example 50 | TAC-1 | 150 | 5 nm | 3 nm | A-3/A-4 | 20/5 | 3.0 | 15 | 5 nm | 3 nm | A |
| Example 51 | TAC-1 | 200 | 5 nm | 3 nm | A-3/A-4 | 20/5 | 3.0 | 15 | 5 nm | 3 nm | A |
| Example 52 | TAC-1 | 300 | 5 nm | 3 nm | A-3/A-4 | 20/5 | 3.0 | 15 | 5 mn | 3 nm | A |
| Example 53 | TAC-1 | 100 | 5 nm | 3 nm | A-3/A-4 | 20/5 | 3.0 | 15 | 5 nm | 3 nm | A |
| Comparative | TAC-2 | 80 | 35 nm | 1 nm | N/A | N/A | 3.0 | 15 | 35 nm | 1 nm | E |
| Example 1 | | | | | | | | | | | |
| Comparative | TAC-1 | 80 | 5 nm | 3 nm | N/A | N/A | 1.2 | 15 | 32 nm | 1 nm | E |
| Example 2 | | | | | | | | | | | |
| Comparative | TAC-1 | 80 | 5 nm | 3 nm | N/A | N/A | 3.0 | 110 | 31 nm | 1 nm | E |
| Example 3 | | | | | | | | | | | |
| Comparative | PMMA/ | 300 | 12 nm | 5 nm | N/A | N/A | 1.2 | 15 | 40 nm | 5 nm | E |
| Example 4 | PC/ | | | | | | | | | | |
| | PMMA | | | | | | | | | | |
| Comparative | PET | 80 | 18 nm | 4 nm | N/A | N/A | 1.2 | 15 | 48 nm | 4 nm | E |
| Example 5 | | | | | | | | | | | |
| Comparative | PC | 300 | 22 nm | 5 nm | N/A | N/A | 1.2 | 15 | 62 nm | 5 nm | E |
| Example 6 | | | | | | | | | | | |
| Reference | Glass | 700 | 1 nm | 1 nm | N/A | N/A | — | — | — | — | A |
| Example 1 | | | | | | | | | | | |

As described in Table 2, the laminate of Comparative Example 1, in which the surface roughness Sa (visual field for measurement: 4 mm×5 mm) of the resin film on the viewing side in a laminated state was high, exhibited quality that is similar to that of glass. Furthermore, each of the laminates of Comparative Examples 2 and 4 to 6, which had a pressure sensitive adhesive layer whose maximum value of tan δ (frequency of 1 Hz) in a temperature range of 0° C. to −40° C. was smaller than 1.3, exhibited glass quality that was lower than that of Examples 6 and 8 to 10 in which the same resin film was used. In addition, the laminate of Comparative Example 3 including a too thick pressure sensitive adhesive layer having a thickness of 110 μm did not exhibited quality similar to that of glass.

In contrast, all of the laminates of the embodiment of the present invention, in which the surface roughness Sa (visual field for measurement: 4 mm×5 mm) of the resin film on the viewing side in a laminated state was within a specific range, the thickness of the pressure sensitive adhesive layer was equal to or smaller than a specific thickness, and the maximum value of tan δ (frequency: 1 Hz) of the pressure sensitive adhesive layer in a temperature range of 0° C. to −40° C. was equal to or greater than a specific value, exhibited excellent glass quality.

As described in the following Table 3, the laminates of Examples 17 to 23 and 47 to 53 in which the HC layer was laminated on the resin film had excellent pencil hardness and rub resistance.

TABLE 3

| | Evaluation | | |
|---|---|---|---|
| | Pencil | Rub | Keystroke |
| | hardness | resistance | durability |
| Example 1 | 6B | E | E |
| Example 2 | 6B | E | E |
| Example 3 | 6B | E | E |
| Example 4 | 6B | E | E |
| Example 5 | 6B | E | E |
| Example 6 | 5B | E | E |
| Example 7 | 3B | E | E |
| Example 8 | H | E | C |
| Example 9 | 6B | E | E |
| Example 10 | 6B | E | D |
| Example 11 | 5B | E | D |
| Example 12 | 5B | E | D |
| Example 13 | 5B | E | D |
| Example 14 | 5B | E | D |
| Example 15 | 5B | E | D |
| Example 16 | 5B | E | D |
| Example 17 | 4B | B | D |
| Example 18 | 4B | C | D |
| Example 19 | 4B | D | D |
| Example 20 | 3B | D | D |
| Example 21 | B | D | D |
| Example 22 | 9H | D | C |
| Example 23 | H | A | D |
| Example 47 | Less than 6B | E | E |
| Example 48 | 5B | A | E |
| Example 49 | 3H | A | D |
| Example 50 | 6H | A | C |
| Example 51 | 7H | A | B |
| Example 52 | 9H | A | A |
| Example 53 | H | A | D |

### Examples 24 to 46 and Comparative Examples 7 to 12

Laminates with a reflection layer were prepared in which any of a mirror reflection layer A and a mirror reflection layer B shown below was used as a reflection layer.

The details of each step in the preparation of the laminate with a reflection layer and used compounds will be described below.

<1. Preparation of Mirror Reflection Layer A (Cholesteric Liquid Crystal Layer)>

(1) Preparation of Coating Solution

A coating solution 1 for a ¼ wavelength plate and a coating solution 2, a coating solution 3, and a coating solution 4 for forming a cholesteric liquid crystal layer were prepared according to the composition shown in the following Table 4. In the table, the content of each component is described without “part by mass”.

TABLE 4

| | | | For forming cholesteric liquid crystal layer | | |
|---|---|---|---|---|---|
| | Material name or trade | For 1/4 wavelength plate | Coating solution 2 | Coating solution 3 | Coating solution 4 |
| Type | name (manufacturer) | Coating solution 1 | (630 nm) | (540 nm) | (450 nm) |
| Rod-like liquid | Following compound 1 | 100 | 100 | 100 | 100 |
| crystal compound | | | | | |
| Chiral agent for | PALIOCOLOR LC756 | N/A | 4.7 | 5.5 | 6.7 |
| right-hand sense | (manufactured by BASF SE) | | | | |
| Photopolymerization | Itgacure 819 (manufactured | 4 | 4 | 4 | 4 |
| initiator | by BASF SE) | | | | |
| Alignment control agent | Following compound 2 | 0.1 | 0.1 | 0.1 | 0.1 |
| Crosslinking agent | A-TMMT (manufactured | 1.0 | 1.0 | 1.0 | 1.0 |
| | by SHIN-NAKAMURA | | | | |
| | CHEMICAL CO., LTD.) | | | | |
| Solvent | 2-Butanone (Wako Pure | 170 | 170 | 170 | 170 |
| | Chemical Industries, Ltd.) | | | | |

Rod-like liquid crystal compound: compound 1 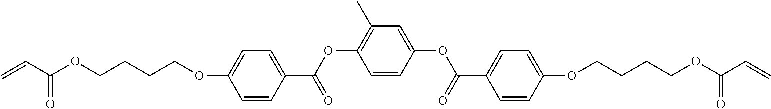 [SMILES: C=CC(=O)OCCCCOc1ccc(C(=O)Oc2ccc(OC(=O)c3ccc(OCCCCOC(=O)C=C)cc3)c(C)c2)cc1]
Alignment control agent: compound 2

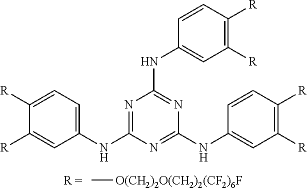

The compound 2 was manufactured by the method described in JP2005-099248A.

(2) Preparation of Temporary Support

As a temporary support (280 mm×85 mm), a PET film (trade name: COSMOSHINE A4100, thickness: 100 μm) manufactured by Toyobo Co., Ltd was used. The temporary support was subjected to a rubbing treatment (rayon cloth, pressure: 0.1 kgf (0.98 N), rotation speed: 1,000 rpm, transport speed: 10 m/min, the number of times of rubbing back and forth: 1).

(3) Preparation of Mirror Reflection Layer A

By using a wire bar, a surface, which had undergone the rubbing treatment, of the PET film was coated with the coating solution 1 and then dried. The film was then placed on a hot plate with a temperature of 30° C. such that the PET film contacted the hot plate, and subjected to ultraviolet (UV) irradiation for 6 seconds by using an electrodeless lamp “D BULB” (trade name, 60 mW/cm²) manufactured by Fusion UV Systems such that the liquid crystalline phase was fixed, thereby forming a ¼ wavelength plate having a film thickness of 0.8 μm. The surface of the formed ¼ wavelength plate was coated with the coating solution 2 by using a wire bar and then dried. The PET film was then placed on a hot plate with a temperature of 30° (such that the PET film contacted the hot plate, and subjected to UV irradiation for 6 seconds by using an electrodeless lamp “D BULB” (60 mW/cm²) manufactured by Fusion UV Systems such that the cholesteric liquid crystalline phase was fixed, thereby obtaining a cholesteric liquid crystal layer having a film thickness of 3.5 μm. The same steps were repeated using the coating solution 3 and the coating solution 4 in this order such that the ¼ wavelength plate and three cholesteric liquid crystal layers were laminated, and the PET film was peeled, thereby preparing a mirror reflection layer A (film thickness of layer of coating solution 3: 3.0 μm, film thickness of layer of coating solution 4: 2.7 μm). The mirror reflection layer A had a structure in which cholesteric liquid crystal layers for 630 nm, 540 nm, and 450 nm were laminated in this order on the ¼ wavelength plate. A transmission spectrum of the mirror reflection layer A was measured using a spectrophotometer (manufactured by JASCO Corporation, trade name: V-670). As a result, a transmission spectrum having a central wavelength of selective reflection at 630 nm, 540 nm, and 450 nm was obtained.

<2. Preparation of Mirror Reflection Layer B (Linear Polarization Reflection Layer)>

Based on the method described in JP1997-506837A (JP-H09-506837A), a linear polarization reflection layer was prepared. By using 2,6-naphthalenedicarboxylic acid and ethylene glycol, 2,6-polyethylenenaphthalate (PEN) was synthesized in a standard polyester resin synthesis furnace. Furthermore, copolyester of naphthalate and terephthalate (coPEN, mass ratio of copolymerization: naphthalate:terephthalate=70:30) was synthesized in a standard polyester resin synthesis furnace by using ethylene glycol as a diol. Each of the 2,6-polyethylenenaphthalate (PEN) and the single-layer film of coPEN was extrusion-molded and then stretched at a temperature of about 150° C. and a stretching ratio of 5:1. It was confirmed that a refractive index of PEN relating to the alignment axis was about 1.88, a refractive index of PEN relating to the transversal axis was 1.64, and all the refractive indices of the coPEN film relating to the alignment axis and the transversal axis were about 1.64.

The aforementioned PEN and coPEN supplied to a standard extrusion die were simultaneously extruded using a 50-slot supply block, thereby forming a reflection layer B1 in which a total of 50 layers including the layer of PEN (hereinafter, referred to as PEN layer) and the layer of coPEN (hereinafter, referred to as coPEN layer) that had the film thickness shown in (1) of the following Table 5 were alternately laminated. Subsequently, reflection layers B2 to B5 were formed in the same manner as in the formation of the reflection layer B1, except that the film thickness was changed as shown in (2) to (5) in the following Table 5. The obtained reflection layers B1 to B5 were laminated in this order such that the PEN layer and the coPEN layer in each of the reflection layers became alternate with each other, and the PEN layer of the reflection layer B1 and the coPEN layer of the reflection layer B5 became the uppermost surface. In this way, a reflection layer B_{All} constituted with a total of 250 laminated layers was formed. The obtained reflection layer B_{All} was stretched and then thermally cured for 30 seconds at a temperature of about 230° C. in an air oven, thereby obtaining a mirror reflection layer B.

TABLE 5

| | (1) | (2) | (3) | (4) | (5) |
|---|---|---|---|---|---|
| Film thickness of PEN layer | 63.4 | 71.5 | 79.6 | 87.7 | 95.8 |
| (nm) | | | | | |
| Film thickness of coPEN layer | 68.5 | 77.2 | 86.0 | 94.7 | 103.5 |
| (nm) | | | | | |

<3. Preparation of Laminate (Bonding of Reflection Layer)>

Each of the laminates of Examples 1 to 23 and Comparative Examples 1 to 6 and the mirror reflection layer A were bonded to each other such that the pressure sensitive adhesive layer of the laminate and the ¼ wavelength plate of the mirror reflection layer A became adjacent to each other, thereby preparing laminates with a mirror reflection layer A of Examples 24 to 46 and Comparative Examples 7 to 12.

Furthermore, each of the laminates of Examples 1 to 23 and Comparative Examples 1 to 6 and the mirror reflection layer B were bonded to each other such that the pressure sensitive adhesive layer of the laminate and the PEN layer of the mirror reflection layer B became adjacent to each other, thereby preparing laminates with a mirror reflection layer B of Examples 24 to 46 and Comparative Examples 7 to 12.

Each of the laminates was used for bonding after the pressure sensitive adhesive layer was exposed by peeling the release sheet from the laminate.

<Test>

The laminates with a mirror reflection layer A and the laminates with a mirror reflection layer B prepared as above were tested as below. The test results are summarized in the following Table 6. Examples 24 to 46 are laminates with a reflection layer of the embodiment of the present invention, and Comparative Examples 7 to 12 are comparative laminates with a reflection layer. In each test, “viewing side” in each laminate means a surface, which is opposite to a surface bonded to the pressure sensitive adhesive layer, of the resin film.

### [Test Example 8] Mirror Quality

The mirror quality of the laminate was evaluated in the following procedure.

The light from a fluorescent lamp was projected onto the uppermost surface on the viewing side of the laminate. By comparing the laminate with a silver mirror (hereinafter, referred to as Ag mirror) manufactured by Keihin Komaku Kogyo Co., Ltd., the mirror quality of the reflected image of the fluorescent lamp was evaluated as below. The mirror quality deterioration is involved not only in the distortion of the reflected image, but also in the surface quality deterioration occurring in the form of orange peel. Therefore, the distortion and the orange peel were evaluated in combination.

<Evaluation Standards of Distortion>

a: The reflected image of the fluorescent lamp was not distorted, and the laminate had quality similar to that of the Ag mirror.

b: Substantially no distortion was observed in the reflected image of the fluorescent lamp.

c: Distortion was observed in the reflected image of the fluorescent lamp, but the distortion was extremely slight.

d: Distortion was observed in the reflected image of the fluorescent lamp, but the distortion was slight.

e: The reflected image of the fluorescent lamp was significantly distorted.

<Evaluation Standards of Orange Peel>

a: The reflected image of the fluorescent lamp did not have surface quality variation in the form of orange peel, and the laminate had quality similar to that of the Ag mirror.

b: Substantially no surface quality variation in the form of orange peel was observed in the reflected image of the fluorescent lamp.

c: Surface quality variation in the form of orange peel was observed in the reflected image of the fluorescent lamp, but the variation was extremely small.

d: Surface quality variation in the form of orange peel was observed in the reflected image of the fluorescent lamp, but the variation was small.

e: A significant surface quality variation in the form of orange peel was observed in the reflected image of the fluorescent lamp, and the mirror quality deteriorated.

TABLE 6

| | Laminate with mirror | | Laminate with mirror | |
|---|---|---|---|---|
| | reflectron layer A | | reflection layer B | |
| | Evaluation of mirror quality | | | |
| | Evaluation of | Evaluation of | Evaluation of | Evaluation of |
| | distortion | orange peel | distortion | orange peel |
| Example 24 | d | d | d | d |
| Example 25 | c | c | c | d |
| Example 26 | b | b | b | c |
| Example 27 | a | a | a | b |
| Example 28 | a | a | a | b |
| Example 29 | a | a | a | b |
| Example 30 | a | a | a | b |
| Example 31 | c | c | c | d |
| Example 32 | c | c | c | c |
| Example 33 | d | d | d | d |
| Example 34 | b | b | b | c |
| Example 35 | c | c | c | c |
| Example 36 | d | d | d | d |
| Example 37 | b | b | b | c |
| Example 38 | c | c | c | c |
| Example 39 | d | d | d | d |
| Example 40 | a | a | a | b |
| Example 41 | a | a | a | b |
| Example 42 | a | a | a | b |
| Example 43 | a | a | a | b |
| Example 44 | a | a | a | b |
| Example 45 | a | a | a | b |
| Example 46 | a | a | a | b |
| Comparative | e | e | e | e |
| Example 7 | | | | |
| Comparative | e | e | e | e |
| Example 8 | | | | |
| Comparative | e | e | e | e |
| Example 9 | | | | |
| Comparative | e | e | e | e |
| Example 10 | | | | |
| Comparative | e | e | e | e |
| Example 11 | | | | |
| Comparative | e | e | e | e |
| Example 12 | | | | |

As described in Table 6, The laminate with a mirror reflection layer of Comparative Example 7, in which the resin film on the viewing side in a laminated state had a high surface roughness Sa (visual field for measurement: 4 mm×5 mm), did not exhibit quality similar to that of a mirror (mirror quality). Furthermore, each of the laminates of Comparative Examples 8 and 10 to 12 including the pressure sensitive adhesive layer whose maximum value of tan δ (frequency: 1 Hz) in a temperature range of 0° C. to −40° C. was smaller than 1.3 exhibited mirror quality lower than that of Examples 29 and 31 to 33 in which the same resin film was used. In addition, the laminate of Comparative Example 9 including a too thick pressure sensitive adhesive layer having a thickness of 110 μm did not exhibit quality similar to that of a mirror.

In contrast, all of the laminates of the embodiment of the present invention, in which the surface roughness Sa (visual field for measurement: 4 mm×5 mm) of the resin film on the viewing side in a laminated state was within a specific range, the thickness of the pressure sensitive adhesive layer was equal to or smaller than a specific thickness, and the maximum value of tan δ (frequency: 1 Hz) of the pressure sensitive adhesive layer in a temperature range of 0° C. to −40° C. was equal to or greater than a specific value, exhibited excellent mirror quality.

It is considered that in a case where the laminate of the embodiment of the present invention is used in a front panel of an image display apparatus, an image display apparatus, a mirror with an image display function, a resistive film-type touch panel and a capacitance-type touch panel, the aforementioned front panel and the like may exhibit excellent glass quality. It is considered that in a case where the laminate of the embodiment of the present invention has an HC layer, the laminate may have excellent pencil hardness and rub resistance. It is considered that in a case where the laminate of the embodiment of the present invention has a reflection layer, the laminate may exhibit excellent mirror quality.

Hitherto, the present invention has been described together with the embodiments thereof. The inventors of the present invention consider that unless otherwise specified, the present invention is not limited to any of the details of the description of the present invention, and should be interpreted in a wide sense without departing from the gist and scope of the present invention described in the attached claims.

The present application claims priorities based on JP2016-103762 filed in Japan on May 24, 2016, JP2016-123240 field in Japan on Jun. 22, 2016, and JP2016-183179 field in Japan on Sep. 20, 2016, the contents of which are incorporated into the present specification by reference as a portion of the description of the present specification.

### EXPLANATION OF REFERENCES

1A: resin film
2A: pressure sensitive adhesive layer
3A: hardcoat layer (HC layer)
4A, 4B: laminate
1: conductive film for touch panel
2: touch panel
3: resin film
4: pressure sensitive adhesive layer
4C: laminate
5: transparent insulating substrate
6A, 6B: conductive member
7A, 7B: protective layer
8: first conductive layer
9: second conductive layer
11A: first dummy electrode
11: first electrode
12: first peripheral wiring
13: first external connection terminal
14: first connector portion
15: first metal thin wire
21: second electrode
22: second peripheral wiring
23: second external connection terminal
24: second connector portion
25: second metal thin wire
C1: first cell
C2: second cell
D1: first direction
D2: second direction
M1: first mesh pattern
M2: second mesh pattern
S1: active area
S2: peripheral region

What is claimed is:

1. A laminate comprising at least:
a resin film; and
a pressure sensitive adhesive layer provided on one surface of the resin film,
wherein the resin film in the laminated state has a surface roughness Sa equal to or lower than 30 nm that is measured in a visual field of 4 mm×5 mm within a surface opposite to the surface having the pressure sensitive adhesive layer,
a thickness of the pressure sensitive adhesive layer is equal to or smaller than 100 μm, and
a maximum value of a loss tangent of the pressure sensitive adhesive layer at a frequency of 1 Hz is found in a temperature range of 0° C. to −40° C. and is equal to or greater than 1.3.

2. The laminate according to claim 1,
wherein the resin film in the laminated state has a surface roughness Sa equal to or lower than 20 nm that is measured in a visual field of 120 μm×120 μm within a surface opposite to the surface having the pressure sensitive adhesive layer.

3. The laminate according to claim 1,
wherein a thickness of the resin film is equal to or greater than 80 μm.

4. The laminate according to claim 1, further comprising;
a hardcoat layer on the surface, which is opposite to the surface provided with the pressure sensitive adhesive layer, of the resin film.

5. The laminate according to claim 4,
wherein a thickness of the hardcoat layer is equal to or greater than 10 μm and equal to or smaller than 50 μm.

6. The laminate according to claim 4,
wherein a pencil hardness of the hardcoat layer is equal to or higher than 511.

7. The laminate according to claim 1, further comprising;
a linear polarization reflection layer or a circular polarization reflection layer on a surface, which is opposite to a surface having the resin film, of the pressure sensitive adhesive layer.

8. The laminate according to claim 7,
wherein the circular polarization reflection layer includes at least one cholesteric liquid crystal layer, and
the cholesteric liquid crystal layer is a layer obtained by curing a liquid crystal composition containing a polymerizable liquid crystal compound and a polymerization initiator.

9. A front panel of an image display apparatus, comprising;
the laminate according to claim 1.

10. An image display apparatus comprising:
the front panel according to claim 9; and
an image display device.

11. The image display apparatus according to claim 10,
wherein the image display device is a liquid crystal display device.

12. The image display apparatus according to claim 10,
wherein the image display device is an organic electroluminescence display device.

13. The image display apparatus according to claim 10,
wherein the image display device is an in-cell touch panel display device.

14. The image display apparatus according to claim 10,
wherein the image display device is an on-cell touch panel display device.

15. A resistive film-type touch panel comprising:
the front panel according to claim 9.

16. A capacitance-type touch panel comprising:
the front panel according to claim 9.

17. A mirror with an image display function,
wherein the image display apparatus according to claim 10 is used.
